(19) United States
(12) Patent Application Publication
(10) Pub. No.: US 2025/0096336 A1
(43) Pub. Date: Mar. 20, 2025

(54) ELECTRODYNAMIC PARAMETERS

(71) Applicant: Iontra Inc, Centennial, CO (US)

(72) Inventors: Daniel A. KONOPKA, Aurora, CO (US); Zhong WANG, Sugar Land, TX (US)

(21) Appl. No.: 18/900,551

(22) Filed: Sep. 27, 2024

Related U.S. Application Data
(63) Continuation-in-part of application No. 18/619,129, filed on Mar. 27, 2024.
Application No. 18/619,129 is a continuation-in-part of application No. 18/127,634, filed on Mar. 28, 2023.
(60) Provisional application No. 63/454,932, filed on Mar. 27, 2023.
(60) Provisional application No. 63/540,924, filed on Sep. 27, 2023.
(60) Provisional application No. 63/542,504, filed on Oct. 4, 2023.
(60) Provisional application No. 63/455,254, filed on Mar. 28, 2023.
(60) Provisional application No. 63/324,505, filed on Mar. 28, 2022.
(60) Provisional application No. 63/540,924, filed on Sep. 27, 2023.
(60) Provisional application No. 63/542,504, filed on Oct. 4, 2023.

(51) Int. Cl. H01M 10/44; G01R 31/392; H01M 10/48; H02J 7/00

(52) U.S. Cl. CPC H01M 10/446; G01R 31/392; H01M 10/48; H02J 7/00712

(57) ABSTRACT

Aspects of the present disclosure involve methods, which may be to manage control of a battery such as through charging, comprising obtaining a value indicative of at least one of a dynamic state of equilibrium, periodic behavior, quasi-periodic behavior, chaotic behavior and random behavior of a battery, which may involve electrodynamic parameters of Lyapunov Exponent, Correlation Dimension, Sample Entropy and Hurst Exponent, among others, the value obtained from a voltage measurement or a current measurement from the battery, and based on the value, operating the battery to maintain the battery within one of the dynamic states.

### CROSS-REFERENCE TO RELATED APPLICATIONS

The present application is a Continuation-in-Part Application related to and claiming priority to U.S. patent application Ser. No. 18/619,129 filed Mar. 27, 2024, titled “Electrodynamic Parameters,” which claims benefit of priority under 35 U.S.C. § 119 to U.S. Provisional Application No. 63/454,932 filed Mar. 27, 2023, titled “System and Method for Deterministic Analysis of Batteries, and Characterization and Charging Based on the Same,” which are hereby incorporated by reference herein. U.S. patent application Ser. No. 18/619,129 is a Non-Provisional Utility patent application related to and claiming priority under 35 U.S.C. § 119 to U.S. Provisional Application No. 63/540,924 filed Sep. 27, 2023 and U.S. Provisional Application No. 63/542,504 filed Oct. 4, 2023, each titled “Electrodynamic Parameters,” both of which are hereby incorporated by reference herein. U.S. patent application Ser. No. 18/619,129 is a Non-Provisional Utility patent application related to and claiming priority under 35 U.S.C. § 119 to U.S. Provisional Application No. 63/455,254 filed Mar. 28, 2023, titled “System and Method of Time-Series Analysis of Noisy Appearing Signals for Battery Charging,” which is hereby incorporated by reference herein.

Additionally, U.S. patent application Ser. No. 18/619,129 is a Continuation-in-Part patent application related to and claiming priority to U.S. patent application Ser. No. 18/127,634 filed Mar. 28, 2023, titled “System and Method of Time-Series Analysis of Noisy Appearing Signals for Battery Charging,” which claims benefit of priority under 35 U.S.C. § 119 from U.S. Provisional Application No. 63/324,505 filed Mar. 28, 2022, titled “Noise,” both of which are hereby incorporated by reference herein.

The present application is a Non-Provisional Utility patent application related to and claiming priority under 35 U.S.C. § 119 to U.S. Provisional Application No. 63/540,924 filed Sep. 27, 2023 and U.S. Provisional Application No. 63/542,504 filed Oct. 4, 2023, each titled “Electrodynamic Parameters,” both of which are hereby incorporated by reference herein.

### TECHNICAL FIELD

Aspects of the present disclosure involve the computation of dynamic parameters from battery measurements such as voltage and current, the dynamic parameters including but not limited to Lyapunov Exponent, Correlation Dimension, Sample Entropy and Hurst Exponent, and/or representations or approximations thereof, the use of such parameters for various battery management tasks including charging, discharging, temperature management and others.

### BACKGROUND AND INTRODUCTION

Battery powered devices have proliferated and become ubiquitous. Device manufactures are constantly pressing for performance improvement in batteries, particularly as batteries are introduced into devices with relatively higher current demands and power needs. At the same time, consumers demand longer battery life, longer times between charges, and shorter charge times. As such, there is an ongoing and continuous need for improvements in how batteries are managed, charged and discharged to enhance performance.

It is with these observations in mind, among many others, that the various aspects of the present disclosure were conceived.

### SUMMARY

Aspects of the present disclosure involve a method, which may be to manage control of a battery such as through charging, comprising obtaining a value indicative of at least one of a dynamic state of equilibrium, periodic behavior, quasi-periodic behavior, chaotic behavior and random behavior of a battery, the value obtained from a voltage measurement or a current measurement from the battery; and based on the value, operating the battery to maintain the battery within one of the dynamic states.

The method may further involve wherein operating the battery to maintain the battery within one of the dynamic states comprises selecting the one of the dynamic states based on an association with at least one of battery safety, charging rate and rate of degradation. Operating the battery may comprise altering a rate of energy flux to or from the battery. For example, operating the battery may comprise ceasing charge or discharge. Altering the rate of energy flux may comprise altering a charge current to the battery or discharge current from the battery.

The value may be a Lyapunov Exponent.

The method may further comprise identifying a rate of change in the value, the rate of change associated with one or more of an onset of plating, degradation, thermal runaway, dendritic short, and oxidation; and operating the battery based on the rate of change.

In another aspect, a method of charging a battery may comprise obtaining at least one Lyapunov Exponent (LE) value associated with at least one harmonic component based on measurements from a battery; and generating a charge signal incorporating the at least one harmonic component.

The method of charging a battery of may further comprise identifying when the at least one harmonic component is associated with at least one of reducing cell degradation of the battery, increasing charging efficiency, optimizing heating of the battery or optimizing cooling of the battery.

The method of charging a battery may further comprise generating the charge signal comprising a plurality of harmonics from the at least one Lyapunov Exponent value, the plurality of harmonics associated with Lyapunov Exponent values of 0 or greater, in the case of lithium-ion batteries. The method may further comprise adjusting a magnitude of at least one harmonic of the plurality of harmonics based on its relative LE value as compared to other harmonics with a different LE value. In some instances, the relative LE value of the at least one harmonic is lower than the different LE value of the other harmonics, and the adjusting comprises at least one of increasing the magnitude of the at least one harmonic or decreasing a magnitude of the other harmonics. In some instances, the charge signal is composed of the plurality of harmonics.

In method may further comprise obtaining the at least one Lyapunov Exponent value based on a change in at least one of a temperature measurement or an impedance measurement. The method may further comprise obtaining the at least one Lyapunov Exponent value based on state of charge.

The Lyapunov Exponent value is obtained based on a probe signal applied to the battery. In some instances, the Lyapunov exponent value is obtained based on a probe signal comprising an active period and a rest period, the measurements taken using the probe signal, which measurements may be voltage measurement. The active period of the probe signal may include a charge portion at a charge current and the rest period follows the charge portion, the rest period including a period where there is no charge current applied to the battery. In some instances, the probe signal is a discrete chirp probing waveform. In some instances, the probe signal is a charge and/or discharge signal and may not include a rest period. In some instances, voltage may be measured while the battery is at rest (i.e., receives zero current) to obtain a measurement of the battery's state at equilibrium; this may be useful for measuring shelf aging or calendar aging (e.g., a cell's unavoidable degradation over long periods of time, or short periods of time when sitting at high temperature, for example) of the cell.

Another aspect of the present disclosure involves a method of charging a battery comprising obtaining a Lyapunov Exponent based on detrended measurements from a battery; generating a charge signal with a charge current magnitude; and altering the charge current magnitude based on whether the Lyapunov Exponent meets a dynamic threshold of the Lyapunov Exponent, the dynamic threshold indicative of a shift in dynamic behavior. The method may involve altering the charge current magnitude by increasing the charge current magnitude when the Lyapunov Exponent is greater than a lower bound dynamic threshold. The method may involve altering the charge current magnitude by decreasing the charge current magnitude when the Lyapunov Exponent exceeds a lower bound indicating a critical change in battery dynamics. In some instances, the critical threshold is 0.

The method may further involve triggering obtaining the Lyapunov Exponent based on a change in at least one of temperature, overpotential, open circuit voltage, dQ/dV or impedance. The method may involve obtaining the Lyapunov Exponent relative to a change in state of charge.

The method may involve applying a probe signal to the battery, the probe signal comprising an active period and a rest period, the detrended measurements taken when the probe signal is applied. In some instances, the probe signal includes a charge portion at a charge current and the rest period follows the charge portion, the rest period including a period where there is no charge current applied to the battery.

In some instances, altering the charge current magnitude comprises altering harmonic content of the charge signal.

Another aspect of the present disclosure involves a method of charging a battery comprising: Obtaining an electrodynamic parameter based on a measurement from a battery; and generating a charge signal based at least in part on the electrodynamic parameter; wherein to obtain the electrodynamic parameter at least one signal including battery voltage or battery current is used, and the electrodynamics measure the properties of 1 dimensional time series data directly and do not depend upon electrochemical equations, impedance, open circuit voltage or over potential. In various aspects of the method, the electrodynamic parameter is a Lyapunov Exponent, a Correlation Dimension, a Sample Entropy or a Hurst Exponent. In various arrangements, generating the charge signal comprises selecting a magnitude of a charge current based at least in part on at least one of the Lyapunov Exponent, the Correlation Dimension, the Sample Entropy, and the Hurst Exponent. Generating a charge signal comprises defining harmonic components of the charge signal, defining charge current magnitude, defining duty cycle and/or defining period.

Another aspect of the present disclosure involves a method of managing a battery comprising: obtaining a fractal dimension based on measurements from a battery; and when the fractal dimension meets a threshold, altering energy to or from the battery. The fractal dimension may be a Correlation Dimension, Sample Entropy, or Hurst Exponent. Altering energy to or from the battery may comprise discharging the battery. In some instances, the threshold is indicative of plating and discharging the battery dissolves plated material from an electrode of the battery. In some instances, the threshold is indicative of a rate of dendritic growth in a lithium metal battery and discharging the battery causes lithium of a dendrite to dissolve into an electrolyte of the lithium metal battery. Discharging the battery may involve one or more discharge pulses.

In some aspects, the method may involve obtaining a rate of change in the correlation dimension and discharging the battery based on the rate of change. In some aspects, altering energy to or from the battery comprises reducing charge current to the battery or ending charge. End of charge may be based on obtaining a rate of change in the correlation dimension and ending charge based on the rate of change.

Another aspect of the present disclosure involves a method of charging a battery comprising: obtaining a fractal dimension based on measurements from a battery; when the fractal dimension meets a first threshold, pausing charging of the battery or discharging the battery momentarily; and resuming charging the battery. The fractal dimension is from a correlation dimension. In some arrangements, when the fractal dimension meets a second threshold, at least partially discharging the battery before resuming charging the battery.

In some aspects, when the fractal dimension meets the first threshold, the method involves assessing whether the correlation dimension also meets the second threshold.

The method may further involve triggering obtaining the fractal dimension based on a change in at least one measurement from the battery, the at least one measurement comprising temperature, overpotential, open circuit potential or impedance. The fractal dimension may also be obtained periodically based on state of charge or some other measure.

To obtain the fractal dimension, the method may involve applying a probe signal to the battery, the measurements (e.g., voltage) taken when the probe signal is applied. The probe signal may comprise an active period and a rest period. The probe signal may include a charge portion, at a charge current and the rest period follows the charge portion, the rest period including a period where there is no charge current applied to the battery.

In some instances, the method may involve obtaining a Lyapunov Exponent based on the measurements from the battery; and when the Lyapunov Exponent meets a threshold indicating stability, not pausing or discharging. In some instances, when the fractal dimension meets the first threshold, discharging the battery is not undertaken below a preset state of charge.

Another aspect of the present disclosure involves a method of charging a battery comprising: obtaining a first correlation dimension based on measurements from a battery at a first time; obtaining a second correlation dimension based on measurements from the battery at the second time; obtaining a rate of correlation dimension change based on the first and second correlation dimensions; determining the rate of correlation dimension change is greater than a threshold rate; halting charging of the battery for a duration; and resuming charging of the battery after the duration. The method may further involve at least partially discharging the battery, e.g., through one or more discharge pulses, based on the determining the rate of correlation dimension change is greater than the threshold rate.

Another aspect of the present disclosure involves a method of charging a battery comprising: obtaining a correlation dimension based on measurements from a battery; and when a change in the correlation dimension meets a first threshold, generating a charge signal altering a charge current magnitude. The method may further involve, when the change in the correlation dimension is an increase in the correlation dimension exceeding the first threshold in the form of a high reference value, decreasing the charge current magnitude. The method may further involve, when the change in the correlation dimension is a decrease in the correlation dimension exceeding the first threshold in the form of a low reference value, increasing the charge current magnitude. In some instances, the method may involve triggering obtaining the correlation dimension based on a change in at least one of temperature or impedance. In some arrangements, the Correlation Dimension is obtained periodically based on state of charge.

Another aspect of the present disclosure involves a method of charging a battery comprising: obtaining a Sample Entropy based on measurements of a battery; and when the Sample Entropy meets a first threshold indicative of a temperature distribution, which may be irregular, in the battery, generating a charging signal or discharging signal responsive to the temperature distribution. The Sample Entropy may be obtained within a time window based on an inverse of a preceding value of Sample Entropy.

In some instances, the charging signal comprises a heating component. In some instances, the battery comprises a battery pack.

Aspects of the present disclosure may further involve a method of obtaining battery capacity comprising: obtaining battery measurements from changes in probing current magnitudes; obtaining fractional Brownian motion values from the battery measurements; when the probing current magnitude approaches a maximum safe capacity, identifying at least one of a plateau in the fractional Brownian motion values or a decrease in the fractional Brownian motion values; and identifying a battery capacity from a charge current of the probing current magnitude when the plateau in the fractional Brownian motion is reached or the decrease in the fractional Brownian motion occurs. The fractional Brownian motion values may be derived from Hurst Exponent values.

Another aspect of the present disclosure may involve a method comprising: obtaining a self-affinity metric from a battery measurement; and controlling a charge or discharge parameter based on the self-affinity metric. The self-affinity metric is based on a Hurst Exponent or detrended fluctuation analysis.

Another aspect of the present disclosure may involve dynamically charging a battery by obtaining a first value for a first electrodynamic parameter associated with behavior of a battery, comparing the first value to a first threshold value for the first electrodynamic parameter; and generating a charging signal for the battery based on the comparison of the first value to the first threshold value.

These and other aspects of the present disclosure are described in more detail in the discussion that follows.

### BRIEF DESCRIPTION OF THE DRAWINGS

The foregoing and other objects, features, and advantages of the present disclosure set forth herein will be apparent from the following description of particular embodiments of those inventive concepts, as illustrated in the accompanying drawings. It should be noted that the drawings are not necessarily to scale; however the emphasis instead is being placed on illustrating the principles of the inventive concepts. Also, in the drawings the like reference characters may refer to the same parts or similar throughout the different views. It is intended that the embodiments and figures disclosed herein are to be considered illustrative rather than limiting.

FIGS. 1A-1B illustrate current and voltage waveforms of a proving signal.

FIG. 2 is a diagram of PID control scheme using electrodynamic parameters.

FIGS. 3A-3B are Lyapunov Exponent diagrams for a battery cell at one cycle and 250 cycles, respectively, showing LE values at different SOC across a spectrum of harmonic frequencies.

FIG. 4 is a flowchart illustrating a method of managing a battery using an LE spectrum.

FIG. 5 is a plot comparing LE for a battery from 0 to 100% SOC versus dQ/dV for the same battery.

FIG. 6 is a plot of LE values based on cycle and SOC for a battery.

FIG. 7 is an ICA plot of dQ/dV values based on cycle and SOC for the battery.

FIG. 8 is a flowchart illustrating a method of managing a battery using LE values based of a detrended waveform.

FIG. 9 is a plot of correlation dimension values for a power cell at one cycle and at 250 cycles.

FIG. 10 is a plot of correlation dimension values for an energy cell at one cycle, 100 cycles and 250 cycles.

FIG. 11 is a charge current plot for the energy cell, at the same 1 cycle, 100 cycles and 250 cycles.

FIGS. 12A-12B are roughness profile plots.

FIG. 13 is a bar chart showing several descriptive parameters quantifying areal roughness, in which values for the power cell and energy cell are taken as a ratio Power/Energy (P/E) for the anode, cathode, and the average value of the two.

FIGS. 14A-14B are diagrams comparing impedance with correlation dimension.

FIGS. 15A-15B are diagrams illustrating correlation dimension as it relates to charged capacity and cycle efficiency for the same battery.

FIG. 16 is a flowchart of a method of managing a battery through pausing charge or discharging, which may serve to reverse plating, using the correlation dimension.

FIG. 17 is a flowchart of a method of controlling battery charge using the correlation dimension.

FIG. 18 is a plot of sample entropy for a 3 Ah battery at different temperatures across a full charge cycle 0 to 100% SOC.

FIG. 19 is a diagram of SE and SOC for a 3 Ah battery at 1 C, 3 C and 5 C charge rates.

FIG. 20 is a diagram of fractional Brownian motion and SE for a 3 Ah battery at 1 C, 3 C and 5 C charge rates.

FIG. 21 is a diagram of SE and battery surface temperature for a 3 Ah battery at 1 C, 3 C and 5 C charge rates.

FIGS. 22A-22B are comparative diagrams of d(SE) and dV/dT for a 5 Ah battery and a 3.3 Ah battery.

FIG. 23 is a diagram of cycle number and SOC for the 5 Ah battery.

FIG. 24 is a flowchart of a method of regulating battery heating and thermal gradients using SE.

FIG. 25 is a flowchart of a method of using SE to set cycle capacity.

FIGS. 26A-26B are diagrams depicting the relationship between fBM and rate of charge and temperature.

FIG. 27 is a plot of temperature (° C., surface), fBM, and SE together with several electrochemical measurements to demonstrate the relationship between electrodynamic and electrochemical data, which include dQ/dV and calculated diffusion coefficients (“D”, cm2/s) obtained from GITT measurements of a 3 Ah LIB 21700 power cell.

FIGS. 28A-28B are diagrams depicting fBM and cell temperature

FIGS. 29A-29B are diagrams of fBM from current and voltage measurements for a 5 Ah battery.

FIG. 30 is a plot of fBM and SOC for a battery at different cycles.

FIG. 31 is a plot of CD and fBM for a 3.3 Ah battery.

FIG. 32 is a plot of fBM and SOC for different positions within a cell across a full charge.

FIGS. 33A-33B are flowcharts depicting methods of assessing cell capacity using fBM for a charge or discharge sequence, respectively.

FIG. 34 is a flowchart of a method of determining usable battery capacity by way of fBM.

FIG. 35 is a diagram depicting ways to assemble a charge signal comprised of different harmonics.

FIG. 36 is a diagram of a computing system, which may be used alone or in part, to implement some of the methods discussed herein and compute the various electrodynamic parameters used as part of the methods discussed herein.

FIG. 37 is a series of plots illustrating surface temperature and reaction heat over State of Charge (SOC) at 1 C, 3 C, and 5 C rates for a new battery cell.

FIG. 38 is a series of plots illustrating surface temperature and reaction heat over SOC at 1 C, 3 C, and 5 C rates for an aged battery cell.

FIG. 39 is a series of plots illustrating surface temperature, ohmic plus reaction heat, and reaction heat alone over SOC for 0.5 C and 1 C rates.

FIG. 40 is a series of plots illustrating Lempel-Ziv complexity over SOC for 1 C, 3 C, and 5 C rates for new and aged cells.

FIG. 41 is a series of plots illustrating Dynamic Fluctuation Analysis over SOC for 1 C, 3 C, and 5 C rates for new and aged cells.

FIG. 42 is a series of plots illustrating Brock, Dechert, and Scheinkman (BDS) test values over SOC for 1 C, 3 C, and 5 C rates for new and aged cells.

FIG. 43 is a series of plots illustrating Lyapunov Exponent values over SOC for 1 C, 3 C, and 5 C rates for new and aged cells.

FIG. 44 is a series of plots illustrating Battery Entropy values over SOC for 1 C, 3 C, and 5 C rates for new and aged cells.

FIG. 45 is a series of plots illustrating Fractal Dimension values over SOC for 1 C, 3 C, and 5 C rates for new and aged cells.

### DETAILED DESCRIPTION

Aspects of the present disclosure involve a new understanding that electrodynamic and electrochemical processes in electrochemical systems, particularly rechargeable batteries, may be identified from what would normally be considered discardable data. In a general sense, “noise” in electrical systems is considered to consist of uncorrelated completely random signal data and is typically ignored or efforts are made to suppress or remove it. In the present application, however, signals that would normally be considered noisy are understood to contain information that may be associated with events occurring in the battery. The detection of such events and the manipulation of such signals, alone or in combination, may be further used to alter various actions on the battery such as charging or discharging. While aspects of this disclosure are discussed primarily in the context of battery charging and discharging, aspects of the disclosure are also applicable to other environments including electroplating systems.

The term “battery” in the art and herein can be used in various ways and may refer to an individual cell having an anode and cathode separated by an electrolyte, solid or liquid, as well as a collection of such cells connected in various arrangements. A battery or battery cell is a form of electrochemical device. Batteries generally comprise repeating units of sources of a countercharge and electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different types of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead-acid batteries, various types of nickel batteries, solid-state batteries, and flow batteries to name a few. The various implementations discussed herein may also apply to different structural battery arrangements such as button or “coin” type batteries, cylindrical cells, pouch cells, and prismatic cells.

To begin, an unfiltered signal, which may appear noisy, or carefully filtered signal is captured from the battery. Such battery measurements may be of voltage, current and/or involve derived or computed values from such measurements such as impedance. From a signal perspective, the voltage and/or current signals may be in time value pairs or other format showing a sequence of battery measurements, which may have a time component. Other measurements such as temperature are also possible. In terms of carefully filtering, for example, the system may include a filter or filters targeted at filtering out readily identified hardware or other forms of ancillary noise. Stated differently, the filter or filters may be set or defined to remove signal data that is known to be related to hardware and environmental contributions (e.g., thermal effects) and not be related to battery dynamics, such as internal battery electrodynamics. The signal may be captured during steady state (equilibrium), pseudo-steady state (as when charging or discharging a battery), and/or during a transition and/or immediately after a transition to a different state.

The battery measurements may be captured in the presence of or otherwise responsive to a probe signal. The probe signal may be a dedicated probing signal or may be a charge signal. The battery measurement signals may also be captured during discharge. In one specific example, the probe signal is a charge signal and includes transient portions and steady state portions. Regardless, the probing signal may include an active period (an active net change in battery charge) that rapidly decreases equilibrium (e.g., transitions to 0 Amps in the case of the current controlled device). The active period may also change to a different current or voltage magnitude, such as decreasing the voltage below a critical voltage threshold but not to cell equilibrium (e.g., below a hexagonal phase transition of an NMC cathode). The change in magnitude may also be to a different polarity. A probing signal may involve many transitions between each of these states for the purpose of comparisons in the resulting electrodynamic parameters computed from the measurements. The rate of change in the magnitude of a probing signal may be carefully controlled. In general, the probing signal is tailored to provoke and measure responses of various dynamic processes which may be present in the battery. Additionally, probing signals may be used to identify a battery's critical boundaries, such as when the battery dynamics transition from periodic to complex-periodic (quasi-periodic), or from the latter to an aperiodic and chaotic dynamical state, from random to quasi-chaotic, quasi-chaotic to chaotic or periodic, or any other change indicating a shift in dynamics. Probing signals may include harmonics associated with specific DC resistance or complex impedance responses of the battery (e.g., harmonics associated with the solid electrolyte interface (SEI) in a Lithium-Ion battery (LIB), as determined by electrochemical impedance spectroscopy (EIS)). Alternatively, harmonics associated with the charge transfer region, and to the specific avoidance of harmonics associated with diffusion-limited conditions.

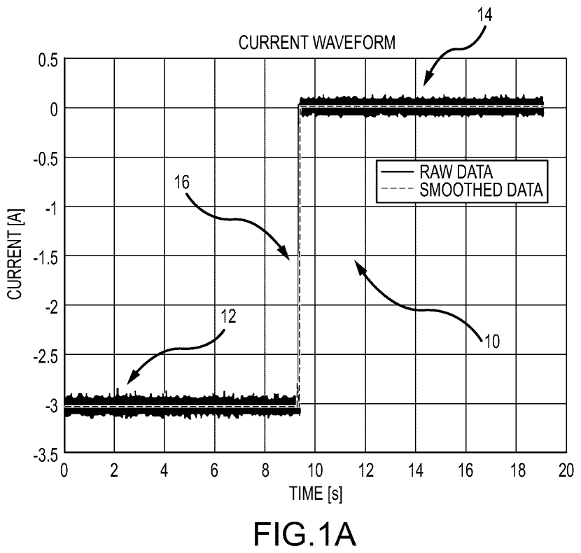

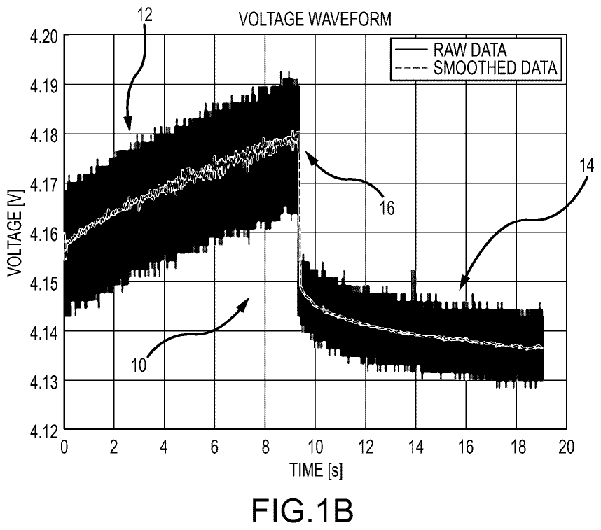

To provide further context, referring to FIGS. 1A and 1B in one particular example, the battery may be probed with a unipolar pulse waveform 10, where the current signal of the waveform is shown in FIG. 1A and the voltage signal of the waveform is shown in FIG. 1B. As noted, the probing waveform may be a charge signal or portion of a charge signal, may be a distinct probe signal, or may be initiated in conjunction with charging or discharging, or otherwise. In the example, the probing waveform involves a charging portion 12 and a rest period 14 with a transition 16 between the same. In the example, the duration (period) of the whole current probing waveform is 20 s including 10 s of the charging part and 10 s of the resting part. In the example illustrated, the magnitude of charging current is 3 A. The rest period may be at 0 Amps or some other non-negative albeit lesser value. It is also possible, to transition to a larger current. If the battery is under charge when the measurement is to occur, the charge current may transition to zero or some lesser value. As noted above, it should be recognized that the probing waveform may vary in duration, shape, the charging portion (or similarly discharging portion) and/or rest period may vary, and the current levels may vary depending on various factors including the type of battery and the type of parameter to be computed from the measurements.

Further, the energy flux through a battery may be sporadic as when a device is plugged in to a power source to charge while also being used by a user or hardware's sub-devices. The voltage and current signals from the battery will represent the dynamics of internal processes provoked by the sporadic power. In this case the signal may be examined as a whole, or in discrete sections of transition, with or without detrending, to characterize such dynamics, to better understand impacts to state of health of the battery, and to alter the charging signal (assuming the discharged energy isn't a controlled variable) to target a particular aspect of battery performance (health, rate, safety, temperature and heat flux, etc.).

In various possible aspects, various electrodynamic parameters, discussed in more detail below, involve parameter or parameter spectrum calculations based on a series of data over time (waveform) of a current, voltage, impedance, temperature, and/or other measurable information from a battery cell during its charging, discharging, probing, transition and/or resting phases. The collected data, which may be time series data and which may be representative of a waveform, can be generated from an active probing signal, or a section of a charge (or discharge) signal during a state or phase transitions of the battery, or immediately after such state or phase transitions.

The time series data (waveform) can be analyzed in the time domain, frequency domain, time-frequency domain, or any other format through domain transfer to generate spectra of interests for harmonic analysis. For some parameters, pre-processing of the raw time series data (waveform) can be implemented before parameter calculations, including detrending (removing trends), filtering, normalizing and scaling or other signal processing techniques in order to extract and/or isolate valuable information about the battery's condition from the data.

Aspects of the present disclosure involve the recognition that information obtained from correlated signal data is representative of electrodynamic affects within a battery and is useful in ways that parameters of electrochemical effects are not. In other instances, and as will be apparent from the discussion below, various electrodynamic parameters discussed herein may be correlated to behavior with the battery, and thus used to trigger some action (e.g., charge control) to stop, suppress, reverse or enhance whatever correlated behavior is detected. Such electrodynamic parameters include the Lyapunov Exponent (LE), the Correlation Dimension (CD), Sample Entropy (SE or SoE) and the Hurst Exponent (HE), and information, computations, statistical representations and the like that are representative of or correlated with such parameters. Other parameters may include BDS, Entropy, Capacity Dimension, Lempel Ziv Complexity and others.

As will be recognized from the discussion below, it has been found that such parameters are strongly correlated with various occurrences, such as lithium plating, within a battery during operation including charging and discharging but may also include other situations such as aspects of battery formation, and as such these parameters may be used to identify such occurrences and act on such occurrences, such as through altering charge or discharge characteristics and thereby have various beneficial effects including broadly related to increasing or otherwise optimizing rates of charge, increasing or optimizing cycle life, improving safety, decreasing the likelihood of battery damage and otherwise, which will be apparent from the discussion that follows.

Depending on any given implementation, various methods of the present disclosure may be implemented with various possible controllers or other hardware arrangements including a PID controller or a model predictive controller such as discussed in U.S. patent application Ser. No. 18/232,331, titled “Model Predictive Controller Architecture and Method of Generating an Optimized Energy Signal for Charging a Battery” filed on Aug. 9, 2023, which is hereby incorporated by reference, or otherwise. In an MPC, the battery model may need to include electrodynamic parameter modeling, which can then be compared to real-time measurements of such parameters as discussed herein and used to provide control of charging and other battery management, while also accounting for SOH, charge rate, temperature, or other controls.

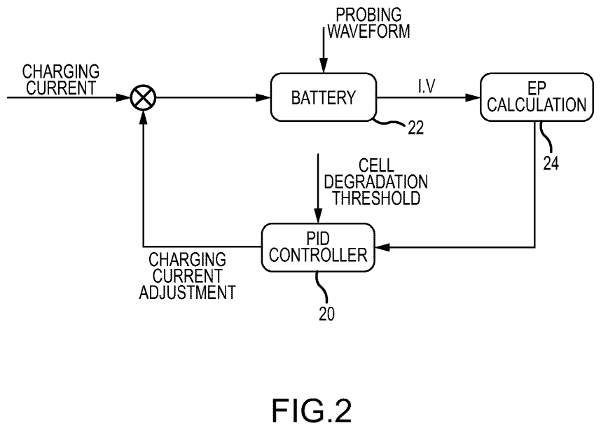

Given the information presented above, an example of a system for controlling charge of a battery is shown in FIG. 2. The controller is configured to control charging based on real-time electrodynamic parameter (EP) feedback. In general, the controller implements a method of real-time monitoring of a cell characteristic, which may be correlated to an electrodynamic parameter (or parameters), through obtaining an electrodynamic parameter calculated from information gather from a probing waveform to adjust charging current dynamically, optimizing battery performance and extending lifespan. The method and variations of the same can be implemented in other controllers, with FIG. 2 presenting one possible example.

FIG. 2 shows block diagram of the feedback controller 20. The probing waveform is applied to the battery, the current and voltage probing waveform are used to calculate an electrodynamic parameter (or parameters) 24, which will be sent to a proportional-integral-derivative (PID) controller 26 as inputs. In one example, in the case of running the PID loop based on computed LE electrodynamic parament, a threshold is set as a target value (e.g.,-0.1 for an LE parameter (noting whether LE is positive or negative may depend on whether LE was normalized or other data processing occurs) for the PID controller. In various possible implementations, the target value may be set based on the electrodynamic parameter being assessed. Based on the difference between the calculated parameter value and the target value, the PID controller may output an adjustment to the charging signal and applies the optimal charging current to the cell. The charging signal adjustment will depend on the type of parameter being assessed and the correlated behavior in the battery and any thresholds established to such correlated behavior. For example, if the LE threshold s correlated to lithium plating, then the charging current adjustment may trigger a charge current reduction, a momentary rest period, and/or a discharge returning to some charge condition, all meant to stop plating or possible alter the effects of plating. Additional details of various techniques, parameters, correlations to battery states, and the like are discussed in more detail below.

The following discussion provides detailed discussions of various electrodynamic parameters, how those parameters are correlated to battery characteristics, and how the information can be used in battery management.

### Lyapunov Exponent

The following discussion addresses the Lyapunov Exponent (LE) electrodynamic parameter. The Lyapunov Exponent is a mathematical concept used to measure the sensitivity of a dynamical system to small perturbations. It is a measure of the average rate of divergence or convergence of nearby trajectories in phase space, where phase space is the space of all possible states of the system.

The system can estimate LE from a voltage waveform V(t) (e.g., voltage measurements related to a probe signal or otherwise as discussed herein noting that current or other measurements may also be used to generate LE values) by the following steps:

Step 1. Embedding: The system first embeds the time series v(t) into a higher dimensional space (m dimensions) using lagged values:

$$X ( t ) = ( V ( t ) , V ( t + Δ t ) , … , V ( t + ( m - 1 ) Δ t ) )$$

where Δt is the time lag.

Step 2. Neighbor Selection: The system then identifies nearby initial conditions in the embedded space, represented by vectors X_i(t) and X_j(t). These represent similar states of the system at a specific time (t).

Step 3. Trajectory Divergence calculation: The average rate of divergence between these trajectories is captured by the largest Lyapunov exponent (λ₁). The system can estimate it by calculating the average exponential separation distance between nearby points over time (t and t+Δt):

$${λ}_{1} \approx lim\_ ( Δ t -> 0 ) ( 1 / Δ t ) * ln ( ‖ X\_i ( t + Δ t ) - X\_j ( t + Δ t ) ‖ / ‖ X\_i ( t ) - X\_j ( t ) ‖ )$$

where ∥⋅∥ denotes the norm (distance) between vectors.

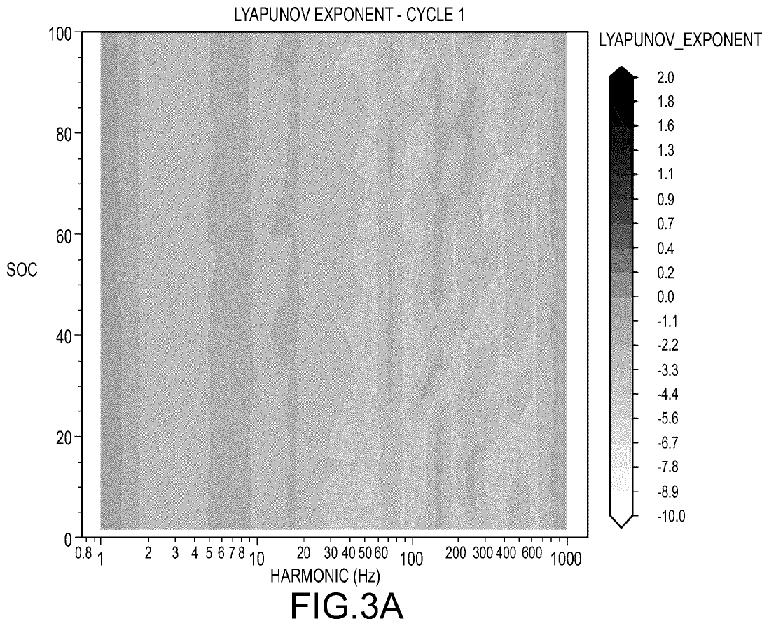

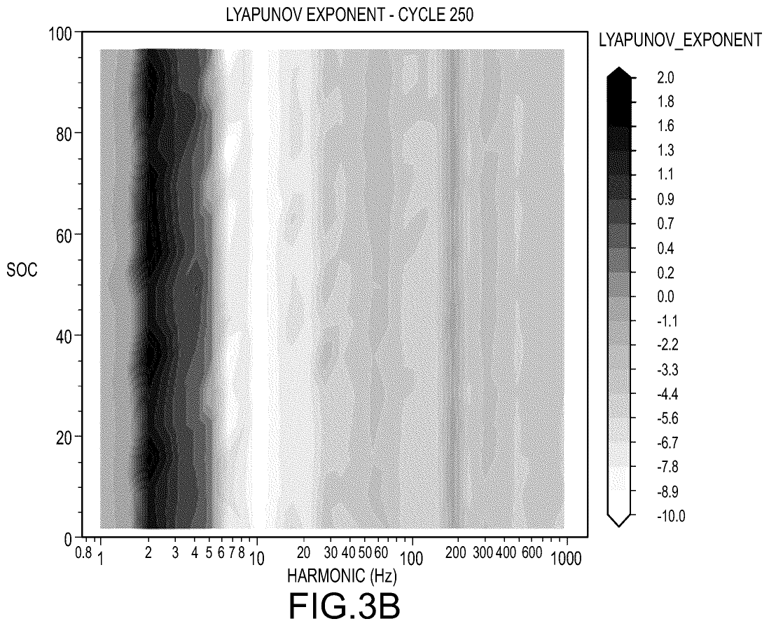

Turning to examples of using LE, for a 3 Ah 21700 lithium-ion battery, the LE computed from a battery voltage signal is shown in FIGS. 3A and 3B as a function of state of charge (SOC), and harmonic content of the charging signal or probing signal. The first diagram (FIG. 3A) has data for the first cycle of the battery, and the second diagram (FIG. 3B) shows data for the 250^{th} cycle of the battery. To generate LE values, for each harmonic assessed, a separate voltage waveform (time series) was applied, which may be a probing waveform, and gathered to compute the LE values.

In Cycle 1, the data shows LE values of 0 or less across the harmonics (1 Hz to 1000 Hz) analyzed, indicating the expected stability of the cell's dynamics under the charging conditions tested. It is understood that an LE value of 0 or less are stable and, for example, associated with little or no lithium plating. There are many frequency and SOC-dependent zones which offer higher stability and system equilibrium (more negative) than others. While the data suggests some level of stability across the harmonics analyzed due to LE values of 0 or less, removal of harmonics from the charging or discharging signal which are relatively less stable may nonetheless support the dominance of intercalation over side reactions, aging modes, and irregular current distribution throughout the cell. For example, harmonics in the range of 30-60 Hz are relatively more stable than harmonics in the range of 5-10 Hz, and hence the system may generate a charging signal composed of harmonics between 30 and 60 Hz. Other harmonics may also be considered for inclusion or exclusion given the data, and the representative ranges are chosen here merely for discussion.

By Cycle 250, after a capacity loss of ˜3.5%, the variations in system dynamics reflected in the LE measurements are greater and more indicative of side-reactions, particularly within the harmonic range of ˜2-5 Hz where the LE values are positive, and some are strongly positive. In this harmonic zone, the dynamics are more chaotic and sensitive to the other parameters of the battery and its environment. Thus, for example, the system may generate a charge signal without such very low frequency harmonics in the range of 2-5 Hz.

In one possible arrangement, a system may obtain such LE spectra, and determine which harmonics are more favorable, and use that information to construct a charge signal composed of harmonics associated with stability and/or avoid harmonics associated with instability. Such spectra calculation may be done through characterization of batteries and charging signals preconstructed based on the same and/or such analysis may be done on a schedule or in real-time while using the battery (e.g., during charge), and the charge signal modified on the schedule or in real-time in such situations.

These interpretations change when the data is collected from a charge signal which is stopped, or an actual pulse, and the data is NOT detrended. When the data collected from a falling edge, such as the falling edge of a probe signal or when charging is discontinued for a short period, is not detrended, the values tend to all be below 0 (negative). This is because the dynamics are highly non-stationary and seem much more linear (the drop is linear). In this case, we look for shifts in the magnitude of the data and an increase in non-linearity may actually manifest as an increase in negative magnitude even though this is counter to the detrended interpretation. As the current decreases and the magnitude of the falling edge decreases, we see the data tend towards 0, which is really just because the non-stationary effects are decreasing, making the data look and behave more like detrended data.

All electrodynamic parameters (e.g., LE, CD, SE and HE) may be based on instantaneous voltage, current, temperature and impedance waveform during phase transition of the cell during charge or discharge.

In general, as a battery ages, the dynamics may become increasingly complex and require ongoing adjustments to the harmonics which are included in the charging signal.

### Examples of Using LE to Manage a Battery

### Creating an Optimal Charge Signal Based Upon Harmonic LE (AC-Type Charge Signal)

The LE values in the data above (FIGS. 3A and 3B) are measured as a means of understanding which harmonics to include (and/or exclude) in a charging signal. Such measurements may be done on some relatively continuous schedule or otherwise. However, in another alternative, rather than making the measurements continuously and computing the LE values from the same, which would require more intensive computational capabilities, the analysis is made only occasionally on a time basis (e.g., every 1 minute or every 5 minutes), based on change in SOC (e.g., every 1% change in SOC), and/or based on some trigger. For example, alone or in combination with other changes, battery measurements and LE computations, and any change based on the same, may be triggered based on a change in other charging metrics such as temperature, anode overpotential, impedance, or a signal from an auxiliary Battery Management System (BMS) to conduct the LE analysis. In these scenarios, hardware with less memory and processing capability, and which more economical hardware and product cost, may be implemented to control the charge process.

In one possible implementation, and referring again to FIGS. 3(A) and 3(B), during the first cycle at 5% SOC, the system may generate a charge signal that includes harmonics between 30-60 Hz so as to maintain the highest stability and equilibrium throughout the cell, favoring optimal diffusion and intercalation at the anode, and with the least probability of inducing side reactions including lithium plating, electrolyte breakdown, and thermal gradients. Here, the harmonic range is associated with LE values of −3.3 or less. Other harmonic ranges are also available with such LE values. In any given instance, depending on the amount of power needed to generate to achieve some charge parameter, more or less harmonics might be included.

To generate a charge signal composed of such harmonics, frequency domain signals for each harmonic may be transformed into the time domain and combined to form a charge signal. One example of systems and method for controlling charge signal harmonic content is described in in co-pending U.S. patent application Ser. No. 17/473,828 (publication 2022/0085633) titled “Systems and Methods for Harmonic-Based Battery Charging,” filed Sep. 13, 2021 and published on Mar. 17, 2022, which is hereby incorporated by reference herein. The techniques and system described therein may be used in various embodiments discussed herein, and in relation to the various ways to generate the harmonic content discussed in detail herein. In other examples, the harmonics could also be applied and regulated according to a modulation scheme. In an example, imagine that you have a function comprised of healthy and stable harmonics, f(time)=sine(30×)+sine(31×)_sine( . . . 60×), and that you then multiply f(time) by a pulse function with a duty cycle of 25%. The result is that the harmonics are applied at full strength for 25% of the time, and diminish to zero at some rate according to the pulse shape and timing properties.

Still during the first cycle but now at 60% SOC, the bandwidth of greatest stability has decreased from 30-60 Hz to about 45-60 Hz. In one example, the system may generate a charge signal composed of such fewer harmonics in the relatively smaller bandwidth. However, depending on a target charge rate—e.g., 1 C, 2 C, 3 C, etc., the charging system may not be able to achieve a target charge rate with the lesser range of harmonics. For example, the charge energy from a charge signal comprised of some number of harmonics may not have enough energy to meet the charge rate requirement. In such a situation, the system may accept the reduced charge rate or adjust the charge signal in some way to provide relatively greater charge energy. In the example of FIG. 3A, the system may select additional harmonics associated with greater LE value albeit values still at 0 or less than zero. Thus, there is flexibility in selecting and scaling harmonics and how the selection overlaps with other charging constraints such as charge rate. Other constraints may include capacity degradation, safety and the like, with the system optimizing and prioritizing different constraints depending on any particular charge scenario. To maintain the charge rate as a priority, any device incorporating the charge technique discussed herein may be arranged accordingly. To meet the charge rate priority, the charge signal is further modified to also include harmonics extending down to 25 Hz. The range from 25-45 Hz induces relatively less stable dynamics within the cell as compared to 45-60 HZ, but the resulting degradation, if any given that the LE value is still negative, will not prevent the cell and product from achieving the desired cycle and operational life. Further, the magnitudes of the less optimal harmonics are adjusted and generally smaller than the higher range more optimal harmonics so as to minimize the instabilities while achieving the targeted charge rate.

As the cell continues to age and degrade with ongoing use, and as notable changes in temperature, overpotential, or impedance (among others) occur, the harmonics of the charging signal are similarly adjusted to maintain stable system dynamics.

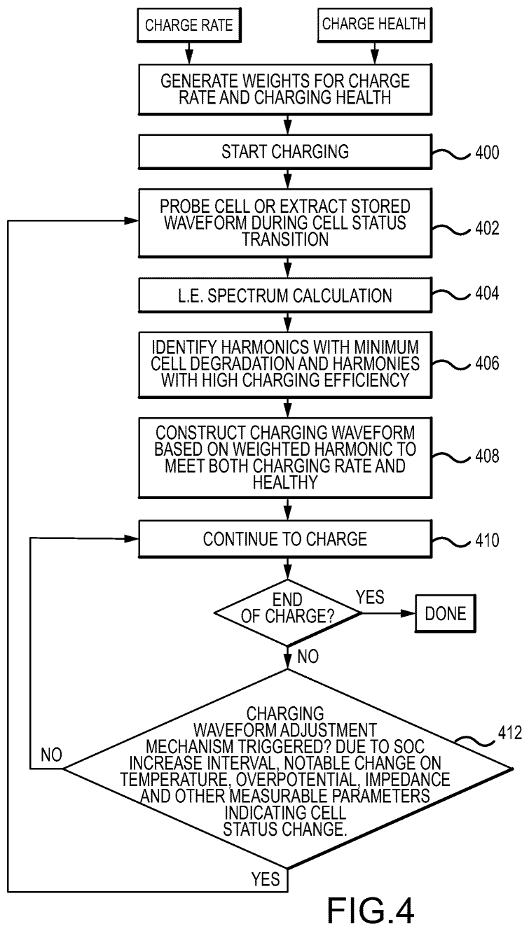

A method of managing a battery cell, including defining a charge signal responsive to LE, is shown in FIG. 4. To begin, in some embodiments, criteria such as state of health and charge rate may be used to define charge parameters, and these values may be weighted to prioritize charging to account for them based on weight.

The method may occur during charging (operation 400) or may occur prior to charging being initiated or during discharge. In any event, assuming the method is occurring during charge, as noted above, to obtain LE, battery measurements may be obtained from a probe signal (operation 402) or taken during some charging transition (e.g., a transition to a rest period from active charging), or a stored measurement waveform may be accessed. From measurements taken from the probe signal, a LE value or values, which may be used to generate an LE spectrum, may be generated (operation 404). The LE spectrum may be association between LE values and harmonics. As noted above, various harmonics may be related to various LE values, from which one or more harmonics may be identified to be included and/or suppressed in a charging signal (operation 406). A charging signal may then be generated that is composed of one or more identified harmonics and/or does not include one or more identified harmonics (operation 408). Charging may then continue with the defined charge signal until end of charge (operation 410) or some other state change (operation 412) that triggers a reassessment of the LE spectrum and redefinition of the charge signal (operations 402-408).

### Measuring Critical System and Component Transitions During Charging

Incremental Capacity Analysis (ICA, commonly presented as dQ/dV), conventional overpotential analysis, and impedance analysis are all useful metrics for understanding battery State of Health (SOH) and State of Charge (SOC). However, challenges and limitations exist for their reliable measurement, interpretation, and actionability toward understanding how to optimize a battery's safety, stability and performance enhancements, whether considering various batteries including an individual battery cell or a battery pack.

ICA or dQ/dV can show the phase changes which occur in the anode and cathode as lithium intercalates from one to the other. The phase changes can be used to identify an unknown anode or cathode composition based upon the position and magnitude of such changes. And, as the cell ages, the changes in peak position and height can be used to monitor degree of degradation. It is not perfect and a battery can still function even when peaks have disappeared. Peaks can disappear when phase changes no longer occur at discrete voltages and instead occur at varying rates at different spatial positions within an electrode. Conventional ICA data must typically be obtained from very slow charge or discharge rates, typically C/2 or less, otherwise the responses normally detected become convoluted. Convolution also occurs once the cell has experienced a small amount of aging due to a shift toward gradated activity in the cell rather than the more uniform transitions which occur when a cell is new. For example, an unaged cathode will alloy and dealloy with lithium in a relatively uniform rate throughout its bulk material, whereas an aged cathode may become oxidized or impeded at the electrolyte interface as compared to the interior, resulting in different kinetics and diffusive characteristics.

Impedance measurements reflect relative changes in the cell response to electrical stimulus, but this data, and certainly the absolute values measured, are best understood and actionable when the cell or pack is well characterized ahead of time and with behavior conforming to a reliable, statistical distribution, equivalent circuit model, or descriptive physics model. Faster rates of charge and discharge, as well as environmental conditions can disrupt this conformance, even in a well-studied system, which is typically handled by implementation of a strong model describing the battery deployed in a battery management system. However, even in such cases, the management by the BMS is usually defensive (geared toward safe operation or maximizing cycle performance, for example) rather than performance-enhancing in nature.

Impedance and overpotential measurements are more useful when they are representative of the anode or cathode, specifically, whereas the measurements which are obtained at the cell or pack level are a convolution of all the internal, inline components. The magnitudes and positions (vs SOC, Voltage) of ICA and overpotential measurements are strongly and collectively dependent upon the electrode of interest as well as its opposing electrode, which, for example, means that ICA peaks associated with phase transitions at the anode can become altered as the cathode ages, even as the anode remains relatively stable. This is one reason why ICA becomes difficult to obtain as the cell is even moderately aged.

State of the art albeit conventional practices to understand isolated anode activity, including anode overpotential, are based upon the development of refined models from empirically derived information, equivalent circuit models, P2D models, and thermal models among others. In accordance with aspects of the present disclosure, in contrast, by understanding when electrodynamics indicate increasingly divergent behavior due to the onset of lithium plating at the anode (anode voltage of a lithium-ion battery may become 0 or negative), or when a critical temperature boundary may be near, a charging system may employ a relatively more optimal single or multi-step charge profile which better protects the cell's health during use while similarly meeting other charge requirements or goals such as charge rate.

Electrodynamics provides a means of observing and better quantifying shifts in the phase change behavior of the electrodes regardless of the charge or discharge rate applied, and charging or discharging protocol employed, and whether or not the voltage is held steady (dQ/dV=infinity). Phase changes refer to structural shifts in the crystal structure of the cathode and anode. Shifts usually occur between two semi-stable crystal structures.

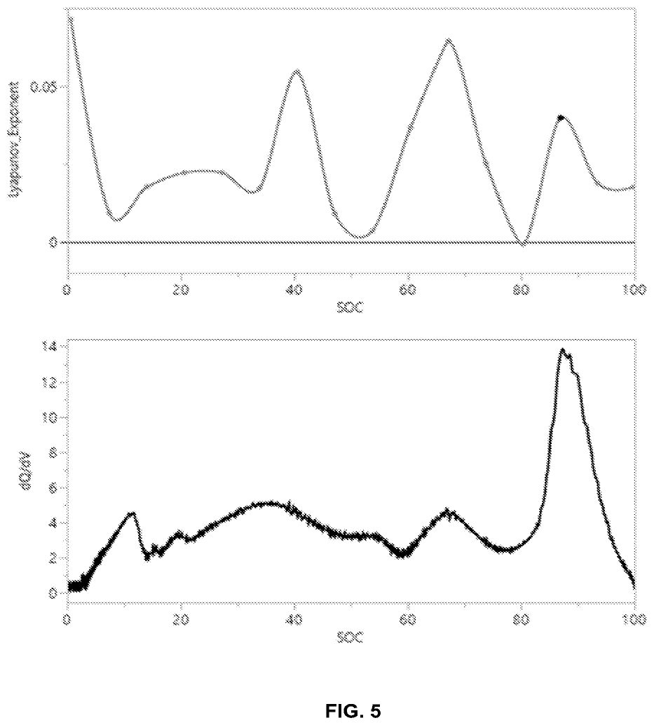

In FIG. 5, comparing dQ/dV and LE data, an NMC cathode experiences a change in anode crystal structure from graphite (C6) to lithiated graphite (LiCx) ˜3.45V. Around 3.65V, the cathode experiences a change from Hexagonal to Monoclinic crystal structure (H1->M), and so on. These changes can be used to identify the electrode composition and general health, at least to a point. The data in FIG. 5 is an example of monitoring the time series data of the charge voltage signal and calculating the Lyapunov Exponent to better understand cell dynamics and electrode phase changes.

The plots show how the LE can be used to robustly observe phase changes and understand their dynamic significance, which provides actionable feedback for controlling the charge current. The bottom ICA curve is collected from a new 3 Ah 21700 Lithium-Ion Battery (LIB) at a charge rate of C/10. This is done because ICA information is incoherent above C/2 at Cycle 1, and above C/5 for an aged cell at Cycle 200 (approximately 20% of the cell's intended useful life). The top LE data is applied minimally (infrequently), containing only 16 data points as opposed to the thousands of measurements reflects in the ICA curve.

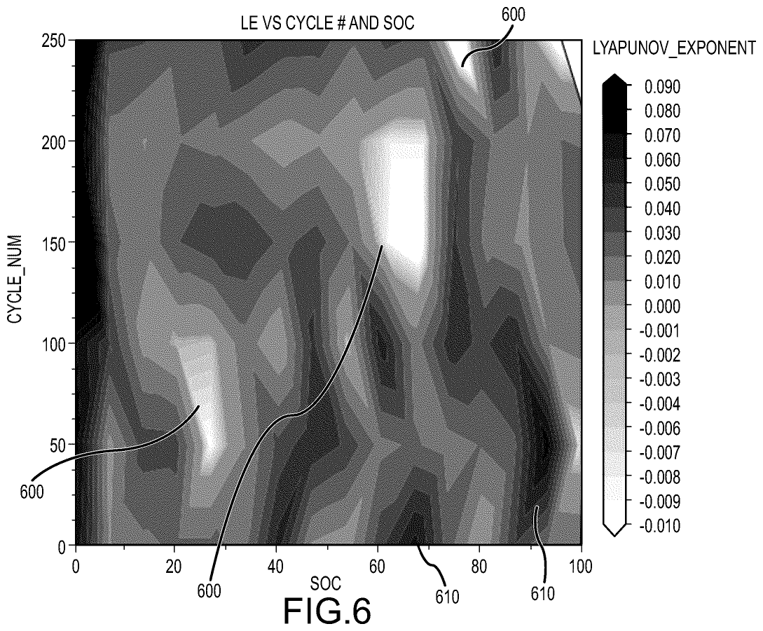

In one instance, the LE curve is used to understand how to regulate the charging current and simultaneously estimate State of Health of the cell. Higher values of the LE, which indicate increasingly chaotic dynamics and non-linear processes, command the charge controller to decrease the current so as to bring the system back toward stability. Non-linear dynamics reflect higher activity from side reactions including irregular spatial current distribution, electrolyte gasification, etc. When the cathode is dealloying lithium, ion diffusion, and intercalation are occurring optimally and more sequentially, the dynamics are more linear and stable in nature as per the intended design of the cell. As the LE values return to lower magnitudes, the charge current may be cautiously (e.g., with relatively small increases (e.g., 10% or 20%), or predictively by the PID controller or other control such as a model predictive controller) to continue meeting a target charge time. The plot of FIG. 6 (LE values as compared to cycle count and SOC) shows how adjustments to the charge current require regular modification rather than a fixed charge profile to maintain stable system dynamics and achieve highest possible charge rates and best protection of cell health. Notably, it can be seen that there are areas of stability (600 (0 and lower LE values) related to optimal charging as compared to areas of instability (620 (positive LE values), and those areas change depending on SOC and cycles. By using LE an optimal charge protocol may be obtained without any a priori knowledge of the cell, including models or empirical information.

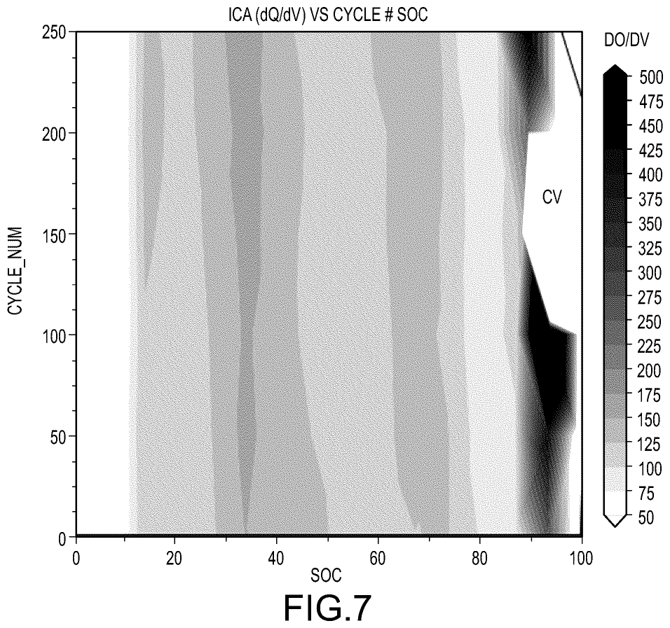

In a different instance illustrated in FIG. 7, the charge current is instead similarly controlled using measured ICA data. The charge current is periodically interrupted in order to achieve a slower “measurement” signal to make reliable conventional dQ/dV assessment feasible. This has the effect of greatly increasing the overall charge time even though the charging currents are the same as in the previous instance.

In this case, in two different tests in which the charge controller regulates current based upon both proportional and inversely proportional relationships to ICA values within the same total current range as the first instance (FIG. 6), both outcomes lead to notably different charge profiles on a cycle to cycle basis, and cycle lifetimes lasting ˜24-36% of that of the first instance. Further, the mechanism of feedback is disabled when the cell reaches its maximum allowable voltage, as no dQ/dV information can be collected even when the smaller measurement signal is applied.

In general, LE is more reliable and maintains accuracy and measurability as the cell ages. LE provides an absolute scale by which to respond with charge signal changes (e.g., current changes) in a proportional manner. In contrast, dQ/dV peak variations are relative to the cell configuration and magnitudes are not in proportion to an optimal change in current or voltage. LE is a powerful parameter to compare with impedance and ICA measurements to make better decisions. For example, with an unknown cell we can measure changes in impedance but don't really know whether the values are healthy or not until we've performed extensive cycling tests. LE can help us immediately understand when impedance values are healthy or unhealthy without extensive cycling. LE is inherently better suited to analysis and charge signal control during fast charge. As dQ/dV becomes inaccurate or immeasurable with fast rates, LE is suited to capture the increase in complexity of cell dynamics. Additionally, using LE extends cycle life than ICA for charging current regulation. LE can also work at CV (constant voltage) stage, whereas ICA data cannot be obtained.

In the first instance, the LE provides a reliable and accurate means of assessing cell dynamics as the cell ages despite no a priori information, making the measurement truly cell and pack agnostic. Whereas in the second instance, dQ/dV is fundamentally biased based upon the configuration of the cell or pack due to dominating impedance effects. In the second instance, ICA could not provide a quantifiable and reliable indication of system dynamics needed to fully protect SOH.

Electrodynamic analysis is inherently suited to identify and describe a broader range of dynamics than EIS and NLEIS (non-linear EIS). EIS is dependent upon the Fourier Transform and its subvariants such as FFT, which are limited to describing signals with periodic and stationary properties. EIS uses periodic, sinusoidal probing signals (or in rarer cases, probing signals with tailored bandwidths which are later transformed into the frequency domain) to stimulate linear responses in a cell. As the probing magnitude becomes too large, the batteries response will be non-linear and the resulting impedance analysis will lose accuracy. State of the art advancements have focused on developing more complex equivalent circuit models (ECM) or physics models to allow EIS to more reliably interpret nonlinear responses from a battery. This allows larger signals to be used which better approximate realistic charging or discharging magnitudes, and may also allow some nonlinear dynamics to be identified. However, the analysis proceeds on a per-harmonic basis which rapidly becomes resource intensive, and with limited reliability. Some of the error lies in the limited degree of nonlinear response accurately described by models, and also with the inherent limitations of FT. A battery is inherently non-stationary during charge and discharge, and particularly so at fast rates, or in cases when the battery is sporadically charging and discharging, such as when a device is plugged into a power source to charge while also being used by the user. Many batteries in a pack also increase in non-stationary behavior. Despite state of the art and ongoing adaptations to EIS that may develop, the method is fundamentally ill-suited to describing non-linear dynamics and unable to deconvolute chaotic and random dynamics.

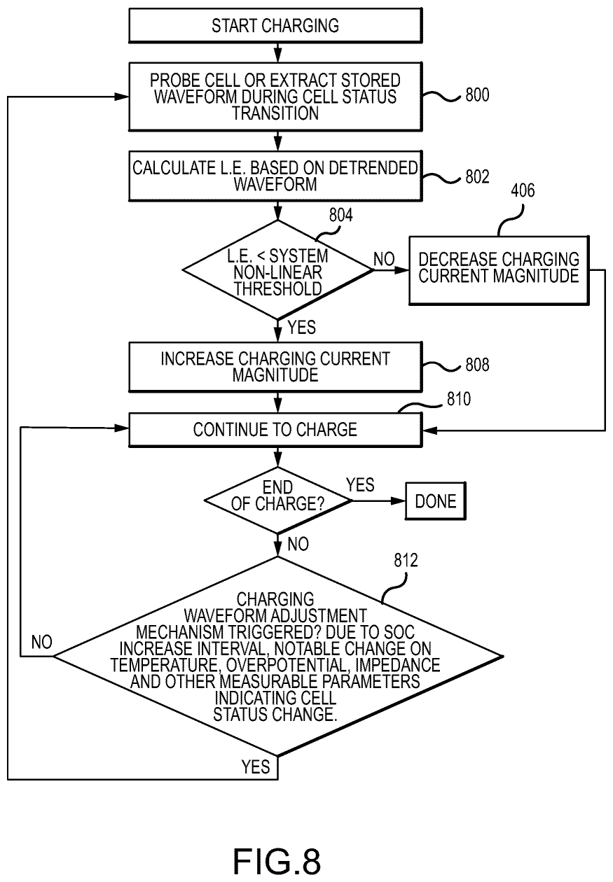

FIG. 8 illustrates another method of charging a battery using LE. After charge is initiated, which may be a constant current or other charge signal, the battery cell is probed (operation 800) or otherwise battery measurements are taken at or during transition from which LE may be computed (operation 802). Here, the LE data is detrended.

In the method of FIG. 8, the LE value is compared to a threshold associated with non-linearities in the battery (operation 804). If the LE value indicates non-linearity (e.g., a threshold of 0), the system may reduce the charging signal magnitude (operation 806). In general, non-linearities may be avoided by staying at or below an LE value of 0. So, in the case of a constant current scheme, the charge current magnitude may be reduced. In some form of intermittent charging scheme, the average charge energy per charging sequence may be reduced. If, on the other hand, the LE value does not indicate non-linearity, then the charging signal magnitude may be increased (operation 808) or not changed.

Charging will proceed until end of charge (operation 810), which may trigger a constant voltage sequence, or charging to halt, or may continue until some state change in the battery indicating LE should be reassessed (operation 812). For example, LE may be reassessed on a time schedule, based on SOC (e.g., every 1% SOC, every 2% SOC, every 5% SOC, or every 10% SOC), due to temperature change with the cell (e.g. a 1 C, a 1.5 C, a 2 C, a 2.5 C or other temperature change), a change in impedance, an indication of a change in overpotential, or reassessed due to some other state change, where operations 802-810 are performed, and the charge signal magnitude may be reassessed.

Aspects of the present disclosure involve the recognition that electrodynamic parameters are suited to identify and quantify linear dynamics as well as non-linear periodic, chaotic and random processes and the recognition of the integration and use of such information to understand battery states and control charging. So much so that many electrodynamic parameters directly describe system dynamics without the use of any model or a priori knowledge of the system, providing many advantages over various conventional techniques discussed above.

### Correlation Dimension

The correlation dimension quantifies the complexity of a system's dynamics by analyzing how similar nearby points in the data space are to each other. Here's how the system can estimate CD from a voltage probing waveform V(t) (noting other probes such as current or measurements taken during charge may be used):

Step 1: Embedding: The system first creates an embedding dimension (m) by constructing m-dimensional vectors from the time series data. For the voltage probing waveform, V(t), this can be done by creating vectors like:

$$X\_i = ( V ( t\_i ) , V ( t\_i + Δ t ) , … , V ( t\_i + ( m - 1 ) Δ t ) )$$

where Δt is the time lag between data points.

Step 2: Correlation Integral: The system then calculates the correlation integral, C(ε), which essentially counts the number of data points within a distance (ε) of each other in the embedded space. This can be estimated by:

$$C ( ε ) = ( 1 / ( N - ( m + 1 ) ) ) * \sum \sum \vert ( ‖ X\_i - X\_j ‖ \leq ε )$$

where N is the total number of data points, I is the indicator function (1 if true, 0 otherwise), and the summation goes over all possible pairs of data points (i≠j).

Step 3: Log-Log Plot: Finally, the system plots the correlation integral on a log-log scale versus the embedding dimension (ε) and performs a linear regression. The correlation dimension (D_2) is estimated by the slope of this regression line:

$$D\_ 2 \approx lim\_ ( ε -> 0 ) d ( log ( C ( ε ) ) ) / d ( log ( ε ) )$$

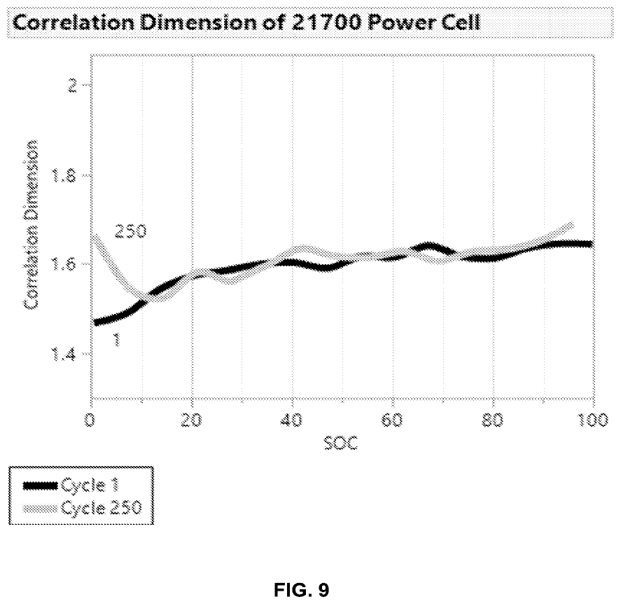

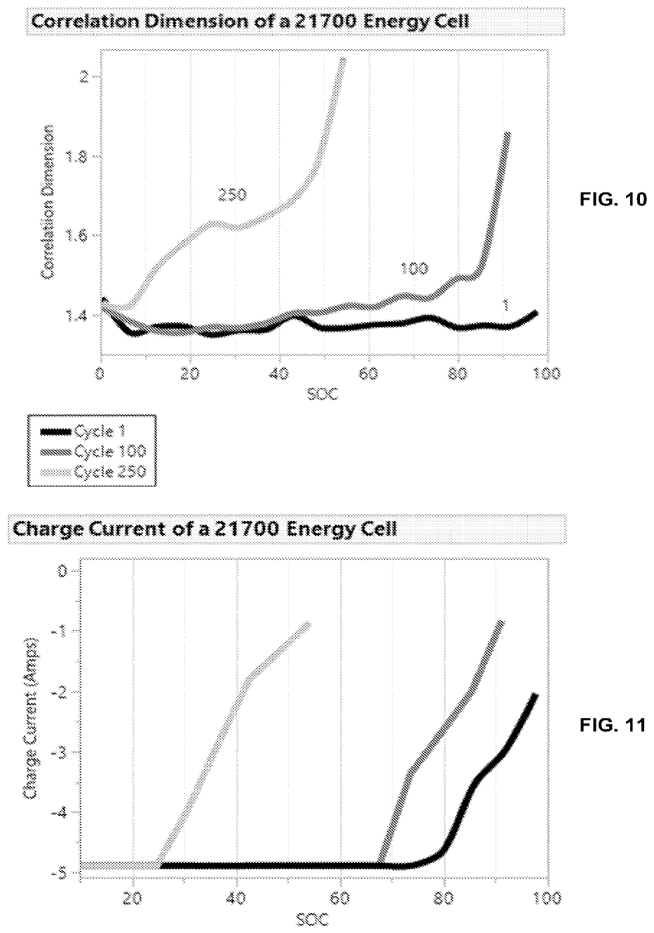

Turning now to examples of using CD, FIGS. 9-11 compare the fractal dimension calculated by the Correlation Dimension (CD) for a 21700 format 3 Ah lithium-ion cell (power cell) (FIG. 9), and a more energy-dense 21700 format 5 Ah cell (energy cell) (FIGS. 10 and 11) with electrodes which are more than 2x greater than the former.

The graph of CD in FIG. 9 shows that the power cell may be charged at 2 C for at least 250 cycles without incurring any notable changes in the fractal dimensionality of the internal components, despite ˜5% capacity loss during usage. The data also suggests that by 250 cycles the structures of the internal interfaces are roughened after discharge, but that the cell recovers to its nominal structure by 10% SOC (represented by the initially higher CD value decreasing to 10%). The CD values between 0 and 10% coincide with known changes in the SEI of lithium-ion cells and the notably higher impedances of cells ˜0-10% SOC.

In contrast and as shown in FIG. 10, as the energy cell is charged at a 1 C rate, the CD indicates a stable interfacial structure for all SOC values only during early cycles. By cycle 100, the structure increases gradually in dimensionality above ˜40% SOC, and sharply so above 83% SOC. The gradual increase may be due to SEI growth and even a degree of planar plating, whereas the sharp portion indicates dendrite formation. This correlates to the 8% capacity loss experienced to that point. By cycle 250, the cell has lost 46% capacity and the fractal structure and severity of lithium plating increases dramatically. This information indicates that the CD parameter may be used to control charging when such changes in the same are identified, and thus avoid or mitigate issues associated with SEI growth, planar plating, and dendrite formation.

The plot (FIG. 11) showing charge current can be compared to the CD plot (FIG. 10) to show that for cycles 100 and 250, the start of the voltage-limited (CV) period (the inflection points in the charge current curves) of a conventional CCCV scheme and subsequent decrease in current is insufficient to stop increases in fractal structure of the interfaces. This exemplifies why CCCV, multistep-CCCV and pulse charging which follow a constant current/constant voltage format cannot be used to entirely prevent plating without a margin of error, and why cells frequently experience dramatic losses in capacity beyond a certain degree of aging. Under conventional charging regimes, plating, capacity loss, and dendrite formation, even if avoided early in the number of charge cycles or at lower SOC, may still be prevalent in later charge cycles and/or at higher SOC. The present technique may be better at avoiding plating, more than conventional techniques like CV operation at the end of charge to avoid plating, and extend cycle life and avoid plating issues as cycling progresses through the life of the battery.

Comparing the CD of the power and energy cells, it is evident that the power cell has a higher baseline value when the cell is unaged, reflecting a higher structural degree (smaller particles, higher porosity, larger bulk surface area) of the power cell. These features are necessary for the cell to support higher currents while maintaining long term stability. More simply, the fractal dimensionality provides a correlation to the electrically active surface area of the cell. In contrast, the energy cell is constructed with larger particles with higher bulk volumetric density in order to increase its available energy density. Again, the CD information strongly correlates with known attributes of the two different types of cells.

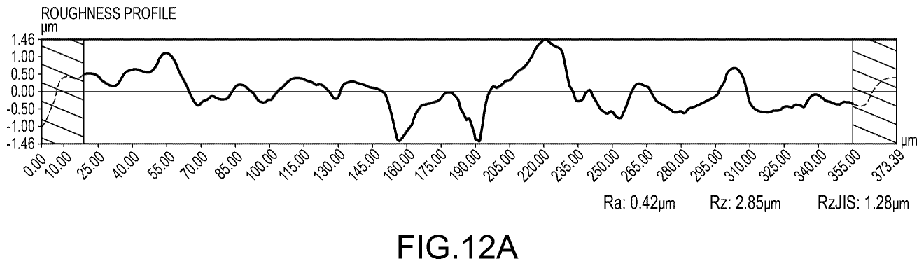

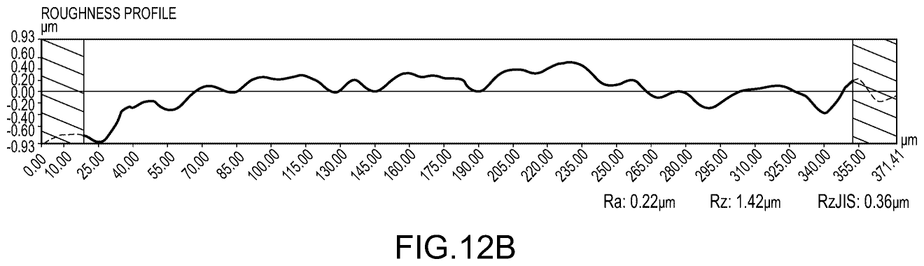

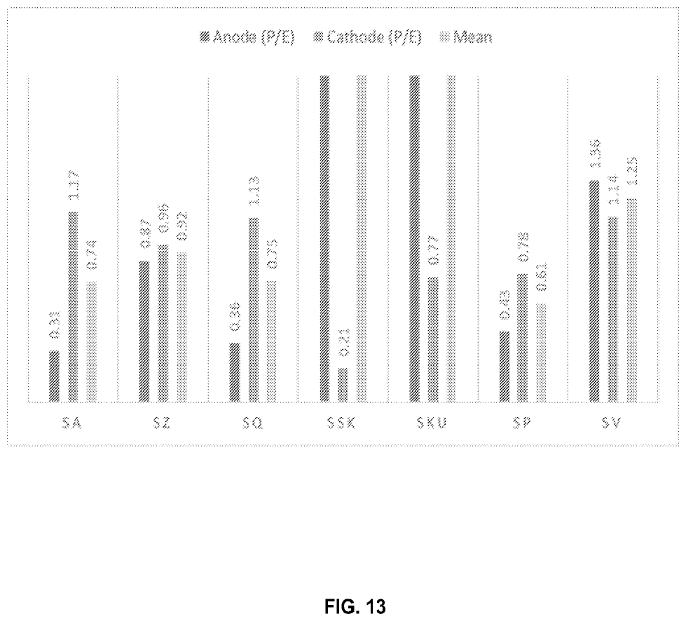

Surface profilometry of the anode and cathode of the power cell and energy cell can be used to understand the relative relationship shown by the CD for unaged cells. The roughness of both electrodes must be considered to understand the net cell roughness. Two surface profiles (FIGS. 12A and 12B) are shown for the power cell, including anode (12A) and cathode (12B). The bar chart of FIG. 13 also shows several descriptive parameters quantifying areal roughness, in which values for the power cell and energy cell are taken as a ratio Power/Energy (P/E) for the anode, cathode, and the average value of the two. Roughness parameters for the power cell were divided by those from the energy cell so that if P/E>1, then a roughness parameter is greater for the power cell. Values greater than 1 indicate higher power cell roughness. Only an approximate relationship is expected between profilometry and CD because the latter measurement reflects electrically active surfaces as to opposed to general surface features. Even so, the measured value for CD_{Power}/CD_{Energy} of 1.16 compares favorably with the areal roughness values. The particular profilometry parameters, and from which electrode, that best correlate to CD will change as the cell ages. However, it is consistent with the dendritic geometry of lithium and the electrochemical understanding of the evolution of lithium plating that the skewness of the surface asperity (ssk) and the incidence of sharp surface features (kurtosis, sku) would play a larger role in the correlation.

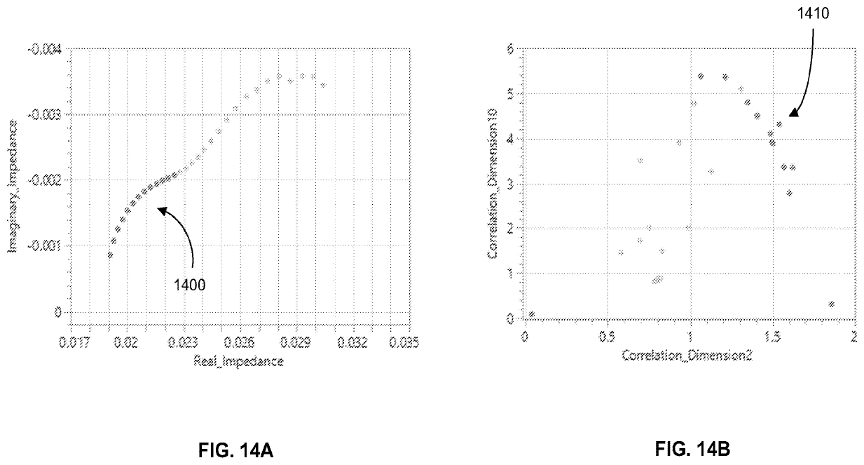

In FIGS. 14A and 14B, the power cell may be analyzed in the frequency domain to verify structural causality between known features of impedance data and the CD. It should be noted that electrochemical impedance measurements cannot be used to quantitatively or qualitatively describe the dimensional state of an electrode outside of idealized simulation in which all other effects are controlled and the cell is well characterized ahead of time. In this ideal case, the CPE term of an Equivalent Circuit Model may be examined for deviation from perfectly circular shape. However, other factors such as dimensions of cell materials, charge rate, and degree of aging distort these measurements beyond deconvolution. Electrodynamic measurements of dimensionality such as the CD provide an alternative and superior means of quantifying structural state of the electrode and interfaces.

An EIS measurement was performed with the power cell to obtain the Nyquist plots in FIGS. 14A and 14B. It is well understood that the highlighted/darker points 1400 in FIG. 14A arise from the capacitive impedance behavior of the battery's SEI layer, while the remaining points reflect properties of the battery's charge transfer reactions. In FIG. 14B, the same data points 1410 are also highlighted to distinguish the behavior of the SEI from the charge transfer behavior in the plot CD dimensionality at two different embedding dimensions. The comparative CD plot contains a clear structural relationship, with points attributable to the SEI occupying a distinct region of that structure. Specifically, points associated with charge transfer reactions maintain proportional increases in embedding dimensions of 2 and 10, whereas SEI dimensionality is distinguished by an inversely proportional relationship. This suggests that the dimensionality of the SEI is more complex, with a higher degree of nonlinear behavior, and benefits from analysis in higher embedding dimensions. The example shows that structural information from CD may be used in a synergistic manner with impedance measurements, that different components such as the SEI can be distinguished in CD and similar electrodynamic measurements, and that, despite the simplicity of this example, the SEI has a fundamentally different effect on the structural conditioning of the cell's components than the kinetic region (and diffusion limited regions).

Lithium metal cells differ from lithium-ion cells by using lithium metal rather than graphite as an anode material, and also in the balance of total lithium distribution among the anode, electrolyte, and cathode. Nonetheless, the CD related processes described herein, as well as other electrodynamic parameter processes described herein including the comparative relationships between impedance and dimensional analysis, work for LMBs in addition to LIBs, even though one is based upon plating and the other upon intercalation. Lithium-ion batteries normally adhere closely to a theoretical capacity of 1.2:1 between anode and cathode, where lithium metal batteries frequently contain multiples more of lithium than the cathode can alloy. A more obvious difference between the two cell types is that LIBs are based upon intercalation of lithium ions following charge exchange and the formation of metallic lithium distinctly decreases the cell's health, whereas LMBs exclusively function via lithium plating during charge and the distinguishment between healthy plating and that which causes capacity loss is more nuanced. The latter calls for electrodynamic measurements which are more capable, sensitive, and reliable, and which yield more gradated information than impedance-based approaches.

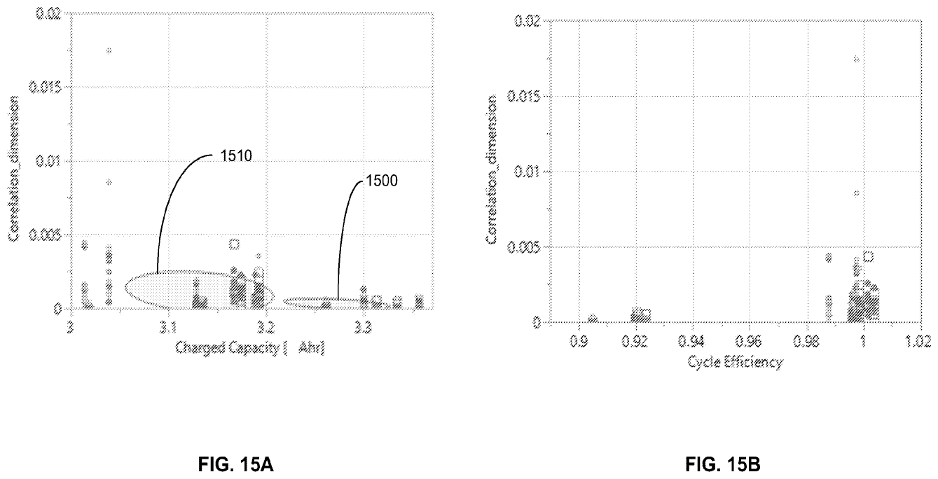

FIGS. 15A and 15B illustrate CD information from three, 3.4 Ah LMB pouch cells, plotted against Charged Capacity (FIG. 15A) and Cycle Efficiency (FIG. 15B). The plots also include information from the LE, in which markers as squares indicate points as which cell gradation is acceptable and normal, while markers as points indicate fast or severe degradation. Further, the density ellipse 1500 (10%) indicates and x- and y-axis position of the highest density of square markers, while the density ellipse 1510 (10%) indicates the position of the highest density of point markers.

At capacities near the cell's nominal value, CD reports the lowest values (points in ellipse 1500), indicating the smoothest anode interface. This is also where the LE reports the highest density of healthy markers. As the charging capacity decreases, the CD begins to report (points in ellipse 1510) increasingly large values due to both the increase in thickness of planar-dendritic deposits as well as the formation of higher aspect-ratio dendrites. The former may cause the CD to increase in magnitude, whereas the latter may cause values to decrease while remaining higher than nominal. The highest values of CD are reported as the cell nears the end of its life.

The same information plotted against Cycling Efficiency (C.E.) (Discharged Ah/Charged Ah) highlights a known failure mechanism of some LMBs with higher theoretical capacity at the anode. The cell normally operates ˜99% efficiency. The highest increases in fractal dimension occur at C.E.=1. Markers indicating both low and high rates of degradation exist in this range, indicating that as capacity is lost (indicated by the Charged Capacity plot), a C.E. near 1 may not be an indication of healthy functionality. Frequently as LIB or LMB cells begin to fail near their End of Life, the efficiency will decrease to lower values. However, in some cases, assuming reliable measurement accuracy, C.E. values ≥1 can be observed and indicate that more energy is being discharged than was charged. This may occur because fresh lithium exists beneath the anode interface, typically below the previously plated lithium. Much of this previously plated lithium oxidizes and becomes inactive as a form of capacity loss. However, with fresh, bulk lithium still electrically accessible in the sublayers, the inventory of lithium practically available for cathode replenishment is retained despite ongoing capacity loss during charging at the anode until the excess capacity at the anode is depleted. The occurrence of this behavior will vary with different LMB designs and modes of aging.

### Examples

### Correcting Failure of Impedance Controlled Charging Using CD

In a hypothetical scenario, a pulse charging methodology with constant current and constant voltage periods is being explored by a smartphone manufacturer to charge lithium-ion batteries in cell phones at faster rates. The period, duty cycle, and magnitude of the square pulses are controlled using ongoing impedance measurements of the square pulses. In particular, the system ensures that the impedance does not become too great by decreasing the current magnitude to avoid overheating the cell. The period and duty cycle of the pulses are also adjusted to maintain operation at the lowest possible impedance. When a critical impedance boundary is reached, the charge controller halts the charging signal and applies a broadband probing pulse for better spectroscopy-based impedance information. As a cycling batch of cells controlled by this method begins to age, a statistically significant portion of the batches may show signs of failing.

Review of the cycling data indicates that the charge controller successfully prevented excessive impedances and destabilizing temperatures, even immediately up to the point of catastrophic thermal failure in some instances. Further, both DC resistance of the charging signal and EIS analysis of the probing signals indicated agreement and optimal function maintaining low impedance during operation for all cells which nonetheless failed catastrophically, and only minor increases in impedance for cells which began to fail more gradually before being halted. The team is unable to draw conclusions from their impedance-based analysis.

To improve on such a hypothetical situation, aspects of the present disclosure involve the recognition that CD analysis as discussed herein may work alone or in conjunction with such a technique or otherwise to fill blind spots not possible with impedance analysis. Aspects of the present disclosure involves the recognition that time series cycling data using electrodynamic analysis and the CD reveals higher values at points which are associated with the lowest values of impedance during charging. These points are usually preceded by gradual increases in impedance. Analysis using both electrochemical and electrodynamic analysis, may determine that in many cell types, a decrease in impedance, measured and maintained preferentially by the charge controller, may actually be due to, and in other cases was caused by, the nucleation of metallic lithium which then accelerated dendrite formation. This is well documented in scientific literature and is analogous to metallic nucleation often performed intentionally in many electroplating systems which are analogous to batteries under charge, yet with a few critical differences. Higher pulse magnitudes are shown to cause metallic nucleation under circumstances of increasing impedance, and the newly nucleated metal creates a secondary reaction pathway which allows to the impedance to then relax while the metallic content increases to the detriment of the cell's health. As such, detrimental processes within the battery are not recognized by impedance and in some instances may be disguised by a decrease in impedance. Thus, CD may be used to compliment impedance analysis, noting periods where impedance is lower but CD is higher, and altering the charge or taking other action to avoid the dendritic growth that may be occurring.

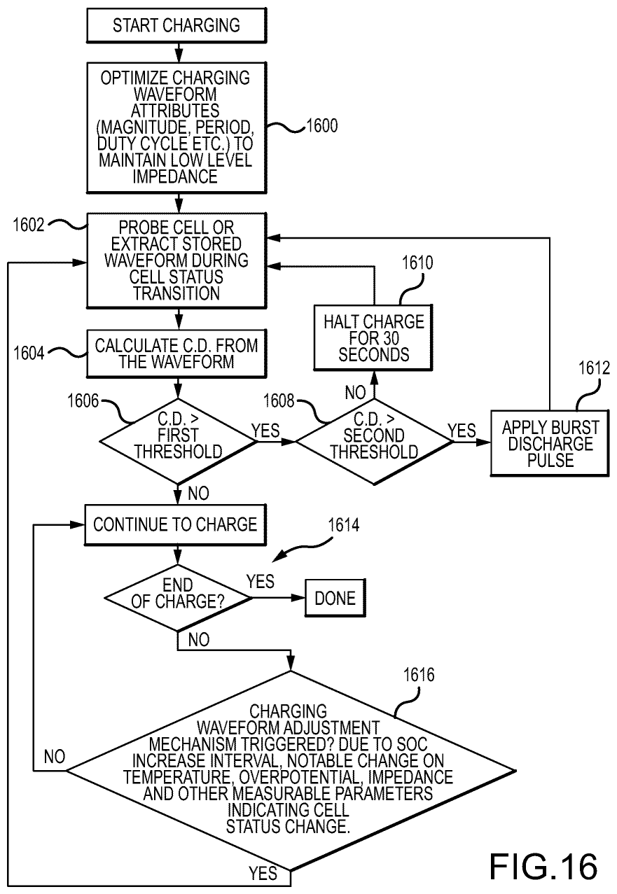

An aspect of the present disclosure involves a charge control method to incorporate the CD measurement, which may be alone or alongside the impedance control methodology. Referring to FIG. 16, in one possible implementation, a controller maintains impedance at relatively low levels during charging, which may be done by decreasing charge magnitude, altering duty cycle, altering prior or otherwise altering the charge signal including altering charge signal shape or harmonic content to operate at a relatively low impedance (operation 1600). Maintaining a low impedance may involve a distinct PID or MPC (model predictive control scheme). With or without impedance control, the charging system may initiate a probe or otherwise obtain battery measurements (operation 1602) from which CD may be computed (operation 1604).

If and when an increase in the structural dimensionality of the system is reported via the CD analysis (e.g., gradually increasing CD values as compared to a first threshold (operation 1606), the CD value may be compared to a second threshold (operation 1608), and halted for a rest period, e.g., 30 seconds, if CD does not exceed the second threshold (operation 1610) whereafter CD is reassessed (operation 1602) In one possible arrangement, the CD value is reassessed after charging resumes and if the CD value hasn't recovered, e.g., it still meets the first threshold (operation 1608) then the rest period repeats or the charging rate may be decreased, or both.

In another arrangement, which may be performed alone or in conjunction with detecting a gradual increase in CD, if the systems detects a sudden increase in the CD values by meeting the second threshold (operation 1608), different from the first and established to detect a sudden change, the charge signal may be halted and a discharge pulse performed (operation 1612). In one example, a discharge is performed for some discrete period of time and at some magnitude. For example, a discharge pulse at 1 C for 2 minutes may be performed. In another example, the discharge pulse may be at a magnitude and with coulombic properties prescribed by a formula which is a function of the CD measurement (e.g., the rate of change, value of CD, SOH, charge requirements, SOC, or some combination of information may be used to tailor the discharge pulse attributes (e.g., magnitude and time). By controlling the discharge pulse in this way, the charge controller assures that no more charge is removed from the battery than is absolutely necessary, and also that the other components of the battery are not exposed to excessive levels and durations of current which may increase their degradation. The discharge pulse may serve to quickly and proportionately redissolve plated and dendritic lithium back into the electrolyte before passivation and capacity loss can occur. The discharge pulse may also preferentially remove the more concerning needle-like and higher aspect ratio dendrites on the basis of ohmic resistance across anode and cathode. The effectiveness of the discharge pulse is verified in the recovered, lower magnitude values of the subsequent CD analysis after resumption of charging, which may be proceed at the same or different current charge value after the discharge pulse. In some instances, charging may proceed for some period at a lower charge rate. One important and possible advantage to the technique is that it may detect metallic growth, through the CD measurement, and act on it immediately maximizing the effectiveness of the discharge pulse and/or minimizing the magnitude and/or duration of the pulse.

After the system assesses CD, charging will proceed until end of charge (operation 1614), which may trigger a constant voltage sequence, charging to halt, or some other end of charge control scheme, or may continue until some state change in the battery indicating CD should be reassessed (operation 1616). For example, CD may be reassessed on a time schedule, based on SOC (e.g., every 1% SOC, every 2% SOC, every 5% SOC, or every 10% SOC), due to temperature change with the cell (e.g. a 1 C, a 1.5 C, a 2 C, a 2.5 C or other temperature change), a change in impedance, an indication of a change in overpotential, or reassessed due to some other state change, where operations (1602-1612) may be performed, and the charge signal magnitude may be reset. It should be noted that impedance optimization 1600 may also be occurring.

In some arrangements, a system and method accommodating CD measurements may account for SOC. For example, in some arrangements, the system may not apply a discharge pulse below some SOC—e.g., 5% or 10%. For example, the system may not activate a discharge pulse despite indications of a high CD value because the detection occurred below 5% SOC and such a pulse would potentially bring the cell voltage below the warrantied lower limit of 2.5V. The system may further implement an LE measurement to understand the cell's dynamic condition at a deeper level than the high impedance state reported from EIS and probing. In such a situation, the LE analysis may be run in conjunction with CD analysis. For example, if LE reports a value close to 0, indicating reasonable stability, the cell may be allowed to continue charging at 20% of the standard charge rate until the impedance values decrease. In contrast, LE may report a value which is more positive than expected, indicating instability and that the cell is unsuited for continued charging without further rest and reevaluation, or a reduction in charge current magnitude and reassessment.

### CD for Charge Regulation and Termination Criteria in the Absence of Constant Voltage Period

Automotive OEM's are increasingly interested in improving the charge rate and cycle life of their energy cells, which often involves various adaptive charging protocols. However, one drawback of conventional approaches is that constant voltage periods, typically toward the end of charge near 100% SOC, do not prevent the propagation of accelerated SEI growth and plating of lithium on the anode. In general, in a CCCV scheme, charging occurs at some constant current, and then when the battery reaches some voltage level typically when nearing a full SOC level, charging changes to maintaining a constant voltage, which is accompanied by a decreasing charge current as the battery reaches 100% SOC. As such, a safer, more controlled and predictable charging method is desired which can optimize long term safety and long-term operability and resale value of their vehicles. The same challenges exist in any number of battery-powered systems.

One example solution according to aspects of the present disclosure is to take advantage of the high sensitivity of the CD measurement and fast response to changes in the structural state of the battery's internal interfaces to combat the sudden and often-irreversible onset of lithium plating. As can be observed and/or understood from CD data, the CV period does not appreciably slow the growth of higher order structural features inside the cell, and also that such growth begins to onset well before the CV period is typically reached. In many conventional scenarios, upon reaching some voltage at the terminals of a battery under charge, control transitions to maintaining a constant voltage and reducing the current (the CV portion of the charge sequence). Impedance-based control may be unfeasible as the onset phenomena is not reflected in models or real-time resistance or impedance measurements until the battery pack is 15% aged. And even then, the impedance models require an empirically-derived understanding to inform how charge profile may be modified to protect the pack SOH.

As such, aspects of the present disclosure involve a charging system, such as a BMS system present in vehicles, which measures the cell voltage and calculates an optimized version of the CD parameter. In one example, and optimized CD parameter is one that uses an optimal number of embedding dimensions which are known to provide the most reliable representation of the fractal dimension of the particular battery. Based upon historical cycling data with the cell and the target rate of charge of 25 minutes, a measurement frequency of Δ2% SOC is calculated to be sufficient to catch and prevent degradation through an automotive pack's end of life.

The CD-based BMS may be used with various pack types including different numbers of cells. The technique may be done on a discrete cell or small pack as well. It is understood that impedance measurements across modules within a pack may be distorted due to the interconnects across cells in series and in parallel, among other things. In contrast, a CD measurement may maintain stability and fidelity. In general, the BMS is arranged to detect increases or more generally changes in CD. For example, during charging, as the pack is charged, and for example at 40% SOC, the system detects a small increase in the CD magnitude, the charge controller may be configured to instructed a decrease in the charge current magnitude, which may be done iteratively, until the CD magnitude stabilizes or reduces. Using CD in this way, for example, the system may detect the irregular onset of SEI growth earlier than was otherwise possible from resistance of impedance spectroscopy methods. In various instances, the situation may involve only modest, e.g., 3% or less reductions in charge current, for some subsequent period (e.g., the following 5-15%) to stabilize the battery. Higher currents may be assessed after this period or the charge may continue at the lesser rate. By responding swiftly to the onset of changes in the cell dimensionality according to the CD measurement, modifications to the charging current are able to remain relatively subtle (e.g., smaller changes in charge current as compared to other techniques that cannot identify changes or identify them later and thus require more drastic changes). During segments of the charge in which CD is particularly stable, the current may be safely increased, and CD or other parameters assessed as discussed herein. Various benefits may be realized by such a charge protocol including improvements in pack cycle life, optimized charge time performance, and reduction or elimination of plating lithium, which has a host of ancillary benefits including safety and material recycling.

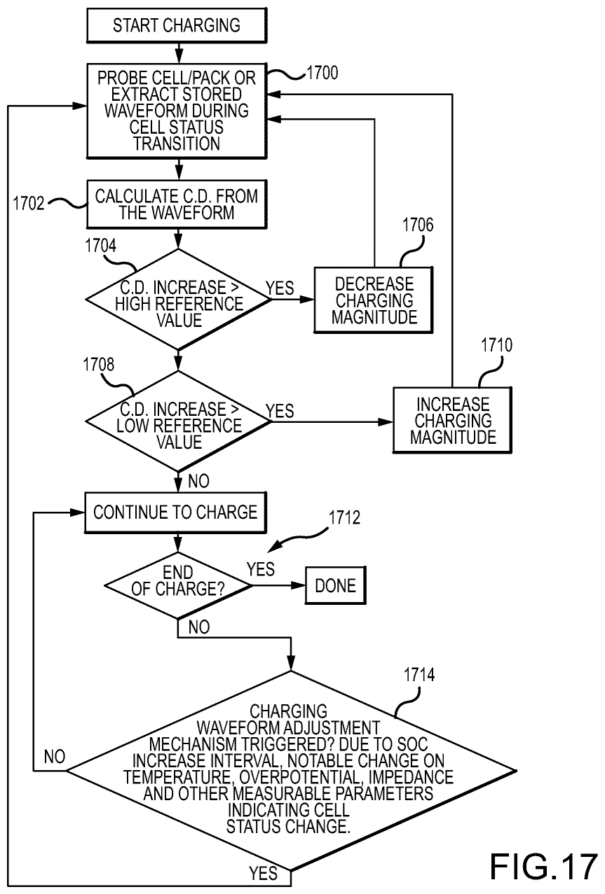

One example of such a method is shown in FIG. 17. Here, like other methods discussed herein, CD is computed from measurements from a probe or other transition period, which may be from a battery under charge (operations 1700-1702). In this example, the system may have two CD threshold values. The CD is compared to the first, relatively higher, threshold at operation 1704, and if the CD values meets the value (e.g., is greater than the threshold), the charge current magnitude may be decreased (operation 1706). If the CD value does not meet the higher threshold, the CD value is also compared to the lower threshold (operation 1708), and if it is less than the lower threshold, charging current may be increased (operation 1710). If the CD value, is greater than the lower value but less than the upper value, charging may continue as before the threshold assessment. Of course, it is also possible to compare CD to a range encompassing the upper and lower thresholds, and act on the range or perform other comparative assessments.

For a particular battery and a particular embedding dimension, an upper CD threshold may be 0.005, which represents a maximum tolerable fractional dimensionality (degree of interfacial roughness) beyond which the SOH may degrade too quickly or dangerously. A lower threshold may be 0.0005, below which the fractional dimensionality may be stable but the charge rate may be too low to meet performance goals, and an increase in charge magnitude is possible. Dimensionality values between these thresholds indicate the region in which the interfaces are reasonably stable, degradation rate and safety state are reasonable, and the battery is able to meet charging performance requirements.

Like other methods discussed herein, charging may proceed until end of charge (operation 1712), which may not include a constant voltage sequence as the technique here removes the need for it if the charging scheme was otherwise constant current or the technique was instituted to detect end of charge, or may continue until some state change in the battery indicating CD should be reassessed (operation 1714). For example, CD may be reassessed on a time schedule, based on SOC (e.g., every 1% SOC, every 2% SOC, every 5% SOC, or every 10% SOC), due to temperature change with the cell (e.g. a 1 C, a 1.5 C, a 2 C, a 2.5 C or other temperature change), a change in impedance, an indication of a change in overpotential, or reassessed due to some other state change, where operations (1700-1710) may again be performed, and the charge signal magnitude may be reset or otherwise charging may proceed.

### Sample Entropy

Sample entropy (SE) is a measure of the complexity and regularity of a time series. It can be used to assess the health of a lithium-ion battery by analyzing its charging voltage or current waveform. To obtain SE, the system performs the following steps:

Step 1: Data Preparation: First, the system defines a sequence length (m) and a tolerance value (r) for similarity comparisons. The sequence length (m) determines how many data points we compare at a time, and the tolerance (r) defines the acceptable range for considering two data points similar.

Step 2. Template Matching: The system then calculates the number of data sequences of length (m) that have a similar counterpart within a tolerance (r) for the next (m−1) data points. Here, similarity refers to the voltage or current values being within the tolerance range. Mathematically, the system can represent this count as Bm.

Step 3: Subsequence Comparison: Similarly, the systems may repeat step 2 but exclude the first data point from the original sequence. This gives the number of similar sequences of length (m−1) within the tolerance (r), denoted by Am.

Step 4. Sample Entropy Calculation: Finally, sample entropy is calculated using the following formula:

$$SampEn ( S E ) = - ln ( Am / Bm )$$

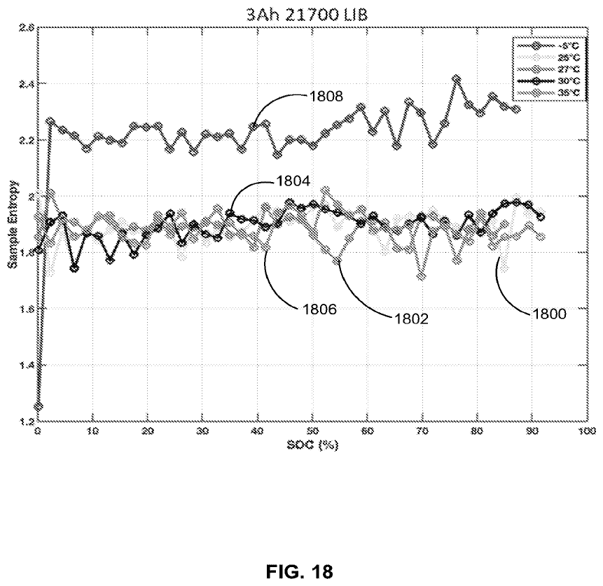

Turning now to examples of using SE, in the data shown in FIG. 18, a 3 Ah LIB is charged at different controlled temperatures to demonstrate and quantify shifts in the stability of the cell dynamics as demonstrated and correlated to sample entropy (SE).

As can be seen, SE values are very similar at 25° C. (1800) and above (27° C. (1802), 30° C. (1804) and 35° C. (1806)), with subtle variations in SE between about 1.7 and 2 depending upon SOC. In contrast, the same cell at −5° C. (1808) shows a notable increase in SE to about 2.15 to 2.4 depending on SOC which may be counter-intuitive because colder temperatures generally slow the kinetics of chemical processes, increase the density of gasses, and otherwise cause a higher degree of order among the species in a system. The same is true for the 3 Ah LIB cell when it is at rest and equilibrium. However, SE is based upon the electrodynamics of the system, which is to say that it has a direct sensitivity to electrochemical reactions which participate in charge exchange. Chemical processes determine the thermodynamic entropy of the cell but may only weakly impact SE if their kinetics are not directly and rapidly coupled to an electrochemical reaction. At temperatures below 25° C., and particularly below 0° C., electrolyte species are much closer to their solidification temperature (order). But this increases complexity of active electrochemical processes (disorder). Specifically, lithium plating may begin to occur in parallel to intercalation in a LIB and the kinetics between chemical and electrochemical steps may vary more greatly as charge exchange is forced by a charging current. For at least this reason, the electrodynamic entropy (aka SE) of the cell at −5° C. when charge current is applied is greater than when the cells are at higher and more optimal temperatures.

At all temperatures, electrodynamic entropy as assessed through the various SE computations discussed herein maintains a steady trend with SOC until 50% SOC. The rate of charge is relatively slow for this power cell at close to 0.5 C, which allows subtle variations in SE to more directly reflect phase changes in the anode and cathode and the heat flux generated as a result. For the higher temperatures, the cells all show a trend toward stable SE rather than the subtle increase from 0-50% SOC. At −5° C., the cell begins to show a small but steady increase in SE above 50% SOC indicating irregular lithium plating on the graphite of the anode. This gives an indication that at −5° C., only 0-50% SOC should be utilized to avoid the highest rates of plating and degradation. Alternatively, a much slower rate of charge could be used to bring the overall entropy/SE down to the demonstrated baseline values of the other cells. Additionally, depending on any particular battery cell type and temperature, the system may be configured to provide some battery heating before or in conjunction with the onset of charging, based on SE and/or battery temperature directly.

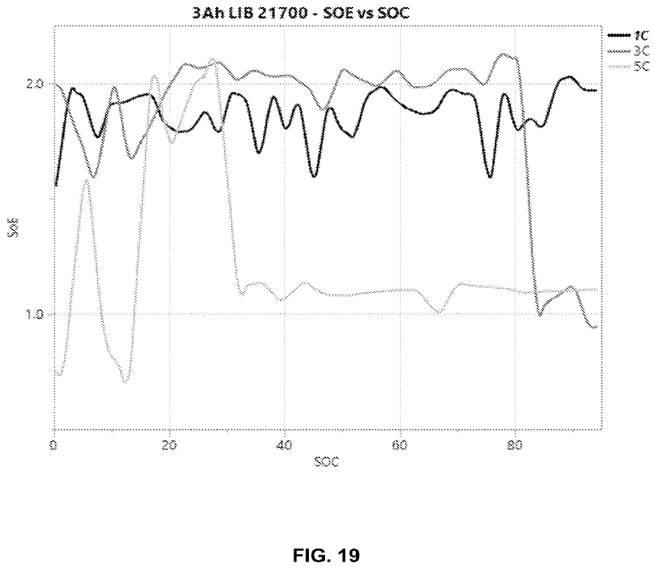

The data in FIG. 19 shows the impact of charge rate on SE. Here, SE is computed for a 3 Ah LIB at 1 C, 3 C and 5 C charge rates, each conducted at 25° C.

At 25° C., a charge rate of 3 C increases the SE only slightly from 1C when the cells are unaged, with some lower values at early and late SOC. However, at 5 C, the SE is notably lower and more variable between 0-15% SOC. From 15-33% SOC, the SE is similar to the 1 and 3C rates. However, above this range, the SE of the 5 C charge rate abruptly drops to a value of 1.1. This indicates a change to a similar state experienced by the cell at the rate of 3 C above 80% SOC. It can be seen that an SE threshold or rate of change of SE threshold may be used to detect a state change in the battery and alter charging parameters.

A lower SE indicates that the electrochemical processes, in particular, are more ordered and may occur for numerous reasons owing to the complexity of cell dynamics. When lithium ions are well dispersed throughout the system, the system will reflect less order, or higher SE. At a charge rate of 1 C, heat flux driven by exothermic and endothermic phase changes have a larger influence on the SE as well as diffusion. SE is not indicative of a specific system state, but rather, whatever system property is most greatly affecting the chemical and electrochemical order of the system. SE may fluctuate up and down during normal and healthy operation. Changes in SE are more interesting than absolute values, and hence change in SE may be used as a threshold to control charging.

SE can be used as a substitute for thermally measured and calculated entropy which may be difficult to get in most cases. This improves the reliability of thermal models and helps reduce the need to have temperature measurements at many places throughout a pack. SE may also be useful as a comparative metric to better understand whether changes in LE or HE (discussed below) are healthy or unhealthy.

In some instances, a change in SE, e.g., d(SE) may be more useful rather than SE directly. d(SE) can be used to estimate the open circuit voltage of a battery when temperature is also known (or vice versa), to calculate the actual heat flux through the cell when temperature and current are also measured, and to calculate enthalpy (which is more directly tied to degradation) to name a few. SE is thus a valuable thermodynamic parameter. Changes in SE can also be used as a trigger to make additional measurements. SE may also be used to correct the distortion of a temperature measurement in cases where the measurable surface temperature is a less accurate representation of the general temperature of the cell or pack, and also to overcome the inability to obtain temperature measurements at all cells within a pack. In this latter case, the SE can provide a reliable means of measuring d(SE) when it cannot be reliably calculated.

1/SE can also be used to calculate and estimate the period of time that the system will continue to exhibit the current dynamics. This could be used to choose a measurement interval for SE or other electrodynamic parameters and charge control methodologies discussed herein, for example. Within the calculated interval, the dynamics will remain predictable based upon the recent SE measurement. Outside of the interval, the potential for a less predictable shift in dynamics warrants the making of a new measurement. This can be used to suggest a refresh interval for SE as well as any other electrodynamic or electrochemical measurement.

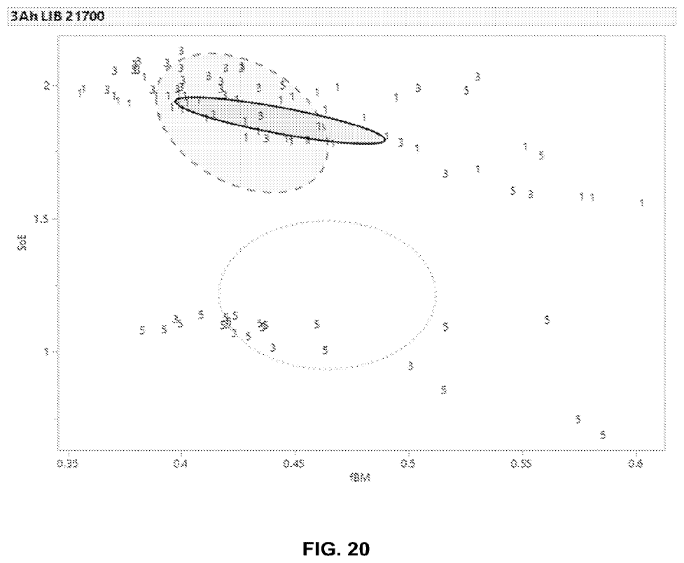

The plot shown in FIG. 20 of SE vs fBM (degree of Brownian motion of diffusive processes) shows a strong and fairly linear correlation indicating that changes in SE are primarily the result of phase changes in the anode and cathode. The plot shows that the correlation is weaker for a rate of 3 C (3 values) and extremely weak for 5 C (5 values). The 3 C rate is slightly more sub-diffusive (lower fBM) than 1 C (1 values), indicating similar governing dynamics but with greater diffusion-limiting activity. The 5C rate, however, shows a shift to lower SE as well as less sub-diffusive behavior than the other rates. This indicates that all diffusive processes through the electrodes and electrolyte are operating at their limiting values and developing strong concentration gradients across electrolyte-electrolyte interfaces at the electrodes (cathode and/or anode), as well as within the electrodes. These dynamics will quickly result in the onset of lithium plating, and thus may be detection thresholds and used to set, control and/or alter charge in some way, including a rest or discharge for plating reversal like discussed elsewhere herein.

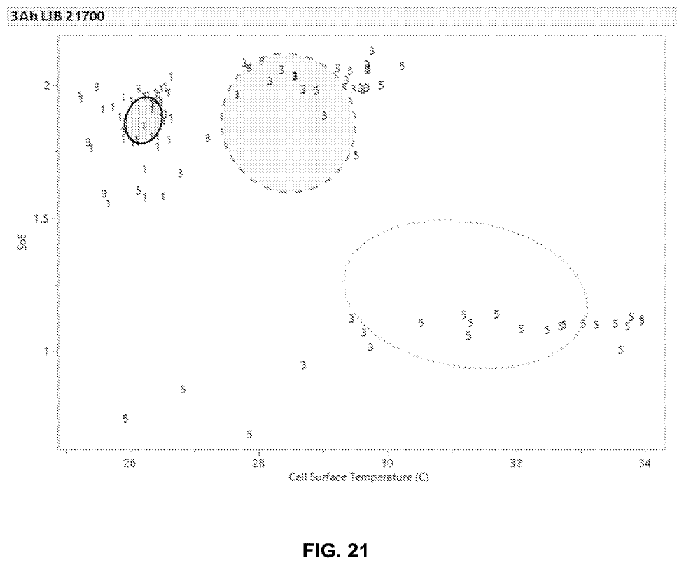

As illustrated in FIG. 21, this also tells us that at faster rates of charge, the entropy (and likely the reversible heat flux through the cell or pack) is less dependent upon diffusive processes and that thermal effects are playing a larger role. This happens when sources of reversible heat generation (exothermic and endothermic electrode phase changes) are dwarfed by sources of irreversible heat generation, such as Ohmic losses (e.g., due to resistive heating of the current collectors or tabs). In this case, the system may stop trying to correlate the SE to impedance measurements and the system be arranged to, in response to SE, decrease charge current or otherwise alter the charge signal to reduce or stop irreversible heat generation.

At a rate of 5 C, internal mechanisms of reversible heat generation (phase changes) are quickly surpassed by irreversible sources of ohmic losses, in which the electrical resistance or impedance of the current collectors and tabs begins to strongly impact heat distribution throughout the cell or pack. Cell SE becomes strongly correlated to cell temperature as compared to cells charged at 1 C and 3 C rates (see FIG. 21). At high rates of charge, diffusion of lithium out of the cathode may begin to exceed electrolyte diffusion. This results is a buildup of lithium at the interface of the cathode and electrolyte (a source of higher order, lower SE). Such changes in sample entropy can be particularly abrupt when a cell is unaged and phase transitions occur uniformly rather than in a gradated manner at different thicknesses or locations throughout the cell, when cell impedance is changing rapidly, or (related to impedance) when either electrode becomes depleted. Impedance and depletion explain why the 3C rate exhibits fluctuations in SE below 20% SOC and a rapid decrease in SE above 82%. The cell charged at 5 C is also affected by high impedance below 20%, with sharp concentration gradients at 30% SOC. Ultimately, the cell is only able to operate with optimal dynamics between 17-30% SOC when charged at 5 C.

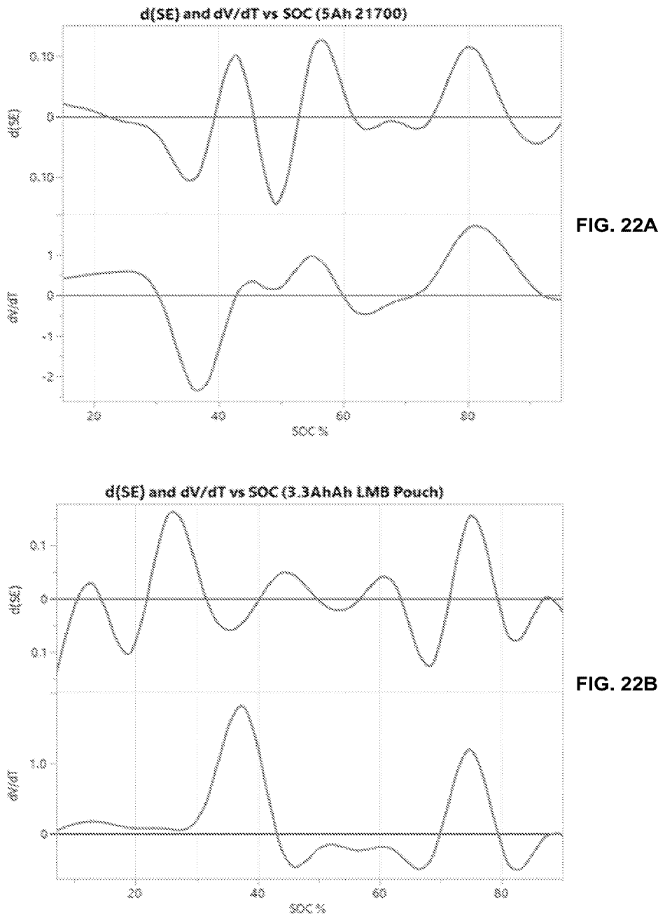

Looking at a different set of data shown in FIGS. 22A and 22B, thermodynamic entropy can be estimated by the relationship d(OCV)/d(T) (change in open circuit voltage over change in temperature) as measured in standard cycling tests and can be useful in understanding aging, calculating heat generation, and calculating other thermodynamic parameters with or without a reference thermal model of the battery. For large cells and packs, in particular, the use of models become more important because obtaining reliable measurements of cells across a pack is difficult and the heat distribution through a pack is irregular. Even for a single cell and perfect placement of a thermal probe to obtain a surface measurement, it is not possible to obtain a reading of temperature distribution at all parts through the cell, nor to avoid thermal gradients throughout, especially with higher rates of charge or discharge. For this reason, entropy estimated based upon voltage and measured or modeled temperature will be subject to some distortion and measurement delay. For the dV/dT data shown in FIG. 22A, a probe was connected to a cell with as ideal a configuration and quality of contact as possible. The data is compared to the change in electrodynamic state of entropy, d(SE).

The two measurements are generally in agreement, with variations in relative peak magnitude due to several reasons:
Error in the probe measurement.
Inability to measure the full thermal character of the cell with a surface measurement.
Time delay in thermal variations (dT) in reaching the probe compared to the more immediate effects of such variations on measured voltage (dV).
Thermodynamic calculations and modeling based upon SE rather than dV/dT will be more accurate and responsive to changes in the cell (and especially to cells in a pack, with benefit increasing with pack size and total cell count), and provide more accurate models as a result. With more reliable inputs, models can be greatly simplified and require less costly hardware resources to support real time operation during charge and discharge control.

The data in FIG. 22 (B) shows the same measurements and comparisons for a clamped, 3.3 Ah lithium metal pouch cell. The clamp prevents useful placement of a temperature probe and also impacts the cell's thermal distribution. In real world packs, and particularly with pouch cells, individual cells are compressed together under external force or pressure, greatly limiting the available options for temperature probe placement.

In such a scenario, as shown in FIG. 22(b), there is a notable difference in the SE and electrochemically calculated thermodynamic entropy. The same reasons previously mentioned are responsible for the difference. Differences are more pronounced below 60% SOC because more heat is internally generated which cannot be accurately measured from temperature probes. However, SE is able to capture the transitions related to endo- and exo-thermic processes, as well as irreversible ohmic processes, with immediacy and fidelity. SE provides higher responsiveness as the cell ages, internal dynamics evolve, and the environment changes, regardless of a cell's material and chemical composition.

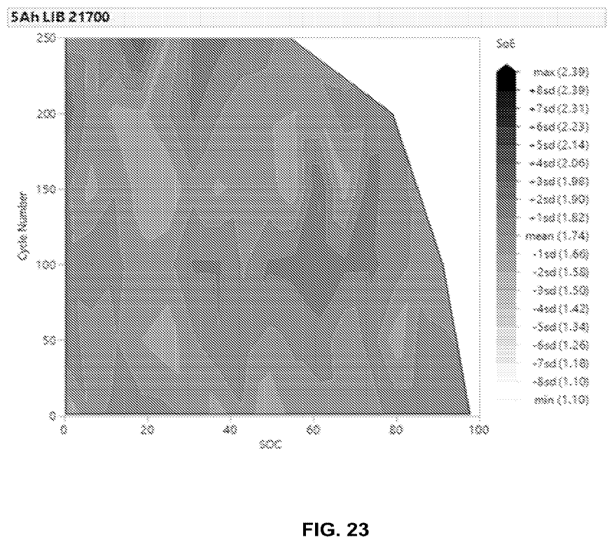

These evolving dynamics are shown in FIG. 23 for a 5 Ah LIB with 5% silicon content. This plot shows that the signal entropy is complex and changes notably from cycle to cycle and with changes in SOC. Therefore, the thermodynamics of the cell, including internal temperature, enthalpy, and free energy states are also changing. This contrasts strongly with fixed current methods of battery charging which do not account for these deviations and, as a result, are inherently limited in how greatly SOH can be protected. Further, these variation with increasing cycle count shows how difficult and unreliable it is for battery descriptive models to be used to estimate the battery's thermodynamic state. Instead, with this type of information collected in real time, better charge control decisions can be made to increase charging performance and protect SOH simultaneously.

With superior information about the cell or pack dynamics using SE, charge and discharge control systems, as well as BMS functionality, can achieve a superior understanding of the presenting thermodynamics, superior temperature models, and safer cell and pack operation, all with the potential for smaller and more material and chemistry-agnostic models, and without needing to interrupt the charging current to measure OCV.

### Examples of Using SE in Charge Control

### SE to Regulate Heat Flux Through a Pack

Electric vehicles are often charged in uncontrolled temperature environments, and in winter can be subject to low temperatures—e.g., ambient conditions of 0° C. or less. Some conventional charging systems involve a pack charge controller equipped with several heating modes and the ability to measure temperature from different thermocouples placed in some spaced manner in the pack. As a general notion, sensors on pack modules closer to the exterior of the pack tend to report lower temperatures, particularly after the pack has been sitting for some time (e.g., car parked overnight).

In general, during early charging of such a pack (e.g., the first 40% SOC) the charger may apply a relatively large charge current which induces enough ohmic heating to maintain optimal dynamics. However, if the charge current is decreased, the exterior cells may cool faster or heat at a slower rate than interior cells due to less ohmic heating and higher heat loss to the cold surroundings. The thermocouples placed within each pack have some error, e.g., +/−2° C. error, and cannot reliably represent conditions across all cells in the pack.

To remedy such a deficiencies, a charge controller implementing an SE method is configured to generate a charging signal designed to induce more heat in the cells while maintaining a lower average current or no charge current, at least initially until the pack and temperature distribution within the pack reaches a temperature threshold. The system may have one or more thresholds where no or some or full charging may occur, which thresholds may be battery type dependent. Heating may be achieved through various techniques including as discussed in U.S. application Ser. No. 18/113,578, which is hereby incorporated by reference herein. In general, a heating signal may involve a sinusoidal or other alternating current, with periods of positive and negative current into and out of the battery, such that there is little or no net charge exchange. The frequency may also be tailored to eliminate or reduce net charge exchange. The heating signal may be in rest period between charge signals or a stand-alone heating only signal, particularly the stand-alone heating signal occurring at relatively lower temperatures where the battery is too cold to safely charge. In a pack setting, the heating signal may allow the exterior cells to become damaged if the heating is not sufficient, and may also damage the interior cells if the heating is too great. The error and variability in temperature measurements would normally mean that the actual charge rate must be reduced by a large margin, e.g., 60%, for the controller to maintain a conservative approach and better protect the health of all cells. However, the charge controller is also capable of making SE measurements from measurements of the pack voltage, which may be during a probe signal or otherwise. To demonstrate the approach, if the SE reflects a value of 2.1 with a variability of +/−0.1 owing to the irregular effect of temperature across the pack. The charging/heating current is applied until the SE of the pack decreases to 2.00+/−0.05, indicating an increase in favorable and healthy pack dynamics and tighter distribution in total system entropy for less cell to cell variation within the pack. The heating aspect of the charging signal is applied in proportion to the standard charging signal in a manner that maintains this minimal allowable SE while also enabling the faster charge rate or a quicker transition and/or a more accurate transition to a faster charging rate.

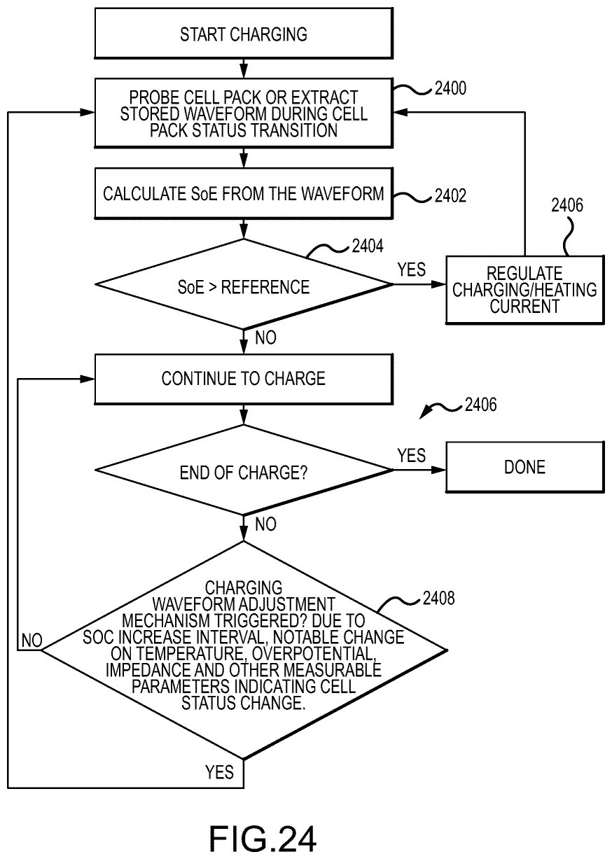

FIG. 24 illustrates a method of charging a battery, particularly under cold temperatures or with uneven thermal distribution across a pack, utilizing SE. Like other techniques discussed herein, the charging system probes the battery pack (operation 2400) to obtain measurements from which SE may be computed (operation 2402). These measurements may also be obtained during charge, or based on a momentary transition to a rest period, with no charge signal or from stored data. Once SE is computed, it is compared to a threshold or some other reference (operation 2404) correlated to regular or even temperature distribution across the pack. An example is an SE value of 2.00+/−0.05 at or below which indicates sufficiently even thermal distribution. The threshold, however, will be based on the battery cell type, pack arrangement if present, number of cells, environmental temperature and other factors.

If the SE and threshold indicate uneven thermal distribution, then a heating signal (alone or in conjunction with a charging signal) (operation 2406) may proceed in a loop until the SE value meets the threshold. If the SE value and threshold indicate sufficiently even thermal distribution, other charging protocols may proceed (operation 2406), including constant current, any of the various LE, CD or other electrodynamic charging techniques, as well as shaped waveform charging discussed in other patent applications of the Applicant. In an alternative, meeting the threshold may trigger a change in charge current magnitude, e.g., reducing charge magnitude.

In alternative to heating, the method may also or alternatively involve a threshold indicating a change in change in charge current is warranted. So, for example, a threshold may be set as a rate of change, and an abrupt change in SE may trigger a reduction in charge current or trigger assessment of a different electrodynamic parameter and related charge control.

Like other techniques discussed herein, charging may also proceed until end of charge, which may not include a constant voltage sequence as the technique here removes the need for it, or may continue until some state change in the battery indicating SE should be reassessed (operation 2408). For example, SE may be reassessed on a time schedule, based on SOC (e.g., every 1% SOC, every 2% SOC, every 5% SOC, or every 10% SOC), due to temperature change with the cell (e.g. a 1 C, a 1.5 C, a 2 C, a 2.5 C or other temperature change), a change in impedance, an indication of a change in overpotential, or reassessed due to some other state change, where operations 2400-2406 may be performed, and the charge signal may be altered, etc.

### SE to Inform an Electrochemical Thermal Model (ETM)

An Electrochemical Thermal Model for the BMS of an OEM's most popular lithium-ion battery is developed by extensive cycling and data collection from hundreds of cells cycled at different rates and temperatures. The job of the BMS is to prevent premature aging of the battery as well as catastrophic failure. The ETM uses inputs of voltage, current, temperature, and periodic OCV and DCIR measurements to understand the battery's health and operating condition. DCIR is a common measurement of DC Resistance, in which a large magnitude pulse is applied for 10-60 seconds in order to make a Voltage/Current type resistance measurement. Specifically, the ETM calculates basic thermodynamic parameters of entropy, enthalpy, and free energy (G), and references real time values against an internal model which associates these thermodynamic parameters with aging and state of charge. The ETM can accurately predict cycle life SOH to 88% of the true value under normal conditions, whereas that accuracy decreases to 67% at temperatures below 0° C. or after the cell has aged by more than 8% (capacity decrease of 8%). The accuracy may also be adversely impacted by variability of how the cells are arranged and constructed into packs, as the OEM cannot generate a unique ETM and accompanying warranty for every unique use case.

The cells are frequently used in portable devices, which are often plugged into charge while the device is in use. The resulting erratic energy flux through the cell due to ongoing, simultaneous bursts of charge and discharge currents complicate the ETMs accuracy, as the heat flux through the cell, and variations of mixed reversible endothermic and exothermic heat and irreversible ohmic heating. Estimation of thermal entropy based upon dV/dT quickly loses accuracy because thermal gradients change more rapidly than is detectable by the surface thermocouple. When this happens, the ETM is forced to halt charge for at least 30 seconds so that erratic flux is reduced, erratic heat flux abates, and so that entropy and OCV can be more reliably estimated.

A second generation of the ETM is redesigned to incorporate SE measurements. The accuracy and reliability of the SE measurement decreases the discrepancies between measurements and actual performance when the cell is used in different products. Because SE can be measured without the use of a temperature input, the calculation of thermodynamic parameters is significantly faster and more accurate. This makes the 2^{nd} generation ETM more reliable, easier to warranty, and capable of safely supporting faster rates of charge. Additionally, the thermodynamic lookup tables employed by the ETM are simplified because the increased accuracy means fewer exception edge cases need to be addressed and manageable by the BMS.

### SE to Quickly and Protectively Respond to Rapid and Destabilizing Changes in Cell Dynamics of a Lithium Sulfur Battery

The manufacturer of a lithium sulfur battery may be developing the technology to take advantage of the design's higher energy density compared to lithium-ion batteries. But they have several challenges which have been difficult to overcome through chemical or material advancements. First, LiS batteries require a lithium metal anode in order to match the higher energy capacity of the sulfur cathode. Preventing the irreversible loss of lithium through oxidation during charging through material and chemical advancements hasn't provided performance acceptable to product OEMs. Second, cycle life and retention of active material are both intrinsically problematic because of the complexity of redox and chemical processes at the cathode during cycling, and the varying diffusive and conductive properties of resulting transitory sulfur species. The functionality of the sulfur cathode requires transmutation from Li₂S>>transitory polysulfide species>dissolved sulfur>solid sulfur across the entire surface area, ideally in a sequential and uniform manner. However, the number of steps and thermodynamic-kinetic dependence of only some species on cell potential leads to exceptional spatial variation and grading of interfacial composition. The poor ionic and electronic conductivity of S/Li₂S₂/Li₂S hinders the cell stability. And the buildup of mobile polysulfides can partially migrate from the interface and contribute to irregularities in electrolyte viscosity. Impedance, alone, is ineffective at detecting these phenomena at an early enough stage to prevent their irreversible onset.

Due to the convoluted mix of reversible and irreversible processes, as well as the increase in chemical and electrochemical steps, the normal operation of LiS batteries involves a higher level of entropy and disorder than normal lithium ion or lithium metal batteries. SE is used to quickly and reliably detect and quantify changes in the entropy of this complex system.

A solution to the challenges may involve a map of healthy SE values as a function of SOC, Cycle Life, and Total Energy Throughput. For the flagship cell design, the SE is centered around 2.6 under healthy operating conditions. That is, when chemical and electrochemical reactions are well synchronized and concentration and chemical gradients inside the cell are low. Cycling data with the cell shows that SE may vary between 2.42 and 2.83, both boundaries indicating critical thresholds of order or disorder of internal chemical species, before the cause behind the shift becomes irreversible and degradation occurs. In one instance SE is monitored at the LiS cell is being charged. Suddenly, a sharp drop in SE from 2.6 to 1.8 is noted at 45% SOC. This value is known to occur due to a buildup of poorly conductive lithium-sulfur intermediate species, resulting a concentration gradient which has not yet impacted impedance measurements. The current is reduced from 1 C to 0.4 C so as to minimize the onset of a concentration gradient and impedance increase, while also maintaining a cell potential sufficient to continue reaction of the accruing intermediate species.

The ability to detect sudden changes in the order of the system before such changes impact impedance and voltage measurements is also used to control the cycled range of SOC. Rather than employing a CCCV or MCCV charging protocol, the cell may be charged with constant current from 72% SOC, and discharged to 12% SOC. The cell is especially susceptible to irreversible damage outside of these boundaries, reflected in sudden increases in impedance well before 0% or 100% SOC. However, instead of monitoring for critical SOC boundaries with impedance, SE is used to rapidly determine when a larger change in the entropy of the system occurs, and to halt charge or discharging processes as a result. By better responding to these changes in cell dynamics, the small but cumulative damage that would otherwise be incurred by using impedance in a similar capacity may result in greatly prolonged cell life and total energy throughput.

SE is also monitored during cell discharge. The cathode of LiS cells experience significant volumetric displacement during charge. Consequently, much of the cathode mass must be reconstituted during discharge, bearing some similarities to an electroplating process. The integrity of the cathode during discharge, and even the SOC during discharge, can be assessed by using SE to measure the degree of order during and at the completion of discharge. The SE at the end of discharge (as well as charge) can be used to assess the integrity of the cell components and distribution of lithium and other reactive species.

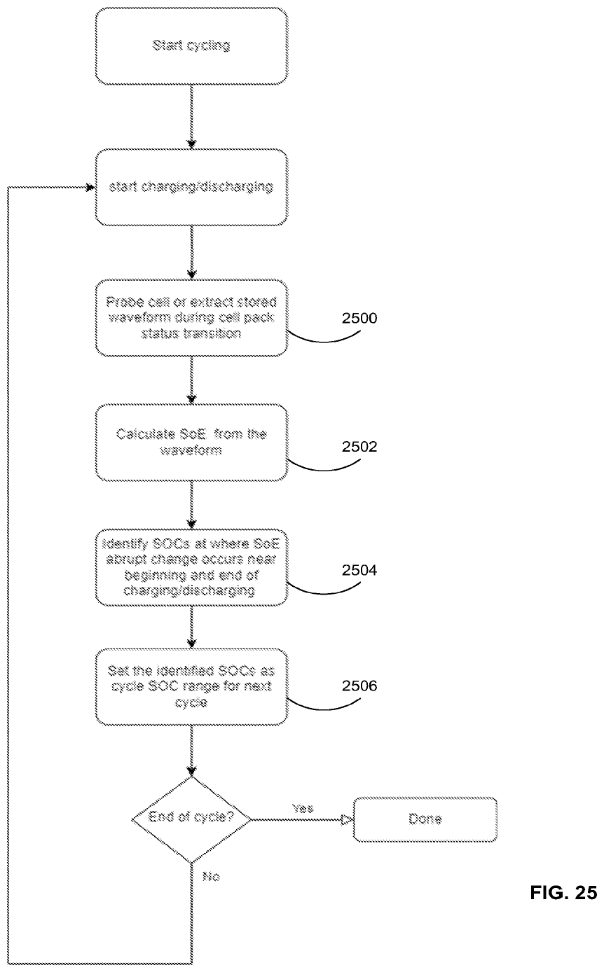

FIG. 25 illustrates an example of a charging method where SE is used to set a cycle range, e.g., beginning SOC and ending SOC, and charge/discharge cycles act within the cycle range. Like other methods discussed herein, SE is obtained (operation 2502) from measurements from the battery, which may be from a charge signal or probe signal (operation 2500). One of the advantages of the various techniques discussed herein is that they may occur in real or near real-time, and hence the techniques may be performed during charging. During a charge cycle, from any starting to any ending SOC, SE is monitored such as at every 1% SOC, every 2% SOC, every 5% SOC, or some other schedule, which may be more or less frequent depending on whether the charge cycle is relatively closer to fully discharged or fully charged. Upon detection of an abrupt change in SE (operation 2504) during a charge or discharge cycle, the abrupt change toward the end of charge (near 100% SOC) or toward the end of discharge (near fully discharged), the associated SOC values may be set as the range of discharge and charge (operation 2506). So, for example, if an abrupt change is found at 2% SOC, during discharge, the following discharge cycle may end at 2% SOC. Similarly, for example, during charge, if an abrupt change is found at 98% SOC, then 98% SOC may be set as a trigger or full charge indicator in the subsequent cycle. In this example, the following battery cycle would charge between 2% SOC and 98% SOC as compared to 0% SOC and 100% SOC in the cycle from which the abrupt changes were identified. The technique would redefine the upper and lower limits of a charge cycle.

### Hurst Exponent

The Hurst exponent (HE) is a measure of long-term memory in a time series. It helps us understand the persistence of trends or fluctuations in the data.

Step 1. Range Analysis: The system calculates the range (R(τ)) of the time series at different time scales (τ). The range is essentially the difference between the maximum and minimum value of V(t) within that time scale.

Step 2. Rescaled Range (R/S): For each time scale (τ), the system calculates the rescaled range (R/S(τ)) by dividing the range (R(τ)) by the standard deviation (σ) of the entire time series.

Step 3.Log-Log Plot: The system plots the log of the rescaled range (log(R/S(τ))) versus the log of the time scale (log(τ)).

Step 4. Hurst Exponent Estimation: The Hurst exponent (H) is estimated by the slope of the linear regression line fitted to the log-log plot. Here's the mathematical relationship:

$$log ( R / S ( τ ) ) \approx H * log ( τ ) + C$$

where C is the y-intercept of the regression line.

Turning now to examples of using HE, the Hurst Exponent (HE) and related metrics such as detrended fluctuation analysis can be used to understand the degree of self-similarity or self-affinity, or degree of persistence, in the voltage and current signals (and related battery signals such as impedance or others). Specifically, these metrics can be used to quantify the nature of diffusion processes occurring within the battery. Diffusion occurs through and across the anode material (often graphite), through the interfaces such as the SEI and CEI (cathode electrolyte interface), through the electrolyte, and through and across the cathode material. In Lithium-Ion batteries, the anode and cathode are both usually comprised of layers of packed particles, and diffusion between these particles, as well as intercalation into the particles, themselves, involve diffusion.

Strictly speaking, the diffusion of intercalating lithium ions through graphite particles at the anode or metal oxide particles at the cathode occurs after the ion has already exchanged its electron, and so this diffusion does not directly impact an electrodynamic measurement. But it does strongly impact preceding diffusive steps which do directly affect electron exchange so a strong secondary effect in the measurements can be detected.

Diffusion through the SEI can be impactful on electrodynamic measurements like Hurst/fBM despite also not involving charge exchange, as liquid electrolytes frequently result in an SEI with a 2× increase viscosity.

Diffusion through the bulk electrolyte as lithium travels between the electrodes also does not involve directly measurable charge exchange but strongly impacts the charge exchange processes at both electrodes.

Finally, when an ion reaches an electrode surface, a limited amount of lateral diffusion occurs across that surface before the ion transfers an electron. All of these effects strongly impact the exchange of electrons, which is ultimately what aspects of the present disclosure reflect through the computation of the Hurst Exponent, as well as other electrodynamic parameters, based on measurements of voltage and/or current at the battery. Therefore, strong relationships are present between the electrodynamic measurement, including HE and fBM, and each of these diffusive processes in the cell. DFA (detrended fluctuation analysis) may also be directly related to HE and fBM in these respects.

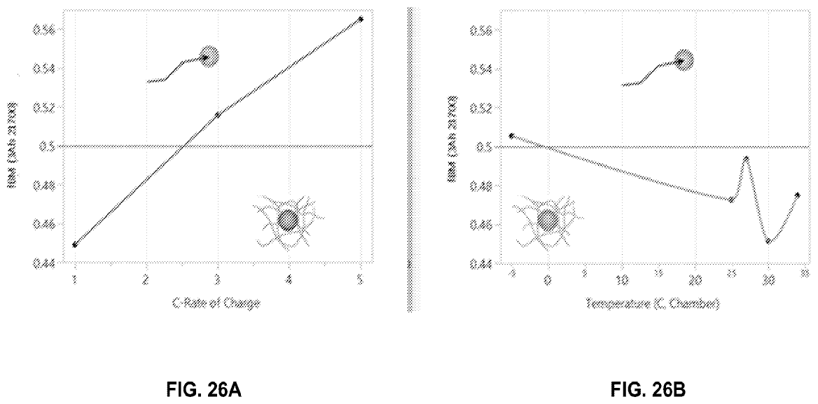

In the data shown in FIGS. 26A and 26B the Hurst Exponent, referred to on the axis as fBM because Hurst quantifies fractional Brownian Motion (fBM), is plotted vs C-Rate in FIG. 26A and vs Temperature in FIG. 26B. In FIG. 26A, a charge rate of 1 C through a 3 Ah power cell results in diffusive behavior through the cell which is described overall as mildly sub-diffusive, as expected for a combination of bulk and lateral diffusive processes. At a charge rate of 3 C, diffusion processes exhibit more influence from super-diffusive activity indicating stronger flow of ions through the electrolyte and electroactive layers. And at a charge rate of 5 C, the degree of super-diffuse activity increases almost linearly. This type of activity is feasible for an unaged power cell at SOC's between 20-50%, and may only be maintained for a limited period of time before diffusion begins to become more sub-diffuse due to reactant depletion and concentration gradients. This provides a means of identifying the available capacity of the cell based upon sustainable degrees of diffusion. Similarly, an increase in SEI thickness or cathode oxidation due to aging, for example, would increase sub-diffusive behavior at these rates and cause fBM values to trend downward. In this way, electrodynamic assessment of diffusion by way of HE can be used to help identify why a system is diffusion limited (or unconstrained) in addition to when it is so.

In the FIG. 26B plot, the cell temperature is controlled while charge rate is fixed at 1 C. At −5° C., net diffusion is primarily Brownian in nature for the unaged cell. This can occur at colder temperatures because the cell is more prone to lithium plating, which circumvents intercalation activity. As temperature increases at 25° C. and above, the variation in fBM is non-linear but broadly decreases due to the higher complexity of interfacial kinetics and greater increase in SEI growth, which favors sub-diffusion.

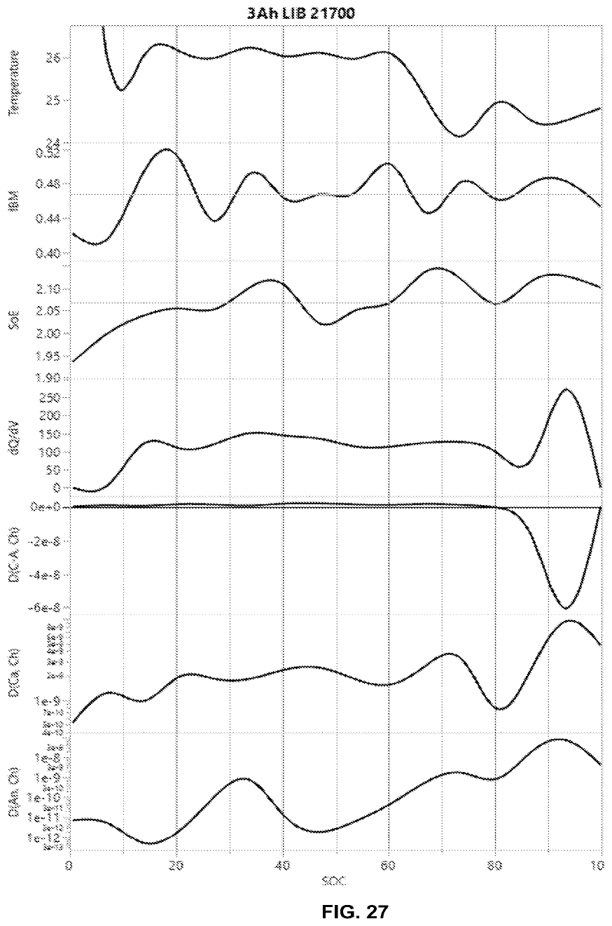

In the plot shown in FIG. 27, temperature (° C., surface), fBM, and SE are plotted together with several electrochemical measurements to demonstrate the relationship between electrodynamic and electrochemical data, which include dQ/dV and calculated diffusion coefficients (“D”, cm²/s) obtained from GITT measurements of a 3 Ah LIB 21700 power cell. Specific values of diffusion coefficients for the anode and cathode are calculated during charge, and the difference between the two (Cathode and Anode) is also shown.

Below 80% SOC, diffusion coefficients, D, for the cathode are slightly higher than the anode, indicating that the mild sub-diffusive behavior seen in fBM may be more descriptive of anodic diffusion processes. The first phase anodic phase transition seen in dQ/dV results in behavior which is more super-diffusive for a short time. Phase transitions are higher SOCs are associated with the cathode and involve more Brownian and sub-diffusive behavior. An increase in D^{Ca} above 30% SOC appears to cause a decrease in sub-diffusive activity as D^{An} remains relatively stable. Above 80% SOC, D increases for both electrodes, coinciding with a final oxidizing phase change at the cathode. However, D^{Ca} becomes strongly limiting and affects an increase in SE as well as less-sub-diffuse activity.

Diffusion is fundamental to understanding the performance and internal processes of a cell. Impedance methods based upon frequency response provide a limited understanding of diffusion. Electrodynamic calculation of fBM can augment or replace impedance information in understanding how to manage battery performance and state. The complex relationship between fBM and the other electrochemical parameters shown can be appreciated. A benefit of electrodynamic measurements, in contrast to the electrochemical parameters is their rapid, often sub-second acquisition, their sensitivity across wide ranges of temperature and rate, their ability to deconvolute data with and without the distinct probing signals employed in GITT and other electrochemical techniques, and their insensitivity to impedance in specific manifestations of the calculations. As faster rates of charge or discharge or applied, or as cell aging sets in and metrics like dQ/dV become more difficult or impossible to measure, electrodynamics maintain reliable fidelity and can reveal a broad range of useful metrics to comprehensively describe system function, including fBM.

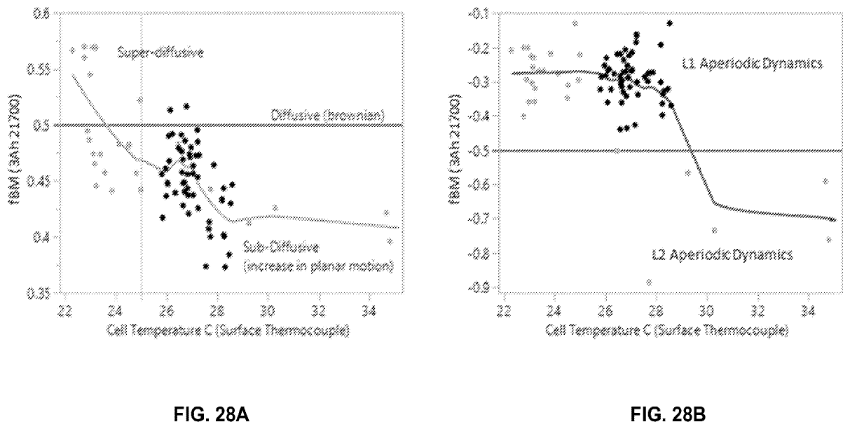

In the plots of FIGS. 28A and 28B, the diffusion characteristics of a 3 Ah LIB 21700 cell are monitored relative to temperature to understand when increasing temperatures may begin to result in sub-diffusive activities which lead to accelerated aging, as opposed to healthy, mildly sub-diffusive behavior. The data collected at 25° C. indicate that the cell is designed to operate with slightly sub-diffusive behavior as described by HE. Above 29° C., it appears that fBM values plateau. In this case, fBM is compared to the Lyapunov Exponent to quantitatively observe any concerning changes in cell dynamics. The LE shows that despite varying diffusive activity, between 22-28° C., the cell dynamics remain stable. However, above 29° C., the LE shows a shift in dynamics, specifically the onset of a parallel process occurring in addition to primary processes. In this instance, the voltage and current signals are coupled to the cell overpotential, and particularly to the anode overpotential (AOP). For this reason, the default quantitative interpretation of LE values does not apply (because the associated, critical behaviors are convoluted with the AOP) and instead, the LE further decreases as the anode potential drops below 0V (vs Li/Li⁺) and the onset of lithium plating introduces a steep increase in periodic behavior. This is consistent with the presence of two stable mechanisms, intercalation and plating, and with plating being a simpler process with fewer mechanistic steps than intercalation.

These points below LE of −0.5 do not exhibit the most sub-diffuse activity as compared to other points. Further, the highlighted points are the same between the two plots and shown zone of sub-diffusive operation which are healthy. These results show the temporary benefit that higher temperatures can provide to batteries: a fleeting relaxation in the diffusion-limited kinetics until secondary reactions including SEI growth, electrolyte gasification, and cathode oxidation eventually age the cell and decrease performance. In this case, the use of electrodynamic measurements allows for near instantaneous determination and distinguishment between healthy and aging modes of operation.

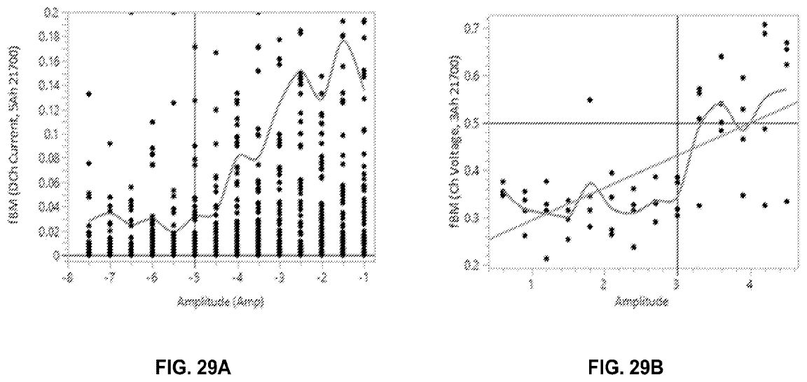

In the plot of FIG. 29A, a 5 Ah energy cell is discharged at an increasing rate to 7.5 A, and the electrodynamics of the current data are analyzed. A trend exists at all SOCs as shown in the data which indicates a distinct shift in fBM to a minimal value at current magnitudes above the cell's 1 C rate. This occurs because discharge rates approaching the areal capacity of the cell modify the net diffusive activity of the cell until the ion flux across the available area saturates. Further, values of fBM are notably lower here than for values typically observed during charge because discharge is electrochemically spontaneous. The states of the anode and cathode are returning to a more stable state.

For a 3 Ah LIB 21700 power cell (FIG. 29B)), increasing charge current results in a similar fBM response. fBM indicates a relatively stable, sub-diffusive behavior below a charge rate of 1 C. Above 1 C, the activity exhibits a sharp transition to more Brownian and super-diffuse values. In both plots of FIGS. 29A and 29B, the data can be used to measure the total capacity of the cell.

In an extreme example, the anode and cathode of a battery at 100% SOC could be connected via a low resistance path to intentionally short the cell to allow the highest possible spontaneous current flow supported by the components. In this case, the voltage will drop rapidly as the current rises to 20C or more. This occurs because ions on and in very close proximity to the electroactive materials rapidly diffuse and intercalate (or plate, in the case of a metal anode) and support a surge in current. The current will soon drop to a lower (though still very high) magnitude because the proximal ions have fully reacted with relatively fast kinetics, and their replenishment depends upon comparatively slow diffusive processes. Diffusion limitations result in exceptionally large and sustained concentration gradients and polarized interfaces at both electrodes. In this case, the system is behaving in a significantly sub-diffuse, diffusion-limited state.

In the more reasonable case of 1 C-2 C discharge, these effects are still apparent in the small values of fBM shown in FIGS. 29A and 29B.

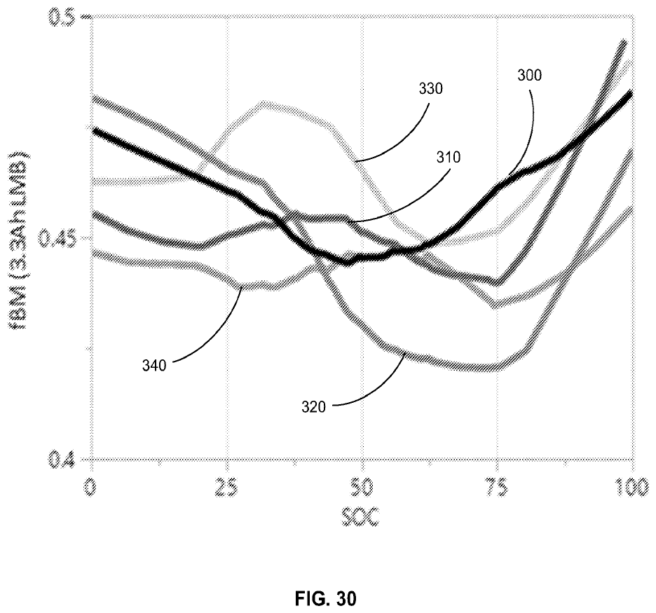

Considering a lithium metal pouch cell, the effects of dead and oxidized lithium, as well as an increasingly tortuous anode interface as aging rapidly onsets are both apparent in the plot of FIG. 30. Line 300 is Cycle 1, line 310 is cycle 20, line 320 is cycle 40, line 330 is cycle 60 and line 340 is cycle 80, the last before 20% loss in capacity.

Most notable about the cell at cycle 1 is the symmetric behavior of fBM below and above 50% SOC. LIBs also frequently exhibit a degree of symmetry around 50% SOC, although the trends for the LMB are far steadier and linear. By the 20^{th} cycle, the symmetry is lost and the lowest values occur near 75% SOC. By 40% SOC these lowest values have broadened and by cycle 60 (line 330) an anti-symmetry has developed. The final cycle (line 340) shows a tighter and more sub-diffuse grouping of fBM across all values of SOC, and the onset of a new symmetry. This new behavior is strongly influenced by the limiting performance of the aged and dendritic anode, where as the symmetry of cycle 1 was more reflective of the cathode. The evolution of cell aging and the ranges of SOC which are mostly strongly affected at different stages are apparent in this comparative data.

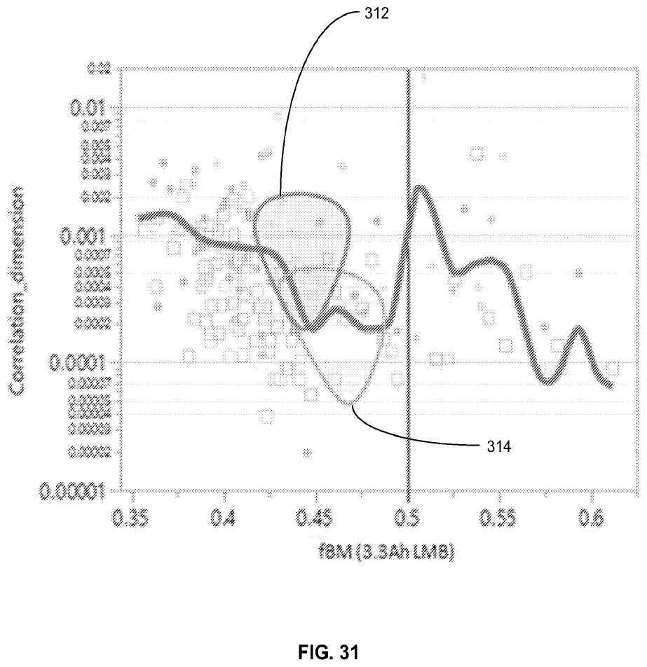

An examination of LMB cells from a different data set shown in FIG. 31, comparing correlation dimension (y-axis) vs fBM (x-axis) and Lyapunov Exponent (marker shapes) shows that higher degrees of degradation indicated by the LE (dots) correlate with higher values of electroactive surface roughness and more sub-diffuse activity (ellipse 312, greatest 10% density of points). The points indicating lowest degree of degradation correlate with lower electroactive roughness and less sub-diffuse activity (ellipse 314, greatest 10% density of points).

These three metrics (and others like them), alone or in combination, can be used for a better understanding of SOH and real time degradation.

### Using Hurst and fBM to Estimate Cell Capacity

In a hypothetical example, a lithium battery recycling facility receives batches of lightly used cylindrical cells which it must assess for second life uses by categorizing and grading into different sub-batches. A particular challenge is the circulation of cells from unreliable manufacturers which are inevitably received at the facility. From such sources, produced cells may carry similar model numbers and yet exhibit widely varying performance characteristics, in contrast to grade A cells from tier 1 battery manufacturers. In a particular case, 21700 cells sourced from a supplier with less build consistency are in question and need to be graded to determine the safe and appropriate second life application.

It is cost and time-prohibitive for the facility to completely cycle all received cells in order to measure SOH based upon one complete cycle. Instead, in accordance with aspects of the present disclosure, cells may be quickly assessed using a rapid contact test based upon fBM capacity assessment. Contact with the anode and cathode is quickly made via probes followed by a 1-2 second test in which fBM is calculated for increasing magnitudes of briefly applied current. The current begins at small magnitudes and may proceed in sequential positive and negative polarities. In various possible arrangements, current and/or voltage may be monitored as the current magnitude is increased. The current may be increased at a gradual rate to ensure magnitudes in excess of the cell's safe capacity is not exceeded while monitoring the fBM response at each current level to identify critical transitions in dynamic behavior.

In one instance, the fBM indicated by the current signal shows an increasingly sub-diffuse trend with increasing current magnitudes until a plateau is measured above 5 Amps. This quickly estimates the cell's capacity to be 5 Ah. A second cell with the same markings exhibits contrasting behavior, in which the voltage reading shows a sharp decrease in sub-diffuse character above 3 Amps, indicating an available capacity of 3 Ah.

Whether or not the differences between the two cells in the test group are due to poor construction, poor labeling, or varying degrees of aging, the facility is able to use this technique to process hundreds of cells or more per hour and reliably categorize cells into capacity-based grades for second life use.

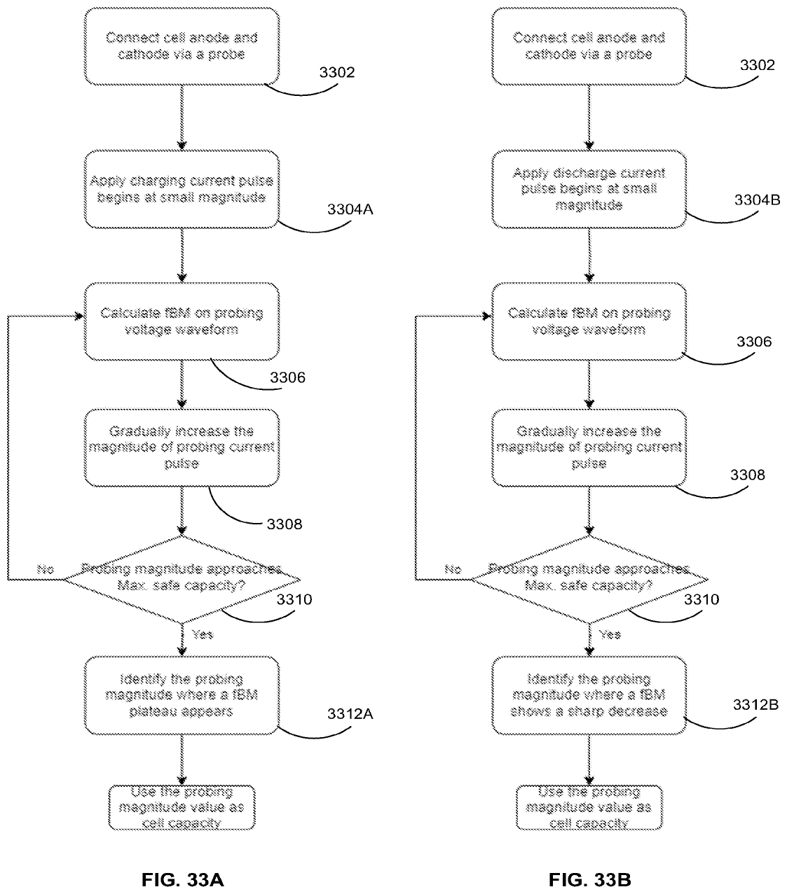

FIGS. 33A and 33B illustrate methods of using HE and fBM to estimate cell capacity in charge or discharge, respectively. The two methods are similar and will be described coextensively. In both methods, the cell anode and cell cathode include a probe through which measurements may be taken (operation 3302). In assessing cell charge capacity, a charging current pulse is initiated with a relatively small magnitude (operation 3304A)—e.g., 1 C. Similarly, in assessing cell discharge capacity, a discharge current pulse is initiated also with a relatively small magnitude (operation 3304B)—e.g., 1 C. Other charge and discharge pulse magnitudes are possible, and they do not need to be the same or equivalent. Further, pulse magnitudes may be incremented at different levels, e.g., 0.1 C increments, 0.5 C increments, 1 C increments, and the like as the methods are run.

For each pulse, fBM is computed from voltage measurements of the probing pulses (operation 3306). In both cases, the magnitudes of the probing pulses are increased, and fBM values are computed (operations 3308) until the an end, e.g., maximum, probing magnitude for the cell type is reached (operation 3310). After the fBM values are obtained for the range of probing currents during charge, in charge cell capacity analysis, the system identifies the probing magnitude associated with a plateau in the fBM computations. The associated probing magnitude may be set as the cell capacity. For example, if a plateau is identified at a 5 amps charging pulse, then the capacity may be 5 Ah. After the fBM values are obtained for the range of probing currents during discharge, in discharge cell capacity analysis, the system identifies the probing magnitude associated with a sharp decrease in the fBM values. The associated probing magnitude may be set as the cell capacity. For example, if a sharp decrease is identified at 3 amps discharging pulse, then the capacity may be 3 Ah. Charge or discharge capacity may be used to set capacity, or charge and discharge used with the lower value being used to set capacity, or one value being used as a check against the other.

### Pack Screening to Identify Usable Capacity and Detect Unavoidable Cell Degradation

In a different hypothetical department of the same second life facility introduced in the previous example, intact packs from used electric vehicles are broken down into modules of 60 cells. The modules need to pass performance and safety qualifications for second life use in a municipal grid storage application. The modules undergo an initial assessment of two complete charge/discharge cycles to determine whether the pass criteria of at least 70% capacity retention is met. Voltage, Current and/or Impedance information may be collected, as well as an fbm assessment in accordance with aspects of the present disclosure which can provide tighter margins for Pass/Fail tests.

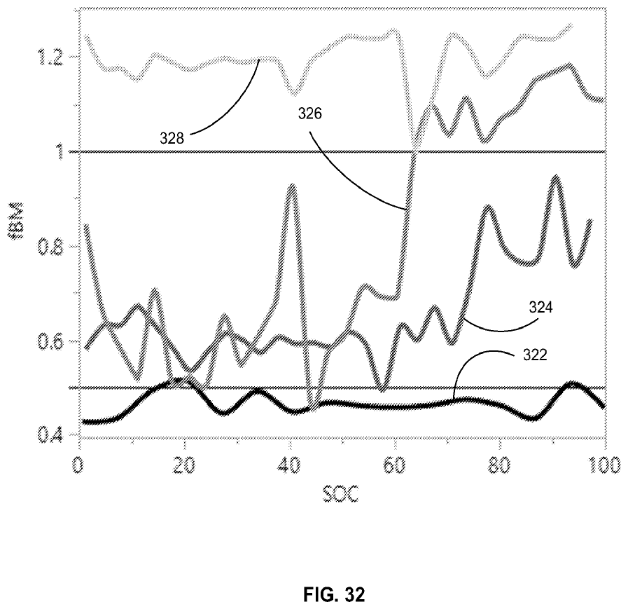

Four modules which occupied different positions in the original pack can be tested and compared by fBM performance during a complete charge from 0-100% SOC as shown in FIG. 32.

In the case of a module from the center of the pack (line 322), fBM behavior is relatively flat and consistent with mildly sub-diffuse behavior as expected for healthy cells. Slight increases to super-diffuse behavior occur only during the largest phase transitions of the anode (19% SOC) and cathode (93% SOC) as expected.

A second module (line 324), originates closer to the exterior of the pack, shows mildly super-diffuse behavior which begins to increase above 70% SOC-signs of potentially acceptable capacity loss. A capacity loss of 25% (1 C cycling) and 2% (0.2 C cycling) are reported by total energy tests. Two rates of cycling are tested because aged modules and packs may report higher levels of capacity retention at low rates, whereas the same cell may exhibit smaller capacities at higher rates, depending upon degree and mode of aging. The fBM results show that this module should not be cycled above 70% SOC even though the MCCV protocol would indicate otherwise.

The third module (line 326) shows similar yet more erratic behavior (below 50% SOC) as the second module. However, above 60% SOC the reported fBM increases sharply and exceeds a value of 1, which might be set as threshold in some aspects of the present disclosure where HE or fBM are used in charge control. The cycling data reports only 30% (1 C) and 3% (0.2 C) capacity loss, which fBM analysis has shown does not reflect the actual degradation dynamics occurring inside the cell during operation. This discrepancy between electrochemical and electrodynamic measurements illustrates why cell and packs cycled with M/CCCV protocols often experience sudden drops in capacity over a very small number of cycles: the CV stage does not adequately protect cell SOH nor indicate when cell charging should stop. While the cycling and impedance data indicated a Pass, the fBM measurements indicated the need for the module to fail the test.

Like the third module, the fourth module (line 328) shows fBM values above 1, instead for the entire SOC range. The module has an imminent failure risk and must instead be recycled for material recovery rather than find use in a second life application. fBM values above 1 indicate a higher degree of non-stationary content in the data arising from complex cell activity. Such activity which is not removed from the data during detrending pre-treatments suggest complex degradation that cause imminent cell failure. For this reason, the third and fourth modules should both recycled rather than reused based upon measurements from fBM which show the usable range of SOC for both cells are too diminished.

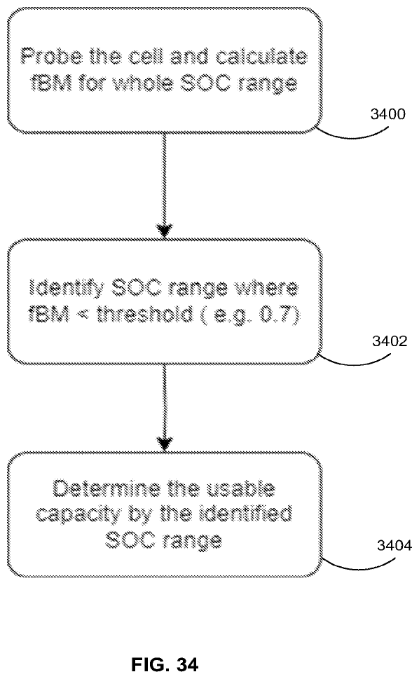

FIG. 34 illustrates a method of using HE or fBM to identify usable capacity. In this example, the cell is probed during a charge cycle and fBM values are calculated at each 1% SOC (or other gradation) as the cell is charged fully (operation 3400). The SOC where fBM meets or falls below a threshold, e.g., 0.7, is identified (operation 3402) and the usable capacity is set based on the those values (3406).

For example and in the context of FIG. 29A, as a battery of unknown capacity is charged, short probing signals of ordinally increasing amplitude are applied and fBM is calculated. The smallest amplitudes tested depend upon the minimum currents supported by the available hardware. The timing of the probing signal may be at least as long as the characteristic time of a coherent, capacitive feature in a Nyquist plot obtained by EIS or similar impedance method. The amplitude of probing may continue to increase by small increments until a plateau (particularly when discharging), a sharp transition (particularly when charging), or a predetermined threshold (charging or discharging) value is observed in the fBM behavior. Such behaviors provide an estimate of the battery's capacity in Ampere-hours which in direct proportion to the probing magnitude in Amperes at which the behavior is noted. Transitional fBM behavior in response to a 4.4 A magnitude probing pulse may indicate a remaining battery capacity, or SOH, or 4.4 Ah. Charging (or discharging) may continue for an additional capacity, which may be estimated at 1% SOC based upon prior measurements, until probing is repeated. Repeating the process provides ongoing refinement of a battery capacity estimate. It is not necessary to fully charge or discharge a battery other than as a means of collecting additional data, or to verify the chargeable or dischargeable capacity of the battery based upon comparison to other metrics (such as dQ/dV, CCCV-type SOH determination, or deterministic parameters discussed herein). A critical benefit of this approach is the ability to estimate SOH without fully cycling the battery.

### Charging Signal Construction

### Harmonic Based Signals

The goal of Harmonic Analysis is to identify how harmonics should be represented in a calculated charge signal. Creation of the charge signal in this case is referred to as Harmonic Assembly. Harmonic Analysis may be conducted by providing any stimulus to the battery with a known frequency content, and from which the perturbations in the signal that vary from the idealized signal can be measured. For example, the battery may be probed with chirp signals at specific frequencies (discrete, continuous, or other). A unipolar or bipolar pulse of fixed timing characteristics may also be used. In both cases, the signal can be detrended, such that the idealized sine wave is removed from a chirp signal, leaving only the perturbations for electrodynamic analysis. All aspects of the data are associated with specific phenomena with different dynamics. In general, the method of detrending and the particular content removed from the data should further reveal the phenomena whose dynamics are of greatest interest.

Harmonic analysis using any of the parameters discussed in this document may be used alone or collectively to create a charging signal which is optimized to protect the health of the battery, to prioritize performance, to minimize or maximize heat generation, or other performance goals, or some combination of weighted performance goals by selecting the appropriate parameters. While various techniques discussed herein may refer to altering charge magnitude responsive to the various parameters, altering the charge signal may also involve defining harmonic attributes of the charge signal.

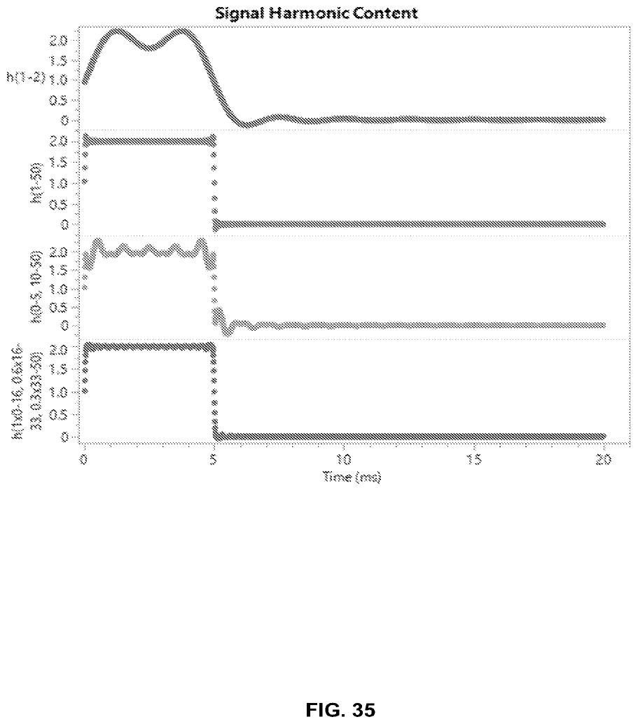

Several examples of harmonic assembly are shown in the FIG. 35 diagram to create an optimized charging (or discharging) signal.

In the top plot, a primary harmonic and its secondary harmonic are combined to create a harmonically optimized stimulus.

In the second plot from top, the first 50 harmonics are combined to create a wider bandwidth stimulus.

In the third plot from top, the stimulus is the same as the previous, except that the 6th-9^{th} harmonics are omitted. This would be similar to instances in which harmonic analysis indicated a narrow bandwidth which resulted in damage or inefficient energy transfer to the battery.

In the bottom plot, the first 16 harmonics are scaled to 1, while the 17th-33^{rd} harmonics are scaled to 0.66, and the 34th-50^{th} harmonics are scaled to 0.33.

The examples above indicate how harmonics may be selectively augmented, decreased, or removed entirely according to the appropriate scaling indicated by electrodynamic parameters. Hence, thus when a charging technique based on one of the parameters discussed herein suggests defining or altering a charge signal, harmonics of the charge (or discharge) signal may be may be scaled, added, or removed when it is necessary to decrease charge current magnitude, increase current due to a max current limitation supported by hardware, or when less constrained hardware capabilities enable a more optimized set of harmonics while still meeting charging rate and time goals, if applicable.

It is not necessary for harmonics to return to 0 Amps. Harmonics may exhibit a minimum value which reverses current or voltage polarity, or may be applied with a DC bias.

Higher mean charge or discharge currents may also be achieved by applying higher magnitude harmonics more frequently, and in lieu of very low magnitude harmonics. For example, in the plots above, the body of harmonics from 0-5 ms may be repeated any time after 5 ms in order to achieve the desired current. Repeated harmonics should be applied with consideration to the signal characteristics at the time of start, and specifically to avoid introducing any undesirable harmonics in a transition from low magnitude (at or near 0) to high magnitude harmonics.

Alternatively, the harmonics may be applied in a continuous manner, in which the harmonics are periodic and potentially varying in magnitude on a per-harmonic (or selective bandwidth) basis.

In any case, the signal may be continuously monitored to assess the performance and degree of optimization as indicated by both electrodynamic and electrochemical parameters.

### Pulsed Type Charge Signals

Pulse signals may be applied by breaking down a pulse into sections. The leading edge of the pulse may be electrodynamically assessed to ensure parameters like LE, CD, SE, and HE yield acceptable values. If not, the leading edge of the pulse may be adjusted appropriate to obtain more optimal results. So, for example, based on LE, CD, SE and/or HE, the shape, slope, or other attribute of the leading edge of the pulse may be altered. For example, in the presence of a positive LE value, the shape of the leading edge may be modified to produce a less abrupt transition, and then the LE value reassessed.

The appropriate leading edge timing characteristics may also be determined using the Harmonics Analysis described above.

The body period of a pulse may be treated similarly, by measuring the perturbations on the signal to assess whether the pulse should continue, end, or be adjusted in a subsequent pulse. For example, a pulse length which begins to cause degradation may exhibit a decreasing value of HE, potentially past a threshold. As such, the width of subsequent pulses is decreased.

A pulse charging signal may include an OFF period or rest period between pulses, and the OFF period can be determined by how coherent and unchanging are the results of electrodynamic analysis. For example, an OFF period may be too short if the dynamics are unfavorable, or if the indicated dynamics continue to change as the OFF time is increased. The OFF period at which dynamics stabilize may be taken as a sign of the cell reaching optimal equilibrium. For example, the rest period may be gradually increased among sequential pulses until the resulting measurement plateaus to a stable value, at which point the rest period is sufficient.

The dynamics are different portions of the pulse may be analyzed separately or together. Separate analysis may be preferable as different sections of a pulse stimulate the battery in different ways, and isolating these effects is usually desirable. Such analysis may be done periodically, in real time, or pulse definitions may be done in advance of charging with or without changing to the pulse signals during charge.

Pulses may be measured directly to obtain electrodynamics measurements, or a distinct probing signal may be applied to assess the battery's response to baseline stimulus (a benchmark, for example the cell's response to 3 A current may be used as a benchmark at any SOC or SOH), or potential charging conditions, or to see how close a cell is to an important threshold, such as end of charge.

The falling edge of a pulse may decrease to values of 0 Amps or to values above or below zero as indicated by the optimal dynamic response of the edge. Conventional pulse charging typically has an undefined and very sharp leading edge and usually returns the current to 0 Amps for several reasons: To let the cell relax/rest and return to internal equilibrium, to measure voltage drop to inform measurements of impedance or open circuit potential, and to decrease overpotential. The logic of these methods as applied to closed battery systems is frequently weak or flawed, whereas open systems provide better circumstances to take advantage of rest periods by allowing other forms of energy inputs to accelerate return to equilibrium (stirring, sparging, addition of new reactants, etc.). In any case, electrodynamic measurements provide insight into the cell's state of recovery without the need to identify impedance, resting potential, or overpotential.

### Continuous Wave Signals

A continuously variable charging signal may be most effectively applied when variations in cell dynamics are sufficiently stimulated. Sufficient stimulation may occur:

Using a probing signal to elucidate the nature of the dynamics present at different levels of current and voltage.

When the charge rate is sufficient to induce changes in the dynamics of the cell, such as rates of fast charge.

When significant changes are occurring within the battery, such as phase changes at the anode or cathode, a sudden change in temperature, and the start of lithium plating and electrolyte breakdown, among others. One important implication here is that continuous monitoring of a cell's voltage and/or current, even if the current is completely flat as with CC charging, can be used to quickly detect sudden internal temperature changes which may precede cell failure or a thermal event, before the change is visible to a temperature probe like a thermocouple.

Alternatively, whether cell dynamics are unstable or stable, using electrodynamic measurements as inputs into a method of predictive control can also be used to reliable control charging current and voltage. All parameters can be continuously monitored, or monitored based upon intervals or triggers from other measurements or devices such as BMS flagging.

Rather than a distinct probing signal, a signal adjustment may be incorporated as a calculated increase or decrease in current or voltage to measure the system's electrodynamic response and probe the dynamic state:

Such adjustments may occur in incremental order, continuing until electrodynamic parameters indicate an optimal value in current or voltage is achieved.

Such adjustments may also be a continuous rather than incremental or discrete.

Adjustments may follow a prescribed rate of change.

The electrodynamic response of an increase in current or voltage may be compared to a preceding or subsequent decrease.

The dynamics of the cell may be probed and stimulated by a source of perturbation other than voltage or current, such as an environmental temperature change, mechanical agitation, introduction or chemical species (as with electroplating), and very small increases in current or voltage above distinct thresholds such as a thermodynamic boundary. In the last case, the change in voltage may be very small relative to a metric such as the cell's overpotential or impedance, but still be enough to cross a key thermodynamic boundary such as 0V vs Li/Li⁺, Co/Ni/Fe, etc.

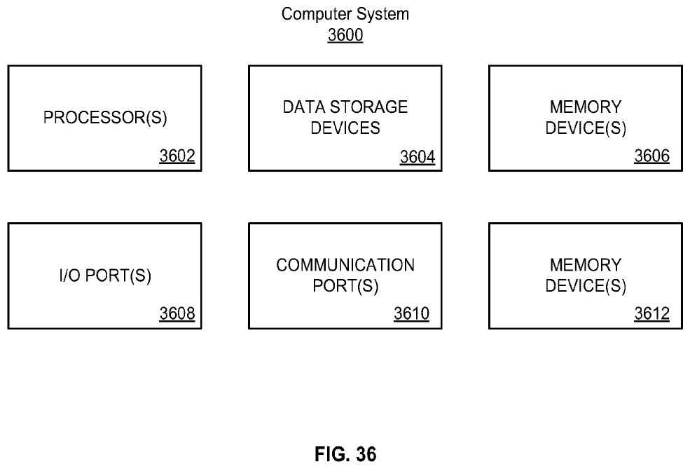

Referring to FIG. 36 (immediately above), a computer system 3600 includes various processing components that may be involved in a battery module, or a device involved in managing a battery or controlling the same. The various electrodynamic parameters (e.g., LE, CD, SE, and HE) may be computed by a computing system (and/or a processor or other component of such a system or a controller or MPC incorporating some form of processing device) and the computing system may provide control signals to a charger or other form of power supply to produce a charge signal, along with other things discussed herein. The system 3600 may be a computing system that is capable of executing a computer program product to execute a computer process. Data and program files may be input to the computer system 3600, which reads the files and executes the programs therein. Some of the elements of the computer system 3600 are shown in FIG. 36, including one or more hardware processors 3602, one or more data storage devices 3604, one or more memory devices 3606, and/or one or more ports 3608-3612. Additionally, other elements that will be recognized by those skilled in the art may be included in the computing system 3600 but are not explicitly depicted in FIG. 36 or discussed further herein. Various elements of the computer system 3600 may communicate with one another by way of one or more communication buses, point-to-point communication paths, or other communication means not explicitly depicted in FIG. 36. Similarly, in various implementations, various elements disclosed in the system may or not be included in any given implementation.

The processor 3602 may include, for example, a central processing unit (CPU), a microprocessor, a microcontroller, a digital signal processor (DSP), and/or one or more internal levels of cache. There may be one or more processors 3602, such that the processor 3602 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 3604, stored on the memory device(s) 3606, and/or communicated via one or more of the ports 3608-3612, thereby transforming the computer system 3600 in FIG. 36 to a special purpose machine for implementing the operations described herein.

The one or more data storage devices 3604 may include any non-volatile data storage device capable of storing data generated or employed within the computing system 3600, such as computer executable instructions for performing a computer process. The one or more memory devices 3606 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 3604 and/or the memory devices 3606, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 3600 includes one or more ports, such as an input/output (I/O) port 3608, a communication port 3610, and a sub-systems port 3612, for communicating with other computing, network, or vehicle devices. It will be appreciated that the ports 3608-3612 may be combined or separate and that more or fewer ports may be included in the computer system 3600. The I/O port 3608 may be connected to an I/O device, or other device, by which information is input to or output from the computing system 3600. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 3600 via the I/O port 3608. In some examples, such inputs may be distinct from the various system and method discussed with regard to the preceding figures. Similarly, the output devices may convert electrical signals received from computing system 3600 via the I/O port 3608 into signals that may be sensed or used by the various methods and system discussed herein. The input device may be an alphanumeric input device, including alphanumeric and other keys for communicating information and/or command selections to the processor 3602 via the I/O port 3608.

The environment transducer devices convert one form of energy or signal into another for input into or output from the computing system 3600 via the I/O port 3608. For example, an electrical signal generated within the computing system 3600 may be converted to another type of signal, and/or vice-versa. In one implementation, the environment transducer devices sense characteristics or aspects of an environment local to or remote from the computing device 3600, such as battery voltage, open circuit battery voltage, charge current, battery temperature, light, sound, temperature, pressure, magnetic field, electric field, chemical properties, and/or the like.

In one implementation, a communication port 3610 may be connected to a network by way of which the computer system 3600 may receive network data useful in executing the methods and systems set out herein as well as transmitting information and network configuration changes determined thereby. For example, charging protocols may be updated, battery measurement or calculation data shared with external system, and the like. The communication port 3610 connects the computer system 3600 to one or more communication interface devices configured to transmit and/or receive information between the computing system 3600 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 3610 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 3600 may include a sub-systems port 3612 for communicating with one or more systems related to a device being charged according to the methods and system described herein to control an operation of the same and/or exchange information between the computer system 3600 and one or more sub-systems of the device. Examples of such sub-systems of a vehicle, include, without limitation, motor controllers and systems, battery control systems, and others.

The system set forth in FIG. 36 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

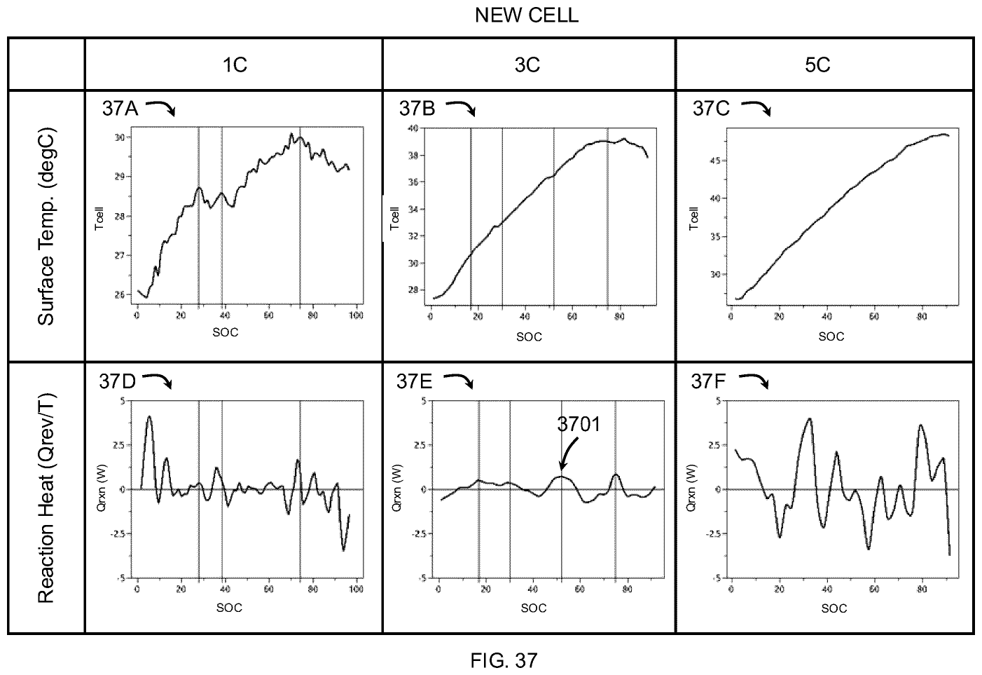

Further discussion of battery parameters that may be used to control battery charging (e.g., in real-time or through battery characterization) is provided below with respect to FIGS. 37-45. New and aged battery cells were charged at 1 C, 3 C, and 5 C rates to obtain data on various parameters for analysis. Plots were generated to show chemical heat generation, surface temperature, Lempel-Ziv complexity, diffusion potential, randomness of battery processes, chaotic versus periodic cell behavior, battery entropy, and fractal dimension of a battery. Plots of each variable are provided over a full State of Charge (SOC) range for each of the six conditions (i.e., new cells at 1 C, 3 C, 5 C and aged cells at 1 C, 3 C, 5 C). The following discussion provides detailed information about each data set and describes how the various parameters may be used alone or in combination to dynamically adjust charging current to minimize the occurrence of detrimental processes and preserve battery health over time. While exact values discussed herein may be specific to this particular data set, battery cell chemistry, and other environmental conditions, the general concepts apply to all batteries. Data trends discussed herein may be used to gain understanding of a battery's condition and/or control charging in new ways based on real-time data.

Reaction Heat versus Surface Temperature

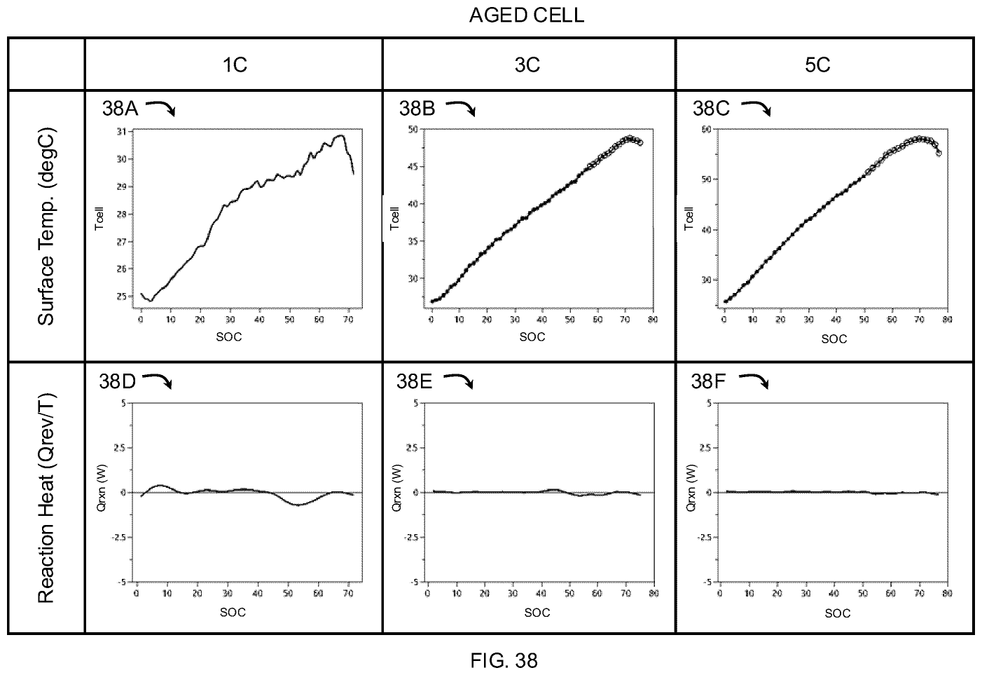

FIG. 37 shows graphs 37A, 37B, and 37C which plot surface temperature measurements as a function of State of Charge % (SOC) for charge rates 1 C, 3 C, and 5 C, respectively. Graphs 37D, 37E, and 37F plot reaction heat (i.e., heat generated by chemical or electrochemical processes) as a function of SOC for charge rates 1 C, 3 C, and 5 C, respectively. The reaction heat value may be determined using sample entropy and is a more accurate representation of heat generated within the battery than can be obtained using a temperature probe. The graphs 37A-37F show data for a new battery cell. Surface temperature measurements and reaction heat measurements for aged cells at the different charging rates are provided in graphs 38A-38C and 38D-38F, respectively, in FIG. 38.

Surface temperature measurements reflect a combination of ohmic heating and reaction heating of the battery. While ohmic heating is the primary component of the overall surface temperature measurement, reaction heat also contributes. With higher charge rates, the proportion of ohmic heating to reaction heat generation increases and may mask the effect of reaction heat in the overall surface temperature measurement. This accounts for the smoothing of the surface temperature measurement, particularly at 3 C and 5 C rates. Additionally, the specific battery tested to obtain the data presented in FIGS. 37 and 38 excels at dissipating heat, which also diminishes the visible impact of the reaction heat on the overall temperature of the battery. However, certain trends can still be observed in the data.

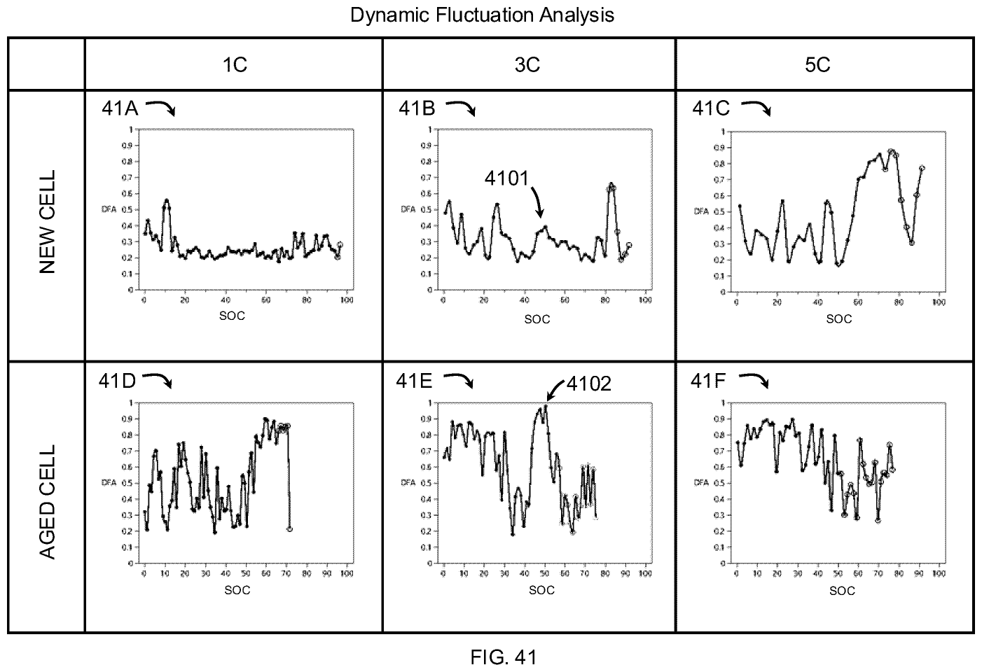

A notable feature in the data occurs in the reaction heat graph 37E for a new cell charged at 3 C. At around 50% SOC, a temporary increase in the reaction heat is marked by arrow 3701. This increase may represent an increase in heat generation due to the electrochemical and chemical activity within the battery cell. This increase also correlates with a large increase in diffusion, which will be discussed with respect to arrows 4101 and 4102 in graphs 41B and 41E, respectively, in FIG. 41.

Referring to the reaction heat graphs 37D-37E for new cells, certain portions of the data indicate higher levels of heat generation. For example, high levels of heat are generated between approximately 0-10% SOC for the 1 C charge rate. If it is known that a high amount of chemical heat is being generated, charge rate may be reduced to decrease the ohmic heat being generated during that time. Thus, charge rate may be used to increase or decrease generation of ohmic heat in order to balance out total heat such that rate of temperature increase is controlled to improve battery health. Alternatively or additionally, high or sustained levels of reaction heat generation may be used as a trigger to analyze other parameters discussed herein in order to gain further insight into processes that are occurring within the battery and to take mitigating action in the form of charge current control.

Referring back to FIG. 38, plots are shown for an aged cell. The reaction heat plots show lines of best fit rather than data points, which tend to exhibit high levels of variability. The line of best fit illustrates that for aged cells, net heat generation from electrochemical and chemical processes is greatly reduced. This is due to the gradated onset of different processes rather than processes which occur in discrete steps as seen in new cells. Faster charge rates result in reduced net reaction heat generation due to the higher irregularity and variability in onset of different processes within the cell. To regain regularity and uniformity in the processes occurring within the battery, and by extension the reaction heat generation data, charge rates may be greatly reduced (e.g., below 1 C). Such an adjustment may allow processes within the battery to sync in a more uniform way, leading to more net thermal behavior.

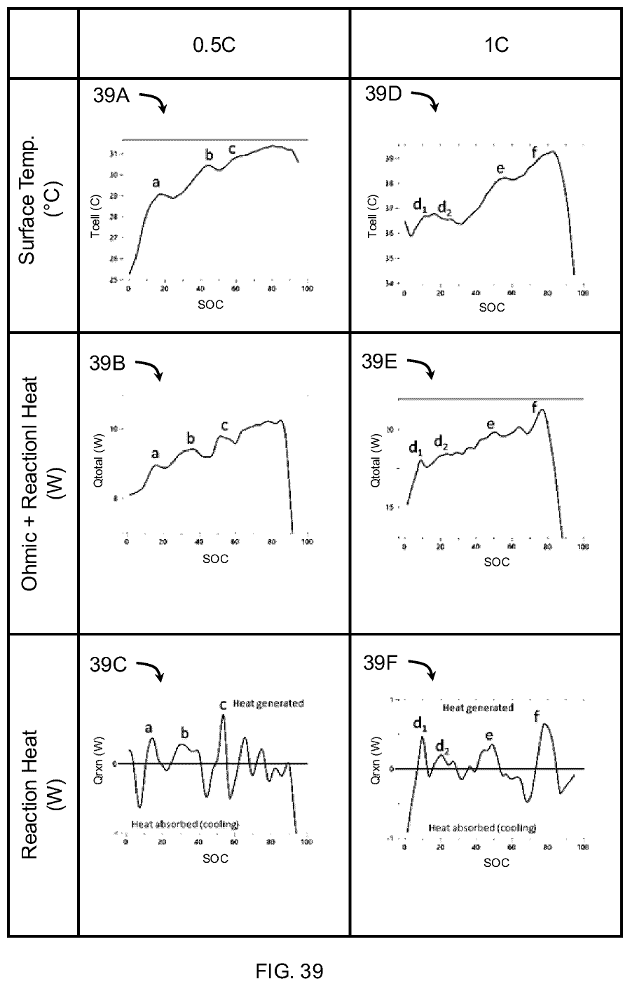

Referring to FIG. 39C, additional comparisons of surface temperature, combined ohmic and reaction heat, and reaction heat plotted over SOC are provided for an energy cell (21700, % Ah) with thick electrode layers and comparatively poor thermal dissipation. Comparisons for 0.5 C and 1 C charge rates are provided. Referring initially to graphs 39C and 39F, spikes in reaction heat generation are identified as points a, b, and c for the 0.5 C case and d1, d2, e, and f for the 1 C case. Looking at graphs 39B and 39E, ohmic and reaction heat generation is plotted, and the contribution of spikes as labeled in plots 39C and 39F is noticeable. The same points a-f are identified. Referring finally to graphs 39A and 39D, surface temperature as measured by a temperature probe is plotted over SOC. The same labeled points a-f are included, and it can be seen clearly that the reaction heat contributes to the shape of the temperature plot. Thus, the identification of a spike in reaction heat generation is correlated to an increase in surface temperature of the battery and may be useful in early detection of a thermal event.

Reaction heat data may be produced in substantially real-time during a battery charge without stopping the charging signal for probing. The ability to receive and analyze reaction heat data may support rapid adjustments to control charging currents. In some embodiments, thermal runaway events may be detected quickly and charging currents may be adjusted (e.g., decreased or stopped entirely) in order to prevent hazardous escalations more quickly than is presently possible using surface temperature measurements. A mitigating adjustments may be made in response to a specific trigger, such as a reaction heat data point being greater than a threshold data point, a rate of increase of reaction heat over an SOC range that is higher than a threshold rate of increase, a sustained reaction heat increase over a range of SOC values, and/or other triggers that may be determined based on specific behavior of cells. In some embodiments, current may be throttled to maintain a desired rate of heating or cooling, to maintain stable temperature operation, and/or to stay within an ideal temperature profile for the battery. If a sharp increase in heat generation is detected, current may be stopped to circumvent thermal runaway.

### Cell Process Predictability (Via Lempel-Ziv Complexity)

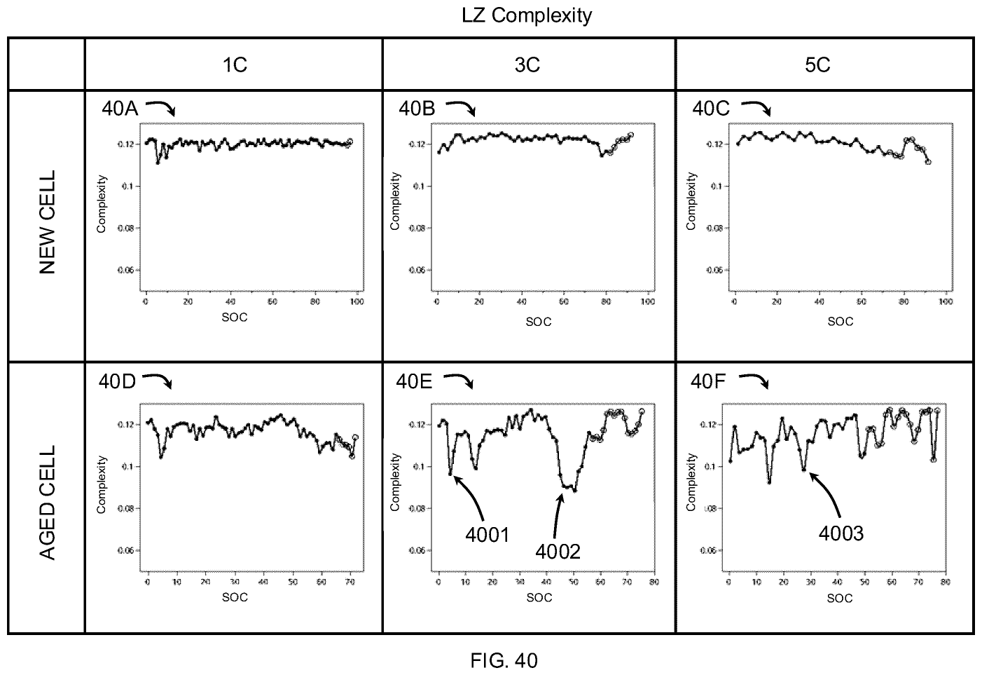

FIG. 40 shows several graphs 40A-40F of Lempel-Ziv (LZ) complexity plotted over State of Charge % (SOC). LZ complexity measurements were obtained for new and aged cells at three different charge rates (1 C, 3 C, 5 C) over a full SOC cycle. The LZ complexity is a measurement of cell process predictability and is on a scale from 0-1, where a 1 indicates completely random behavior and 0 indicates perfectly predictable behavior. In a battery, detrimental processes such as plating and dendrite growth may appear as highly predictable processes compared to kinetics rate-limited by intercalation. Thus, deviations of LZ complexity toward 0 may be indicative of undesirable processes occurring within the battery. In contrast, intercalation of lithium ions into the graphite structure of an anode is characterized by a higher degree of randomness and prevents the electrochemical dynamics from being fully predictable.

Referring to FIG. 40, LZ complexity is measured for a new cell and an aged cell at each of three charging rates (1 C, 3 C, and 5 C). For each cell and charge rate, a graph of LZ complexity (y-axis) as a function of State of Charge (SOC %, x-axis) is shown. The cells were charged using a constant current/constant voltage (CCCV) charging signal. Solid data points on the graphs indicate a constant current portion of the charging signal where open data points indicate a constant voltage portion of the charging signal.

Referring initially to graph 40A, a new cell was charged at 1 C. This scenario results in a stable LZ complexity value that stays near 0.12 over the full charge cycle. The LZ complexity value observed at 1 C for a new cell may serve as a baseline value associated with healthy processes occurring within the cell.

Continuing to refer to the new cell data, at faster charge rates (3 C in graph 40B and 5 C in graph 40C), higher variation in LZ complexity can be seen. Referring to graph 40B, increasing the rate of charge results in a slight decrease of the predictability of the system through most of the charge period until approximately 80% SOC when predictability increases. In this scenario, the CV period begins too late to fully prevent the increase in predictability; however, the CV period does help the system achieve its original level of predictability over the remainder of the charge period.

Continuing to graph 40C, a new cell has been charged at a 5 C charge rate. Initially, the LZ complexity stays above the predictability baseline set during the 1 C charge cycle. However, at around 50% SOC, predictability of the system begins to increase. As will be discussed in further detail below, this 50% SOC level is also associated with a sharp increase in diffusion potential, an increase in heat generation, an increase in the chaotic dynamics of the system, and a decrease in entropy. Around 70% SOC the charge signal changes from constant current to constant voltage. Similar to the 3 C charging speed, this transition occurred too late to prevent a decrease in complexity did prove effective in eventually recovering the predictability level of the system. However, after the initial recovery, predictability of the system again increased. In some embodiments, a deviation away from baseline (e.g., a threshold value, threshold rate of change, and/or value outside of a standard deviation, etc.) during the CV portion or after a certain SOC % may be used as a trigger to stop the charging process in order to prevent processes (e.g., plating) that are detrimental to battery health.

Looking at LZ complexity data from the aged cell, higher variation is generally observed when compared to new cells charged at the same rate. Referring to graph 40D, an aged cell was charged at 1 C charge rate. Despite being aged, the cell remains near its expected baseline (e.g., 0.12 in this example) but includes more notable variation. Toward the end of charge, (e.g., around 50-60%), predictability of the cell begins to increase. This may indicate increasing influence from processes other than ion intercalation.

Graphs 40E and 40F show LZ complexity for an aged cell charged at 3 C rate and 5 C rate, respectively. These graphs show spikes 4001, 4002, 4003 in predictability (i.e., steep dips in the graph). The abrupt variations may be due to localized degradation (e.g., lithium plating or dendrites, cathode oxidation, solid-electrolyte interfase (SEI) growth and repair). The return of the LZ complexity level to near baseline after the period of increased predictability implies that the localized degredation process has abated.

LZ complexity may be used alone or in combination with other parameters (e.g., Lyapunov Exponent, diffusion potential, temperature measurements, entropy, etc.) to understand processes occurring within the battery and/or to adjust charge or discharge signals. For example, LZ complexity calculations may be completed in real time and may serve as a basis for adjusting charge rate of a battery. LZ complexity may provide immediate feedback about a cell's response to a particular charging current. If LZ complexity starts to move away from a baseline value toward zero (e.g., indicating plating or dendrite formation processes), charging current may be reduced until the LZ complexity value increases to a threshold value or increases to stay within a tolerance range of a nominal LZ complexity value. The nominal LZ complexity value may be established using known LZ complexity information for a particular battery or may be determined based on the LZ complexity values seen under 1 C charging when the cell is new.

In some embodiments, charge control systems may be developed that are based, at least in part, on LZ complexity measurements and/or changes in the LZ complexity measurements. For example, a data set showing low variation across LZ complexity values indicates that the system is generally very stable and the associated current levels are not causing excessive degradation. In such a scenario, higher currents could be tested. Variation of the LZ complexity measurement may be used as feedback to increase current until stability of the system is compromised. Similarly, if high variation of values is observed, current may be decreased until the variation is below an upper threshold value. Variation may be calculated using various known statistical analyses (e.g., standard deviation, variance, etc.). Other electrodynamic parameters may be used in the same way (e.g., reaction heat and sample entropy).

In some embodiments, LZ complexity may be used in a battery cell characterization process for analyzing a battery and pre-determining a specific charging protocol. The charging signal may change over the life of the battery as the LZ complexity becomes more variable as shown above in the comparison of new versus aged cells.

In some embodiments, detection of a plating process (e.g., using one or more parameters discussed herein) may trigger a plating reversal sequence. The plating reversal sequence may include a period of decreased or zero charge current to the battery (e.g., a rest period) followed by a discharge pulse. Multiple rest periods and/or discharge pulses may be used in various combinations to break down plating and extend the life of the battery. In some embodiments, LZ complexity measurements may be used to confirm the efficacy and extent of plating reversal achieved using the methods described. For example, LZ complexity data collected after completing a successful plating reversal process would exhibit fewer and/or lower magnitude drops toward predictability. In some embodiments, LZ complexity may be used as a trigger for completing a plating reversal process one or more times until the LZ complexity data demonstrates a desired level of predictability.

### Dynamic Fluctuation Analysis (Via Hurst or DFA)

FIG. 41 shows several graphs 41A-41F of Dynamic Fluctuation Analysis (DFA) measurements plotted over SOC. DFA measurements were obtained for new and aged cells at three different charge rates (1 C, 3 C, 5 C) over a full SOC cycle. DFA is a measure of diffusion potential or diffusion motion of ions through the battery. DFA values are on a scale from 0-1, where 1 indicates a perfectly linear path of an ion from a cathode to an anode and 0 indicates that ions have no net motion between electrodes. Values closer to 1 may indicate that detrimental processes such as plating or dendritic activity are occurring.

The DFA measurement is similar to the Hurst exponent discussed above. When a battery is relatively stable, Hurst and DFA will yield the same results. For increasingly unstable (i.e., non-stationary) systems, however, the DFA provides more insightful information. This is particularly useful in the context of batteries because cell aging and increased charge rates generally cause batteries to exhibit less stability. Notably, the term “stationary” and “non-stationary” are used in the manner common in signal analysis to describe the character and stability of a given signal.

Graph 41A shows DFA values for a new cell charged at 1 C rate. The higher values from approximately 0-15% SOC occur because of SEI growth, which consumes diffusing ions. Following the SEI growth period, the cell exhibits a baseline DFA of approximately 0.2 which indicates stable, healthy diffusion. This baseline may serve as a comparison reference for charge control as will be discussed in further detail below.

Graph 41B shows DFA values for a new cell charged at a 3 C rate. Similar to the trend discussed with respect to graph 41A, the 0-15% SOC range shows higher DFA values due to the SEI growth process. At around 50% SOC, a large increase in diffusion potential is observed as indicated by arrow 4101. This large increase accompanies the exothermic peak illustrated by arrow 3701 in graph 37E describing chemical heat generated by a new cell charged at a 3 C rate.

Graph 41C shows a diffusion potential for a new cell charged at 5 C. At this very fast rate of charging, the diffusion behavior increases dramatically above approximately 60% SOC. This likely indicates significant material degradation accompanied by lithium plating. The lithium has a less circuitous and more linear diffusion path as plating and dendrites grow. The CV period, notated with open data point markers, is not sufficient to protect the cell and there is approximately 10% ASOC (i.e., between approximately 70% SOC and 80% SOC) that elapses before the decreasing current of the CV period begins to normalize the diffusion activity back toward a baseline (e.g., as determined in graph 46A).

Referring to graph 41D, an aged cell is charged at 1 C. This cell exhibits approximately 30% capacity loss. For cells having this amount of aging, even charging rates as low as 1 C are no longer stable for the battery and plating appears to begin above approximately 55% SOC. Again, the CV period fails to adequately protect the cell by preventing or sufficiently minimizing degradation.

Graph 41E shows DFA for an aged cell charged at a 3 C rate. Lithium plating and electrolyte breakdown begin immediately as indicated by the high (e.g., greater than 0.6 in this example) DFA values that begin at 0% SOC. These high DFA values persist throughout much of the charge cycle. Similar to the new cell charged at 3 C, the aged cell charged at 3 C exhibits a large increase in diffusion potential around 50% SOC and labeled with arrow 4102.

Graph 41F shows data for an aged cell charged at 5 C. As with the aged cell charged at 3 C, the 5 C aged cell shows high DFA values at the beginning of the charge cycle, likely indicating plating and/or electrolyte breakdown. The DFA values remain high for the duration of the charge cycle and never reach the 0.2 threshold.

In addition to providing insight into processes occurring within the battery cell, DFA values may be used in charge control. In some embodiments, DFA values may be selected as triggers for adjusting charge current. For example, to prolong cycle life and protect against lithium plating, current may be decreased until DFA is below approximately 0.5. Thresholds lower than 0.5 may be selected to further extend cycle life. In some embodiments, inability to reduce the DFA value below the selected threshold (e.g., 0.5) over a selected SOC duration (e.g., 2% SOC duration for SOC greater than 70%) may serve as a charge termination trigger.

### Randomness of Battery Processes (Via BDS)

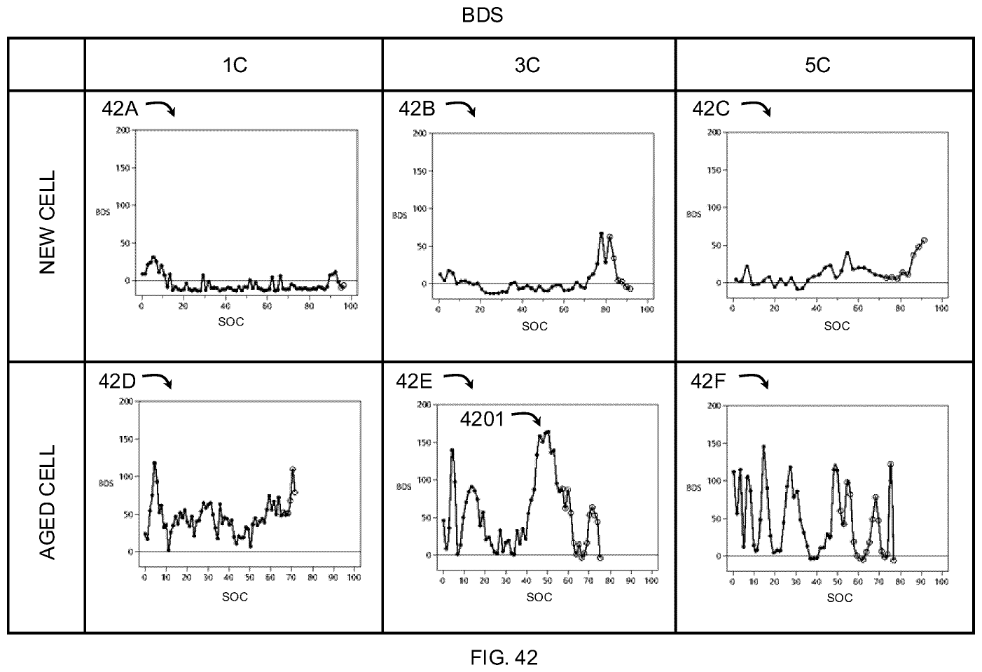

The Brock, Dechert, and Scheinkman (BDS) test is a statistical test that may be used to detect nonlinearity in a time series. In its present implementation, BDS values serve as a measure of randomness of processes within a battery. A BDS value of zero indicates perfectly random processes; a positive shift away from zero indicates correlation while a negative shift away from zero indicates anti-correlation. FIG. 42 includes graphs 42A-42F showing BDS values plotted over SOC for new and aged cells charged at 1 C, 3 C, and 5 C rates. Specific BDS data plots are described as a means of conveying how certain observable data features can be interpreted; however, trends and values shown on BDS plots may vary significantly for different types of batteries (e.g., energy cells versus power cells, thicker versus thinner electrodes, etc.).

Graph 42A shows BDS data for a new cell charged at a 1 C rate. Initial SOC values (e.g., from approximately 0-10%) show positive values of BDS. This indicates the occurrence of an ordered process, such as SEI formation. The remainder of the charge generally exhibits slightly negative BDS values, indicating steady and slightly anti-correlated behavior. This generally steady behavior may provide a baseline reference level for BDS value for a healthy cell.

Graph 42B shows a new cell charged at a faster 3 C rates. As with the 1 C rate, BDS values begin slightly positive. However, the BDS values for 3 C and 5 C remain positive longer into the SOC cycle, indicating that SEI growth may be more gradual and/or significant. The values drop near the negative near-baseline BDS value for only a short period afterward, if at all. At around 70% SOC, an increase in BDS values is observed, indicating the start of processes other than ion intercalation within the cell. The other processes are more ordered and may represent detrimental plating or dendrite growth. Peaks near 80%-100% SOC for the 3 C and 5 C rates may reflect significant and expected cathode restructuring. This feature is less distinctive in aged cells, as will be seen with respect to graphs 42D-42F. Graph 42C showing BDS values for a new cell charged at 5 C exhibits similar behavior with very few negative points near the baseline value.

Referring to graphs 42D-42F, aged cell data is shown for 1 C, 3 C, and 5 C. At the beginning SOC region for each graph, higher positive values are observed than those measured for the new cells charged at a corresponding rate. Positive values at this magnitude may indicate SEI growth that results in the consumption of lithium and electrolyte and also causes increased internal resistance. Thus, these positive BDS values are generally not considered healthy for the cells. For aged cells at all charge rates tested, BDS values remain primarily highly positive indicating that all of the tested charge rates are too fast for the aged cells to maintain stable and healthy electrochemical dynamics.

Looking at graph 42E, a noticeable change in process order is seen around 50% SOC, as indicated by arrow 4201. This particular feature corresponds with an increase in diffusion potential (see graph 41E) and a decrease in entropy (see graph 44E) at the same SOC %. This points toward localized degradation within the cell. Graph 42F shows that an aged cell charged at a 5 C rate exhibits highly variable BDS values. Under the 5 C charge conditions, the aged cell is routinely destabilized in a manner indicating continuous degradation.

BDS values may be used to control and adjust a charging signal. For example, and upper threshold BDS value may be selected. The upper threshold may represent a point above which cell degradation impacts cycle life. For the cell used to generate the BDS data of FIG. 42, an upper threshold around 50 may be selected, for example. BDS values approaching or surpassing the upper threshold may trigger an adjustment of the charge signal (e.g., to decrease the charge rate) until BDS values are within a desired range. In some embodiments, lower thresholds may be selected (e.g., associated with more random or anti-correlated magnitudes) to further improve cycle life. Due to its high level of sensitivity, BDS values may also be used alone or in combination with other parameters (e.g., DFA above a threshold value or above a threshold value for a determined SOC % duration) to trigger the end of a charge cycle.

### Chaotic Versus Periodic Cell Behavior (Via Lyapunov Exponent)

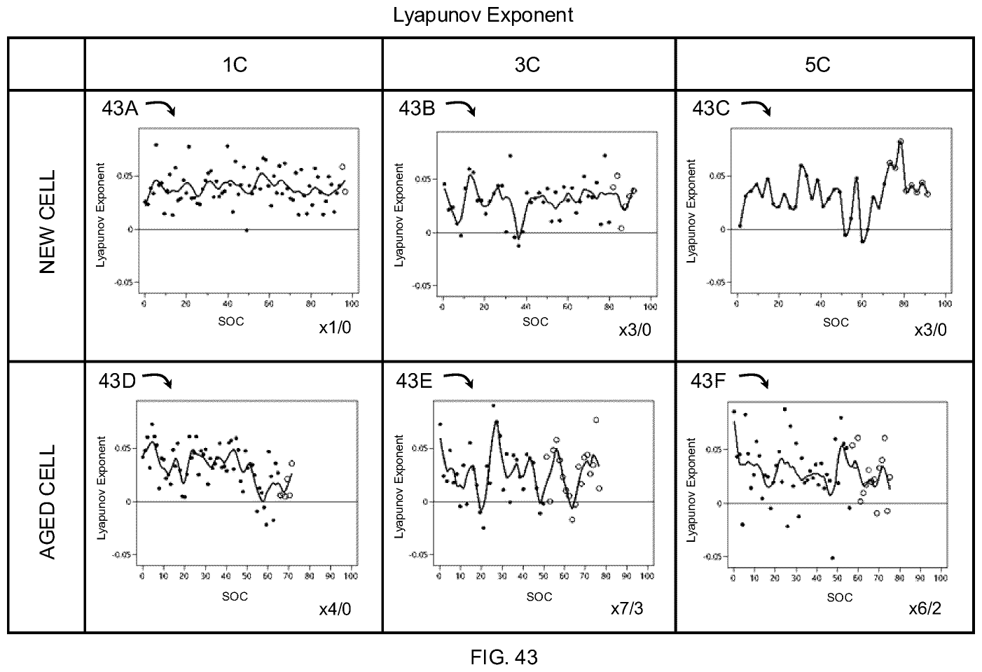

FIG. 43 shows Lyapunov Exponent (LE) values for new and aged lithium ion cells charged at 1 C, 3 C, and 5 C. In these plots, every data point at or below zero indicates that electrochemical processes inside the battery transitioned to a chaotic state, potentially triggering a secondary process (e.g., degradation such as plating, electrolyte breakdown, etc.). Subsequent points above zero do not mean that those secondary processes have ceased occurring. Other parameters may be used to determine whether the secondary processes are ongoing.

In the graphs, inset text is included in the format “x #/#.” The first number “x #′ represents the number of points at or below zero during the CC stage (indicated by solid data point markers). The second number “#” represents the number of points at or below zero during the CV stage (indicated by open data point markers). These zero crossings show that as the charge rate increases, the occurrence of chaotic transitions increases, and as the battery ages, such transitions increasingly occur. The CV period fails to maintain stabilization of electrochemical processes.

Referring to graph 43A, LE values indicate relatively stable activity characterized by a random nature. Graph 43B shows occasional shifts toward periodic behavior, indicating destabilization of the battery's electrodynamics due to the onset of undesirable secondary reactions. Graph 43C shows that battery dynamics become critically unstable around 50-60% SOC, coinciding with distinct increases in super-diffusive behavior (FIG. 41) and increases in predictability (FIG. 37) likely indicating lithium plating. As shown in graphs 43D-43F, aged cells generally exhibit increased zero crossings in the CC and CV portions of the charging signal.

LE values may be used to control charging. In some embodiments, decreasing the charge current when LE begins to approach or drop below zero may result in prolonged cycle life and may protect against lithium plating and other degradation processes. Notably, the correct interpretation of LE values is highly dependent on battery chemistry. For example, for lithium metal batteries, LE values below zero may be considered healthy and normal due to the more direct correlation between ion adsorption and charge exchange at the anode. If the rate-limiting process of the cell is random, the interpretation discussed with respect to FIG. 43 is useful. If the rate-limiting process of the battery is a more ordered process, the interpretation may deviate from the FIG. 43 discussion. Thus, to use LE in charge control, the type of battery and the LE behavior representative of healthy cell processes must be understood.

### Battery Entropy (Via Sample Entropy)

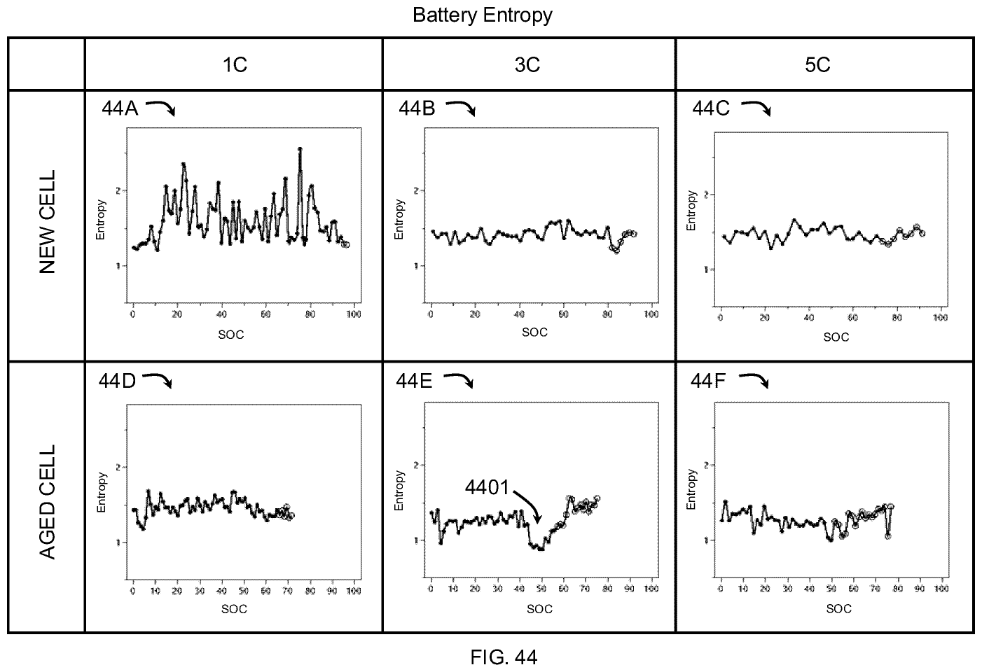

Sample entropy values are determined over a 1 C, 3 C, and 5 C charge cycle for new and aged cells. The data is plotted in graphs 44A-44F. Integer values of sample entropy, S, plotted on the y-axis imply primarily stable and periodic electrodynamics while non-integer values imply at least some degree of chaotic electrodynamics. In all of the plots of FIG. 44, the batteries have a mildly chaotic baseline value which is consistent with data presented in prior figures (e.g., BDS values of FIG. 42).

Looking to graph 44A, a new cell is charged at 1 C. Under these conditions, the system is operating in a stable range such that the battery entropy data clearly shows discrete changes as lithium ions shift. In the early SOC ranges, the sample entropy values are lower (i.e., indicating high levels of order within the system) because a majority of the lithium ions are stored within the cathode. Looking to the end of the charge cycle, sample entropy decreases again due to the lithium ions having moved into the anode. Between the beginning and end of charge, ions are more randomly distributed resulting in higher entropy values.

As charging rates increase (i.e., to 3 C as shown in graph 44B and to 5 C as shown in graph 44C), the discrete steps associated with the position of ions as shown in the 1 C graph are no longer visible in the data. This may be due to different processes occurring at different times and rates. These mixed effects can cause damping of the net signal.

Referring to the data obtained charging an aged cell (graphs 44D-44F), the distinct features seen in the graph 44A are convoluted because changes in anode and cathode structure occur in more gradated and less discrete stages, thereby causing entropy effects to be mixed. Referring to graph 44E where an aged cell was charged at 3 C, a sharp decrease in entropy is seen at arrow 4401 once the anode is approximately 50% full. This is consistent with a lithium plating process and agrees with decreased randomness at the same SOC % in graphs 42B, 42E, increased diffusion in graph 41B, 41E, and increased heat generation in graph 37E. Following the ˜50-60% SOC period, sample entropy recovers which may indicate a decrease in the lithium plating rate. This may be in part due to the transition to a CV charge.

Graph 44F shows that at 5 C charge rates, lithium plating in an aged battery is so severe that the entropy behavior is inverted (i.e., shows lower values between the beginning and end of charge rather than higher values). Plated lithium is more ordered and is associated with lower entropy values than intercalated lithium.

Sample entropy may be used in controlling charge for a battery. Cycle life may be prolonged by throttling current to maintain stable entropy readings (e.g., similar to those shown in graph 44A). Charging may be paused or ended in response to sudden changes in entropy, particularly if those changes reach or cross an integer value of sample entropy, S.

### Fractal Dimension of Battery Processes (Via Correlation Dimension)

Correlation dimension (CD) is a measure of the fractal dimension of the system. In an electrochemical system like a battery, fractal dimension may reflect the actual geometry of the electrode materials or interfaces (e.g., smooth and 2-dimensional versus increasingly fractal, rougher, and more highly dimensional), SEI thickness and tortuosity, or the complexity of the chemical processes. However, in a battery, each of these characteristics usually go hand-in-hand. Higher CD values imply increasing fractal dimension. Integer values imply stable process behavior, while non-integer values imply chaotic behavior.

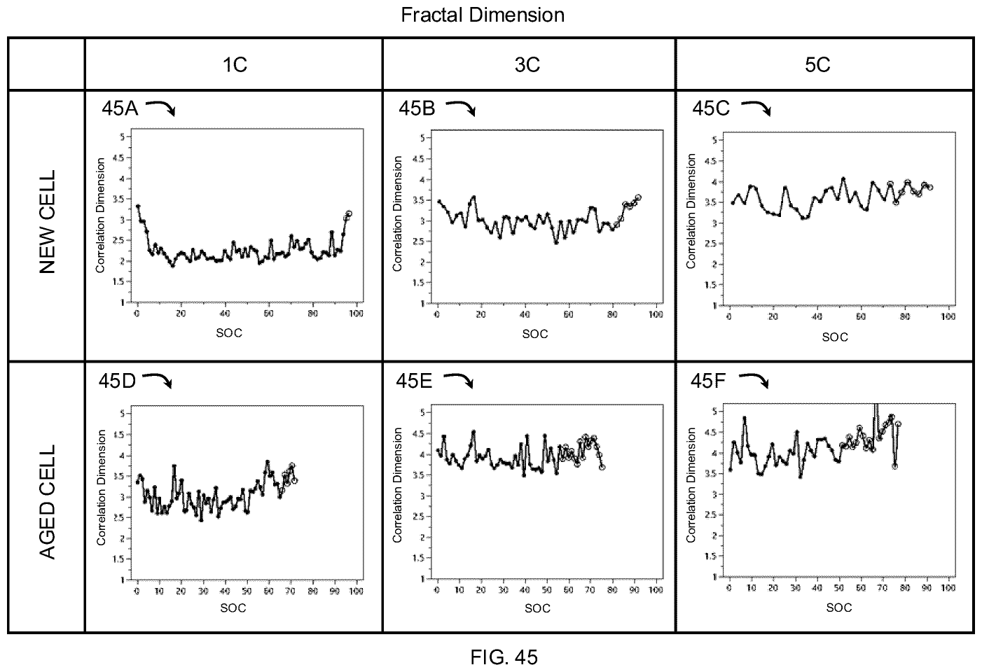

Referring to FIG. 45, graphs are shown for correlation dimension plotted over SOC % for new and aged cells each charged at 1 C, 3 C, and 5 C. Faster charge rates generally increase the complexity of features (e.g., plating and dendrites, hot spots, etc.) and chemical processes (e.g., primary and unwanted side reactions). In general, higher CD values indicate increasingly complex current distribution.

Graphs 45D-45F show data associated with aged cells. The aged cells in particular show how batteries are incapable of becoming infinitely complex, and for the particular cell tested, a CD value of approximately 4 appears to be an upper limit. Data in graphs 45E, 45F exhibit points above 4 and moving toward a CD value of 5. This may indicate a significantly greater level of degradation of the cell that should be avoided. Thus, CD may be used as a trigger to control charge and, in some instances, terminate charging when an upper threshold is reached or exceeded.

Current may be throttled based on CD values. In the example of FIG. 45, current may be controlled to maintain CD values between 2-3.5, or even lower if slow rates of charge are acceptable for the particular application. Battery end-of-life (EOL) may be determined if CD cannot be maintained below 3.5 at the desired rate of charge. Batteries which exceed 3.5 at any charge rate may be treated as unstable.

The parameters discussed above may all be based on real-time processing and analysis of a signal collected from a battery undergoing charging. No probing interruptions are required to obtain this data and as such, charging speed may be improved compared to protocols that must pause to run a probing signal.

The parameters also advantageously provide accurate, actionable information about processes occurring within the battery. As discussed, one or more of the parameters may be used to generate a dynamic charging signal that is specifically tailored to the individual battery cell and provides current in a way that minimizes the occurrence of detrimental processes. For example, current may be controlled throughout a charge cycle in order to maintain one or more of the parameters within a range. The range may be pre-determined and may be constant throughout the charge cycle and battery life or may change over a charge cycle or battery life. Ranges may be stored as equations, look-up tables, or may be otherwise accessed locally or through remote connections. This approach may eliminate the practice of applying a constant current and constant voltage charge to batteries. Instead, dynamic current control governed by one or more of the parameters discussed herein may lead to improved battery health and increased cycle life. The constant voltage portion of traditional charging signals may be omitted entirely, as several plots described herein indicate that the CV portion of a charging signal is typically ineffective at preventing the onset of detrimental processes toward the end of a charge cycle. In some embodiments, no prior battery information or history is needed to govern the charging signal.

In addition to using electrodynamic parameters described herein to control charge current, one or more of the electrodynamic parameters may be used to characterize batteries at rest. Batteries are susceptible to a process known as shelf aging and/or calendar aging, where degradation of the battery occurs while the battery is at rest. This can become problematic when batteries sit in storage or are otherwise unused for long periods of time. Exposure to warm temperatures may lead to more rapid degradation. Understanding an extent to which calendar aging has occurred may be beneficial (e.g., for quality checking batteries prior to installing them in a product, etc.). In some embodiments, a voltage measurement may be taken while the battery is at rest (i.e., with zero current). Electrodynamic parameters may be calculated using the voltage measurement data. In some embodiments, the calculated electrodynamic parameters may be compared to known values for new cells and cells at various stages of calendar aging to determine an approximate calendar age for the measured battery. In general, this approach may provide a quantifiable way to assess static (e.g., non-charging, non-discharging) health of a cell.

Electrodynamic parameters described herein may also be used to determine State of Health (SOH), State of Charge (SOC), State of Function (SOF), State of Energy (SOE), degradation rate for use in determining Remaining Useful Life (RUL), and other battery characterizations. These battery metrics can be used in various ways. For example, SOE may be used to inform the generation of a charge signal, where poor or decreasing SOE leads to reduced charge rates or otherwise less aggressive battery use.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed is:

1. A method of dynamically charging a battery, the method comprising:
obtaining a first value for a first electrodynamic parameter associated with behavior of a battery;
comparing the first value to a first threshold value for the first electrodynamic parameter; and
generating a charging signal for the battery based on the comparison of the first value to the first threshold value.

2. The method of claim 1, wherein obtaining the value for the electrodynamic parameter comprises calculating the electrodynamic parameter from a battery feedback signal.

3. The method of claim 2, wherein the battery feedback signal is generated during charging of the battery.

4. The method of claim 1, wherein the electrodynamic parameter comprises one selected from a group consisting of reaction heat, Lempel-Ziv (LZ) complexity, dynamic fluctuation analysis (DFA), Brock Dechert Scheinkman (BDS) test, Lyapunov Exponent (LE), Sample Entropy (SE), and Correlation Dimension (CD).

5. The method of claim 1, further comprising:
obtaining a second value for a second electrodynamic parameter associated with behavior of the battery;
comparing the second value to a second threshold value for the second electrodynamic parameter; and
generating the charging signal for the battery based on the comparison of the second value to the second threshold value.

6. The method of claim 1, wherein the first threshold value comprises an upper limit for the first electrodynamic parameter.

7. The method of claim 6, wherein generating the charging signal for the battery comprises selecting a charge rate that maintains the first value for the first electrodynamic parameter below the upper limit.

8. The method of claim 1, wherein the first threshold value comprises a lower limit for the first electrodynamic parameter.

9. The method of claim 8, wherein generating the charging signal for the battery comprises selecting a charge rate that maintains the first value for the first electrodynamic parameter above the lower limit.

10. The method of claim 1, wherein generating the charging signal for the battery comprises controlling current to the battery throughout an entire charge cycle.

11. The method of claim 10, wherein there is no constant voltage (CV) portion of the charging signal.

12. The method of claim 1, wherein generating a charging signal comprises determining an end of charge for the charge cycle.

13. The method of claim 12, wherein determining the end of charge comprises determining that no charge rate produces a first value that satisfies the first threshold value.

14. The method of claim 1, further comprising:
determining an amount of variation across a plurality of values for the first electrodynamic parameter;
comparing the amount of variation to a threshold amount of variation; and
generating a charge signal for the battery based on a result of the comparison.

15. The method of claim 14, wherein each of the plurality of values is associated with a different State of Charge percent value.

16. The method of claim 14, further comprising:
determining that the amount of variation is higher than the threshold amount of variation; and
reducing a charge rate of the battery.

17. The method of claim 14, further comprising:
determining that the amount of variation is lower than the threshold amount of variation; and
increasing the charge rate of the battery.

18. The method of claim 14, wherein the amount of variation is determined using fluctuation analysis.

19. The method of claim 18, wherein the fluctuation analysis is selected from a group consisting of point-to-point standard deviation, average deviation, and coefficient of variation, and skewness.

20. The method of claim 14, wherein the first electrodynamic parameter comprises one selected from a group consisting of LZ complexity, reaction heat, sample entropy, dynamic fluctuation analysis, BDS analysis, Lyapunov exponent, and correlation dimension.

21. A method of characterizing aging in a battery, the method comprising:
measuring a voltage of a battery while the battery is at rest;
calculating at least one electrodynamic parameter from the measured voltage; and
based on the at least one electrodynamic parameter, determining an amount of calendar aging associated with the battery.

22. A method of characterizing a battery, the method comprising:
obtaining a first value for a first electrodynamic parameter associated with behavior of a battery; and
determining a battery characterization metric based on the first value for the first electrodynamic parameter.

23. The method of claim 22, wherein the battery characterization metric comprises one selected from a group consisting of State of Health (SOH), State of Charge (SOC), State of Function (SOF), State of Energy (SOE), and Remaining Useful Life (RUL).
